(19) United States
(12) Patent Application Publication
(10) Pub. No.: US 2026/0305167 A1
(43) Pub. Date: Oct. 1, 2026

(54) ORGANIC ELECTROLUMINESCENT MATERIALS AND DEVICES

(71) Applicant: UNIVERSAL DISPLAY CORPORATION, Ewing, NJ (US)

(72) Inventors: Michael S. WEAVER, PRINCETON, NJ (US); NICHOLAS J. THOMPSON, HAMILTON, NJ (US); VADIM ADAMOVICH, UARDLEY, PA (US); JERALD FELDMAN, CHERRY HILL, NJ (US); CHUN LIN, YARDLEY, PA (US)

(73) Assignee: UNIVERSAL DISPLAY CORPORATION, Ewing, NJ (US)

(21) Appl. No.: 19/683,892

(22) Filed: May 21, 2026

Related U.S. Application Data
(63) Continuation of application No. 16/856,428, filed on Apr. 23, 2020.
(60) Provisional application No. 62/840,143, filed on Apr. 29, 2019.

(51) Int. Cl. H10K 85/60; H10K 50/11; H10K 50/18; H10K 85/30; H10K 101/10; H10K 101/20

(52) U.S. Cl. CPC H10K 85/6572; H10K 85/322; H10K 85/342; H10K 85/622; H10K 85/633; H10K 85/636; H10K 85/657; H10K 85/6574; H10K 85/658; H10K 50/11; H10K 50/181; H10K 85/346; H10K 2101/10; H10K 2101/20

(57) ABSTRACT

Disclosed is electron/exciton blocking material that is a compound of

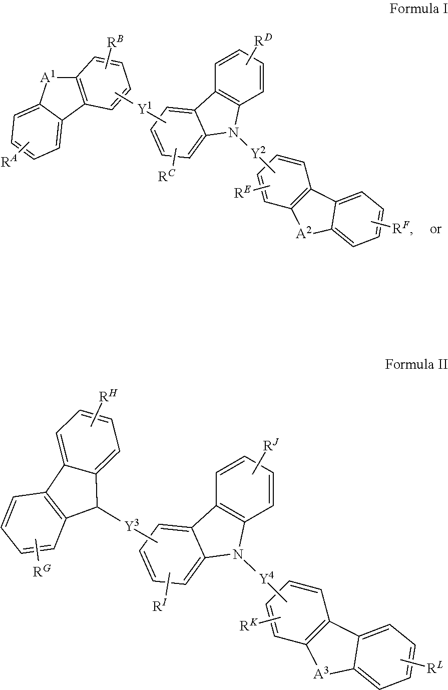

that is useful in improving the EQE of OLEDs. Also disclosed are OLEDs incorporating the electron/exciton blocking materials in their electron/exciton blocking layers and display devices incorporating such OLEDs.

### CROSS-REFERENCE TO RELATED APPLICATIONS

This application is a continuation of U.S. application Ser. No. 16/856,428, filed Apr. 23, 2020, which claims priority under 35 U.S.C. § 119(e) to U.S. Provisional Application No. 62/840,143, filed on Apr. 29, 2019, the entire contents of which are incorporated herein by reference.

### FIELD

The present disclosure generally relates to organometallic compounds and formulations and their various uses including as hosts or emitters in devices such as organic light emitting diodes and related electronic devices.

### BACKGROUND

Opto-electronic devices that make use of organic materials are becoming increasingly desirable for various reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials.

OLEDs make use of thin organic films that emit light when voltage is applied across the device. OLEDs are becoming an increasingly interesting technology for use in applications such as flat panel displays, illumination, and backlighting.

One application for phosphorescent emissive molecules is a full color display. Industry standards for such a display call for pixels adapted to emit particular colors, referred to as “saturated” colors. In particular, these standards call for saturated red, green, and blue pixels. Alternatively, the OLED can be designed to emit white light. In conventional liquid crystal displays emission from a white backlight is filtered using absorption filters to produce red, green and blue emission. The same technique can also be used with OLEDs. The white OLED can be either a single emissive layer (EML) device or a stack structure. Color may be measured using CIE coordinates, which are well known to the art.

### SUMMARY

Disclosed herein is a novel electron/exciton blocking family of materials (herein after “EBL family”) that are useful for electron/exciton blocking layer (EBL) in OLEDs.

In one aspect, the present disclosure provides an OLED comprising sequentially: an anode; a hole transporting layer comprising a first hole transporting material; an EBL comprising an electron/exciton blocking material; an emissive region comprising an EML that comprises a first emissive dopant; and a cathode, wherein the electron/exciton blocking material comprising a compound of

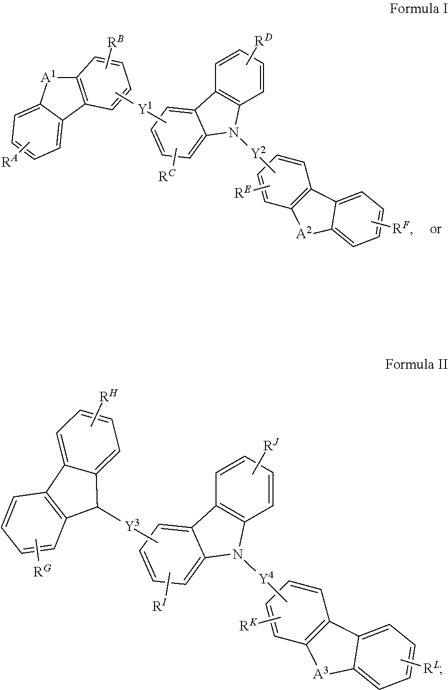

wherein, A¹, A², and A³ are each independently selected from the group consisting of O, S, and NR; Y¹, Y², Y³, and Y⁴ are each independently a direct bond, O, S, NR, or an organic linker comprising 1 to 18 carbon atoms; R^{A} to R^{L} each independently represents mono to the maximum allowable substitutions, or no substitution; each R, R^{A} to R^{L} is independently a hydrogen or a substituent selected from the group consisting of the general substituents defined herein; and any two substituents can be joined or fused together to form a ring.

A display device comprising multiple OLEDs with a common EBL is also disclosed herein.

In another aspect, the present disclosure provides a formulation of the electron/exciton blocking material of the present disclosure.

In yet another aspect, the present disclosure provides a consumer product comprising an OLED of the present disclosure.

### BRIEF DESCRIPTION OF THE DRAWINGS

The following figures are provided to help in describing the subject matter of the present disclosure. All figures are schematic and are not intended to show actual dimensions or proportions of any structures.

FIG. 1 shows an organic light emitting device.

FIG. 2 shows an inverted organic light emitting device that does not have a separate electron transport layer.

FIG. 3 shows a cross-section of an example of an OLED structure where the anode is deposited on the substrate first and one of the layers is an EBL of the present disclosure is provided between the hole transporting layer (HTL) and the EML

FIG. 4 shows a cross-section of an example of an inverted OLED structure where the cathode is deposited on the substrate first and the EBL of the present disclosure is provided between the HTL and the EML.

FIG. 5 shows a cross-section of an example of a tandem stacked OLED structure in which two sets of Emissive Region/EBL/HTL combination layers, in which the EBL of the present disclosure is between the HTL and the Emissive Region in each set.

FIG. 6 shows a cross-section of another example of a stacked OLED structure in which three sets of Emissive Region/EBL/HTL combination layers, in which the EBL of the present disclosure is between the HTL and the Emissive Region in each set.

FIG. 7 shows a cross-section of a portion of an example of a pixel in a display device in which 3 sub-pixels of different color are formed by 3 OLED structures where one common continuous EBL comprising the electron/exciton blocking material of the present disclosure extends across the 3 OLED structures between their EML and HTL.

FIG. 8 shows a cross-section of a portion of another example of a pixel in a display device in which 3 sub-pixels of different color are formed by 3 OLED structures where one common EBL of the present disclosure extends across 2 adjacent OLED structures of the 3 OLEDs.

FIG. 9 shows a cross-section of a portion of another example of a pixel in a display device in which 4 sub-pixels of different color are formed by 4 OLED structures where one common EBL of the present disclosure extends across the 4 OLED structures.

FIG. 10 shows a cross-section of a portion of another example of a pixel in a display device in which 4 sub-pixels of different color are formed by 4 OLED structures where one common EBL of the present disclosure extends across 2 adjacent OLED structures of the 4 OLEDs.

FIG. 11 shows a cross-section of a portion of another example of a pixel in a display device in which 4 sub-pixels of different color are formed by 4 OLED structures where one common EBL of the present disclosure extends across 3 adjacent OLED structures of the 4 OLEDs.

FIGS. 12A-12C are example energy level diagrams of OLED embodiments containing an EBL comprising the EBL material of the present disclosure. The dashed lines in the EML represent the energy levels of the emitter dopant.

FIG. 13 is a plot of external quantum efficiency (EQE) vs. current density for two devices with Emitter 1: one device with an EBL of the present disclosure and one device without the EBL. Notice that the less efficiency at high brightness is minimized for the device with the EBL.

### DETAILED DESCRIPTION

### A. Terminology

Unless otherwise specified, the below terms used herein are defined as follows:

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processable” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

The terms “halo,” “halogen,” and “halide” are used interchangeably and refer to fluorine, chlorine, bromine, and iodine.

The term “acyl” refers to a substituted carbonyl radical (C(O)—Rₛ).

The term “ester” refers to a substituted oxycarbonyl (—O—C(O)—Rₛ or —C(O)—O—Rₛ) radical.

The term “ether” refers to an —ORₛ radical.

The terms “sulfanyl” or “thio-ether” are used interchangeably and refer to a —SRₛ radical.

The term “sulfinyl” refers to a —S(O)—Rₛ radical.

The term “sulfonyl” refers to a —SO₂—Rₛ radical.

The term “phosphino” refers to a —P(Rₛ)₃ radical, wherein each Rₛ can be same or different.

The term “silyl” refers to a —Si(Rₛ)₃ radical, wherein each Rₛ can be same or different.

The term “boryl” refers to a —B(Rₛ)₂ radical or its Lewis adduct —B(Rₛ)₃ radical, wherein Rₛ can be same or different.

In each of the above, Rₛ can be hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, and combination thereof. Preferred Rₛ is selected from the group consisting of alkyl, cycloalkyl, aryl, heteroaryl, and combination thereof.

The term “alkyl” refers to and includes both straight and branched chain alkyl radicals. Preferred alkyl groups are those containing from one to fifteen carbon atoms and includes methyl, ethyl, propyl, 1-methylethyl, butyl, 1-methylpropyl, 2-methylpropyl, pentyl, 1-methylbutyl, 2-methylbutyl, 3-methylbutyl, 1,1-dimethylpropyl, 1,2-dimethylpropyl, 2,2-dimethylpropyl, and the like. Additionally, the alkyl group may be optionally substituted.

The term “cycloalkyl” refers to and includes monocyclic, polycyclic, and spiro alkyl radicals. Preferred cycloalkyl groups are those containing 3 to 12 ring carbon atoms and includes cyclopropyl, cyclopentyl, cyclohexyl, bicyclo[3.1.1]heptyl, spiro[4.5]decyl, spiro[5.5]undecyl, adamantyl, and the like. Additionally, the cycloalkyl group may be optionally substituted.

The terms “heteroalkyl” or “heterocycloalkyl” refer to an alkyl or a cycloalkyl radical, respectively, having at least one carbon atom replaced by a heteroatom. Optionally the at least one heteroatom is selected from O, S, N, P, B, Si and Se, preferably, O, S or N. Additionally, the heteroalkyl or heterocycloalkyl group may be optionally substituted.

The term “alkenyl” refers to and includes both straight and branched chain alkene radicals. Alkenyl groups are essentially alkyl groups that include at least one carbon-carbon double bond in the alkyl chain. Cycloalkenyl groups are essentially cycloalkyl groups that include at least one carbon-carbon double bond in the cycloalkyl ring. The term “heteroalkenyl” as used herein refers to an alkenyl radical having at least one carbon atom replaced by a heteroatom. Optionally the at least one heteroatom is selected from O, S, N, P, B, Si, and Se, preferably, O, S, or N. Preferred alkenyl, cycloalkenyl, or heteroalkenyl groups are those containing two to fifteen carbon atoms. Additionally, the alkenyl, cycloalkenyl, or heteroalkenyl group may be optionally substituted.

The term “alkynyl” refers to and includes both straight and branched chain alkyne radicals. Alkynyl groups are essentially alkyl groups that include at least one carbon-carbon triple bond in the alkyl chain. Preferred alkynyl groups are those containing two to fifteen carbon atoms. Additionally, the alkynyl group may be optionally substituted.

The terms “aralkyl” or “arylalkyl” are used interchangeably and refer to an alkyl group that is substituted with an aryl group. Additionally, the aralkyl group may be optionally substituted.

The term “heterocyclic group” refers to and includes aromatic and non-aromatic cyclic radicals containing at least one heteroatom. Optionally the at least one heteroatom is selected from O, S, N, P, B, Si, and Se, preferably, O, S, or N. Hetero-aromatic cyclic radicals may be used interchangeably with heteroaryl. Preferred hetero-non-aromatic cyclic groups are those containing 3 to 7 ring atoms which includes at least one hetero atom, and includes cyclic amines such as morpholino, piperidino, pyrrolidino, and the like, and cyclic ethers/thio-ethers, such as tetrahydrofuran, tetrahydropyran, tetrahydrothiophene, and the like. Additionally, the heterocyclic group may be optionally substituted.

The term “aryl” refers to and includes both single-ring aromatic hydrocarbyl groups and polycyclic aromatic ring systems. The polycyclic rings may have two or more rings in which two carbons are common to two adjoining rings (the rings are “fused”) wherein at least one of the rings is an aromatic hydrocarbyl group, e.g., the other rings can be cycloalkyls, cycloalkenyls, aryl, heterocycles, and/or heteroaryls. Preferred aryl groups are those containing six to thirty carbon atoms, preferably six to twenty carbon atoms, more preferably six to twelve carbon atoms. Especially preferred is an aryl group having six carbons, ten carbons or twelve carbons. Suitable aryl groups include phenyl, biphenyl, triphenyl, triphenylene, tetraphenylene, naphthalene, anthracene, phenalene, phenanthrene, fluorene, pyrene, chrysene, perylene, and azulene, preferably phenyl, biphenyl, triphenyl, triphenylene, fluorene, and naphthalene. Additionally, the aryl group may be optionally substituted.

The term “heteroaryl” refers to and includes both single-ring aromatic groups and polycyclic aromatic ring systems that include at least one heteroatom. The heteroatoms include, but are not limited to O, S, N, P, B, Si, and Se. In many instances, O, S, or N are the preferred heteroatoms. Hetero-single ring aromatic systems are preferably single rings with 5 or 6 ring atoms, and the ring can have from one to six heteroatoms. The hetero-polycyclic ring systems can have two or more rings in which two atoms are common to two adjoining rings (the rings are “fused”) wherein at least one of the rings is a heteroaryl, e.g., the other rings can be cycloalkyls, cycloalkenyls, aryl, heterocycles, and/or heteroaryls. The hetero-polycyclic aromatic ring systems can have from one to six heteroatoms per ring of the polycyclic aromatic ring system. Preferred heteroaryl groups are those containing three to thirty carbon atoms, preferably three to twenty carbon atoms, more preferably three to twelve carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Of the aryl and heteroaryl groups listed above, the groups of triphenylene, naphthalene, anthracene, dibenzothiophene, dibenzofuran, dibenzoselenophene, carbazole, indolocarbazole, imidazole, pyridine, pyrazine, pyrimidine, triazine, and benzimidazole, and the respective aza-analogs of each thereof are of particular interest.

The terms alkyl, cycloalkyl, heteroalkyl, heterocycloalkyl, alkenyl, cycloalkenyl, heteroalkenyl, alkynyl, aralkyl, heterocyclic group, aryl, and heteroaryl, as used herein, are independently unsubstituted, or independently substituted, with one or more general substituents.

In many instances, the general substituents are selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, boryl, and combinations thereof.

In some instances, the preferred general substituents are selected from the group consisting of deuterium, fluorine, alkyl, cycloalkyl, heteroalkyl, alkoxy, aryloxy, amino, silyl, alkenyl, cycloalkenyl, heteroalkenyl, aryl, heteroaryl, nitrile, isonitrile, sulfanyl, boryl, and combinations thereof.

In some instances, the more preferred general substituents are selected from the group consisting of deuterium, fluorine, alkyl, cycloalkyl, alkoxy, aryloxy, amino, silyl, boryl, aryl, heteroaryl, sulfanyl, and combinations thereof.

In yet other instances, the most preferred general substituents are selected from the group consisting of deuterium, fluorine, alkyl, cycloalkyl, aryl, heteroaryl, and combinations thereof.

The terms “substituted” and “substitution” refer to a substituent other than H that is bonded to the relevant position, e.g., a carbon or nitrogen. For example, when R¹ represents mono-substitution, then one R¹ must be other than H (i.e., a substitution). Similarly, when R¹ represents di-substitution, then two of R¹ must be other than H. Similarly, when R¹ represents zero or no substitution, R¹, for example, can be a hydrogen for available valencies of ring atoms, as in carbon atoms for benzene and the nitrogen atom in pyrrole, or simply represents nothing for ring atoms with fully filled valencies, e.g., the nitrogen atom in pyridine. The maximum number of substitutions possible in a ring structure will depend on the total number of available valencies in the ring atoms.

As used herein, “combinations thereof” indicates that one or more members of the applicable list are combined to form a known or chemically stable arrangement that one of ordinary skill in the art can envision from the applicable list. For example, an alkyl and deuterium can be combined to form a partial or fully deuterated alkyl group; a halogen and alkyl can be combined to form a halogenated alkyl substituent; and a halogen, alkyl, and aryl can be combined to form a halogenated arylalkyl. In one instance, the term substitution includes a combination of two to four of the listed groups. In another instance, the term substitution includes a combination of two to three groups. In yet another instance, the term substitution includes a combination of two groups. Preferred combinations of substituent groups are those that contain up to fifty atoms that are not hydrogen or deuterium, or those which include up to forty atoms that are not hydrogen or deuterium, or those that include up to thirty atoms that are not hydrogen or deuterium. In many instances, a preferred combination of substituent groups will include up to twenty atoms that are not hydrogen or deuterium.

The “aza” designation in the fragments described herein, i.e. aza-dibenzofuran, aza-dibenzothiophene, etc. means that one or more of the C—H groups in the respective aromatic ring can be replaced by a nitrogen atom, for example, and without any limitation, azatriphenylene encompasses both dibenzo[f,h]quinoxaline and dibenzo[f,h]quinoline. One of ordinary skill in the art can readily envision other nitrogen analogs of the aza-derivatives described above, and all such analogs are intended to be encompassed by the terms as set forth herein.

As used herein, “deuterium” refers to an isotope of hydrogen. Deuterated compounds can be readily prepared using methods known in the art. For example, U.S. Pat. No. 8,557,400, Patent Pub. No. WO 2006/095951, and U.S. Pat. Application Pub. No. US 2011/0037057, which are hereby incorporated by reference in their entireties, describe the making of deuterium-substituted organometallic complexes. Further reference is made to Ming Yan, et al., Tetrahedron 2015, 71, 1425-30 and Atzrodt et al., Angew. Chem. Int. Ed. (Reviews) 2007, 46, 7744-65, which are incorporated by reference in their entireties, describe the deuteration of the methylene hydrogens in benzyl amines and efficient pathways to replace aromatic ring hydrogens with deuterium, respectively.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or attached fragment are considered to be equivalent.

In some instance, a pair of adjacent substituents can be optionally joined or fused into a ring. The preferred ring is a five, six, or seven-membered carbocyclic or heterocyclic ring, includes both instances where the portion of the ring formed by the pair of substituents is saturated and where the portion of the ring formed by the pair of substituents is unsaturated. As used herein, “adjacent” means that the two substituents involved can be on the same ring next to each other, or on two neighboring rings having the two closest available substitutable positions, such as 2, 2′ positions in a biphenyl, or 1, 8 position in a naphthalene, as long as they can form a stable fused ring system.

### B. The EBL Material and the OLED of the Present Disclosure

The EBL family of materials disclosed herein can be used to block electrons and excitons when used as an EBL in an OLED in combination with an adjacent emissive layer (EML) containing one or more of phosphorescent, fluorescent, and thermally activated delayed fluorescence (TADF) emitters, or a combination of these emitter classes. This EBL family has the potential to be used as a common layer EBL in an OLED display for use with 1, 2, 3 or all colors of the sub-pixels. This EBL family of materials has commercial level of stability and can help increase OLEDs' efficiency by confining electrons and/or excitons within a given EML by blocking or reducing the movement of electrons and excitons out of the EML on the anode side of the device.

This EBL family of materials has demonstrated excellent OLED device performance with fluorescent blue emitters, as well as phosphorescent blue, green, and red emitters.

In addition to this EBL family's ability to prevent electrons and excitons from leaving the device on the anode side of the device, many embodiments of this EBL family have a HOMO level that is between the HOMO levels of the typical HTL material and the typical host material in the EML. This energy level alignment facilitates the injection of holes into the EML and can assist in obtaining charge balance in the OLED at all brightness levels. The EBL family of the present disclosure are high triplet EBL materials. This means that the triplet energy T₁ of the EBL family of the present disclosure is greater than the triplet energies T₁s of all materials in the EML.

In some embodiments of the present disclosure, this EBL family is used in conjunction with a high T₁ hole/exciton blocking layer (HBL) and an EML which has a fluorescent blue dopant and a host material which undergoes triplet-triplet annihilation. By using the high triplet EBL on the anode side of the EML and an additional high triplet HBL on the cathode side of the EML, the triplet excitons will be spatially confined to the EML with minimal quenching to any transport layers and thus the triplet excitons are more likely to undergo triplet-triplet annihilation and re-form singlet excitons which can then be emitted by the blue fluorescent dopant.

Because a higher density of triplet excitons promotes more efficient triplet-triplet annihilation, a thinner EML will have higher triplet exciton density for the same current density of operation. Thus, it is preferred that the EML be between 50 to 500 Å thick, and more preferably between 100 to 300 Å thick. Blue fluorescent emitters include deep blue and light blue colors. Blue emitters in OLED devices (with or without a microcavity) normally have a dominant wavelength of less than or equal to 510 nm. In some embodiments, it can be less than or equal to 490 nm. In another embodiments, it can be less than or equal to 470 nm. In a further embodiments, it can be less than or equal to 460 nm.

When using the presently disclosed EBL family with a high triplet HBL material (“high triplet” means that the T₁ of the HBL is greater than the T₁s of all materials in the EML), in some embodiments the LUMO level of HBL is lower than the LUMO level of the electron/exciton transport layer (ETL) material but higher than the LUMO level of at least one material in the EML.

In another embodiment, the LUMO level of the HBL material is higher than that of all materials in the EML but lower than that of the ETL material. In other embodiments, the LUMO level of the HBL is higher than that of at least one material in the EML and higher than the LUMO level of the ETL. In other embodiments, the LUMO level of the HBL is higher than that of all materials in the EML and higher than the LUMO level of the ETL.

In some embodiments, the HOMO level of the HBL material is lower than that of at least one material in the EML. In some embodiments, the HOMO level of the HBL is lower than that of all materials in the EML.

When the HBL is used in conjunction with the EBL as blocking layers for a fluorescent blue EML, the singlet energy S₁ of the HBL will be greater than that of the blue fluorescent material. In other embodiments, the S₁ of the HBL will be greater than the S₁ of all materials in the EML.

Devices using this EBL family will have the EBL having a thickness from 10 to 1000 Å (1 to 100 nm), more preferably 10 to 300 Å (1 to 30 nm), more preferably 10 to 250 Å (1 to 25 nm), even more preferably 10 to 200 Å (1 to 20 nm), more preferably 10 to 150 Å (1 to 15 nm). These thicknesses refer to embodiments where the EBL is a neat layer. When EBL is comprised of the EBL family and a dopant, the EBL can be thicker than the neat layer EBL.

In some embodiments of this invention, the EBL material of the present disclosure will have a LUMO level that is higher than the LUMO level of at least one material in the EML. In some embodiments, the EBL material will have a LUMO level that is higher than the LUMO level of all the materials in the EML. In some embodiments, the EBL will have a higher S₁ than all materials in the EML. In some embodiments, the EBL will have a higher T₁ than all the materials in the EML.

In one aspect, the present disclosure provides an OLED comprising sequentially: an anode; a hole transporting layer comprising a first hole transporting material; an EBL comprising an electron/exciton blocking material; an emissive region comprising an EML that comprises a first emissive dopant; and a cathode, wherein the electron/exciton blocking material comprising a compound of

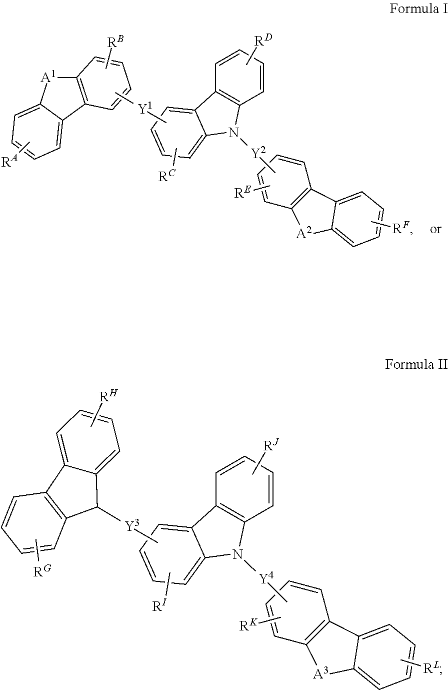

wherein, A¹, A², and A³ are each independently selected from the group consisting of O, S, and NR; Y¹, Y², Y³, and Y⁴ are each independently a direct bond, O, S, NR, or an organic linker comprising 1 to 18 carbon atoms; R^{A} to R^{L} each independently represents mono to the maximum allowable substitutions, or no substitution; each R, R^{A} to R^{L} is independently a hydrogen or a substituent selected from the group consisting of the general substituents defined herein; and any two substituents can be joined or fused together to form a ring.

In some embodiments of the OLED, each R, R^{A} to R^{L} is independently a hydrogen or a substituent selected from the group consisting of the preferred general substituents defined herein.

In some embodiments, Y¹, Y², Y³, and Y⁴ are each independently selected from the group consisting of a direct bond, phenyl, biphenyl, terphenyl, and napththyl. In some embodiments, Y¹, Y², Y³, and Y⁴ are each direct bonds. In some embodiments, at least one of Y¹, Y², Y³, and Y⁴ is a phenyl.

In some embodiments, A¹, A², and A³ are each NR, wherein R is aryl. In some embodiments, R^{A} to R^{L}, R^{X}, R^{Y}, and R^{Z} are each hydrogen. In some embodiments, the compound in the organic layer is a compound of Formula III

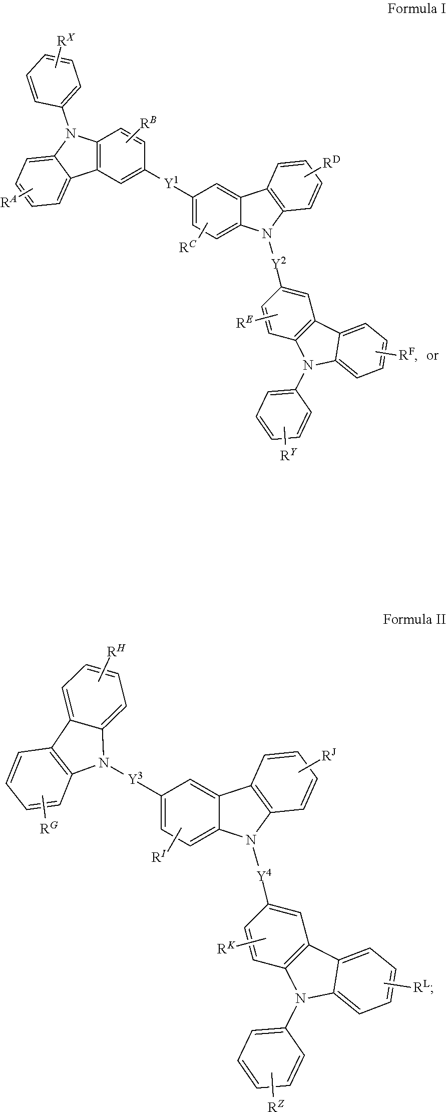

and wherein R^{X}, R^{Y}, and R^{Z} have the same definition as R^{A} to R^{L}.

In some embodiments of the OLED, the electron/exciton blocking material is a compound selected from the group consisting of:

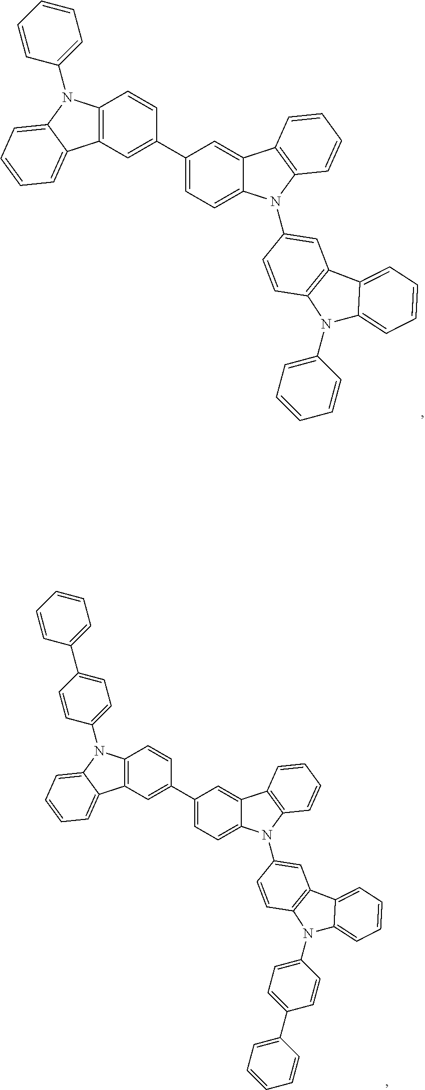 [SMILES: c1ccc(-n2c3ccccc3c3cc(-c4ccc5c(c4)c4ccccc4n5-c4ccc5c(c4)c4ccccc4n5-c4ccccc4)ccc32)cc1 ; c1ccc(-c2ccc(-n3c4ccccc4c4cc(-c5ccc6c(c5)c5ccccc5n6-c5ccc6c(c5)c5ccccc5n6-c5ccc(-c6ccccc6)cc5)ccc43)cc2)cc1]

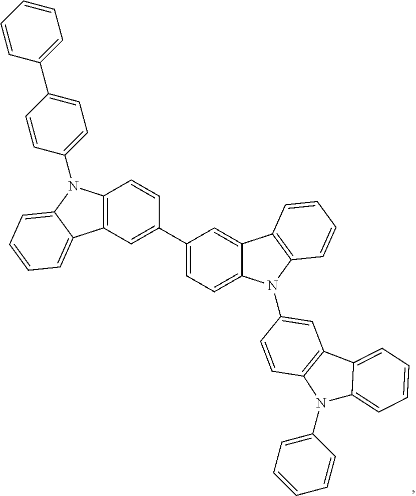 [SMILES: c1ccc(-c2ccc(-n3c4ccccc4c4cc(-c5ccc6c(c5)c5ccccc5n6-c5ccc6c(c5)c5ccccc5n6-c5ccccc5)ccc43)cc2)cc1]

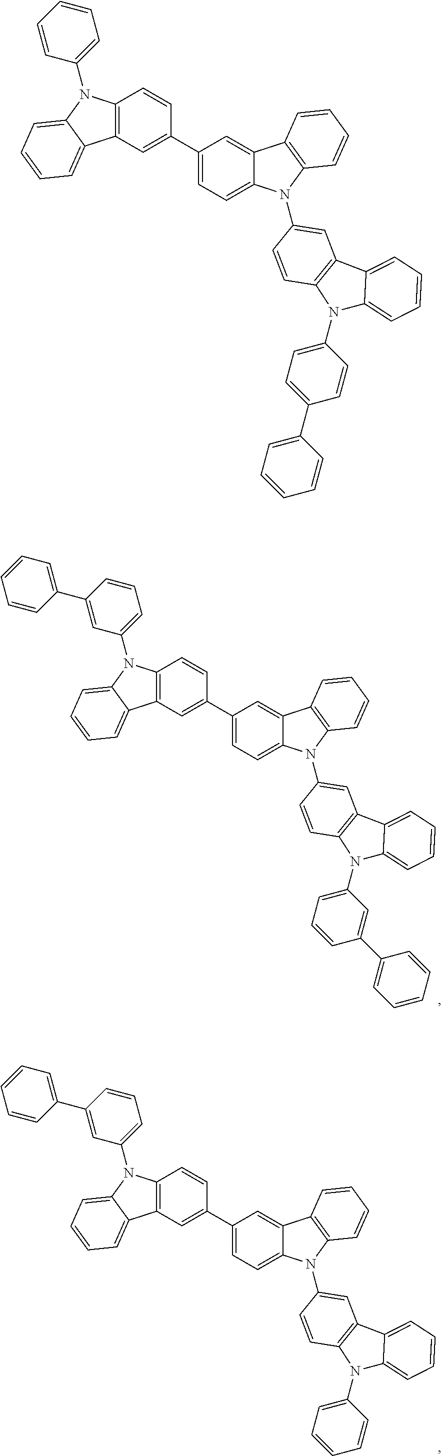 [SMILES: c1ccc(-c2ccc(-n3c4ccccc4c4cc(-n5c6ccccc6c6cc(-c7ccc8c(c7)c7ccccc7n8-c7ccccc7)ccc65)ccc43)cc2)cc1 ; c1ccc(-c2cccc(-n3c4ccccc4c4cc(-c5ccc6c(c5)c5ccccc5n6-c5ccc6c(c5)c5ccccc5n6-c5cccc(-c6ccccc6)c5)ccc43)c2)cc1 ; c1ccc(-c2cccc(-n3c4ccccc4c4cc(-c5ccc6c(c5)c5ccccc5n6-c5ccc6c(c5)c5ccccc5n6-c5ccccc5)ccc43)c2)cc1]

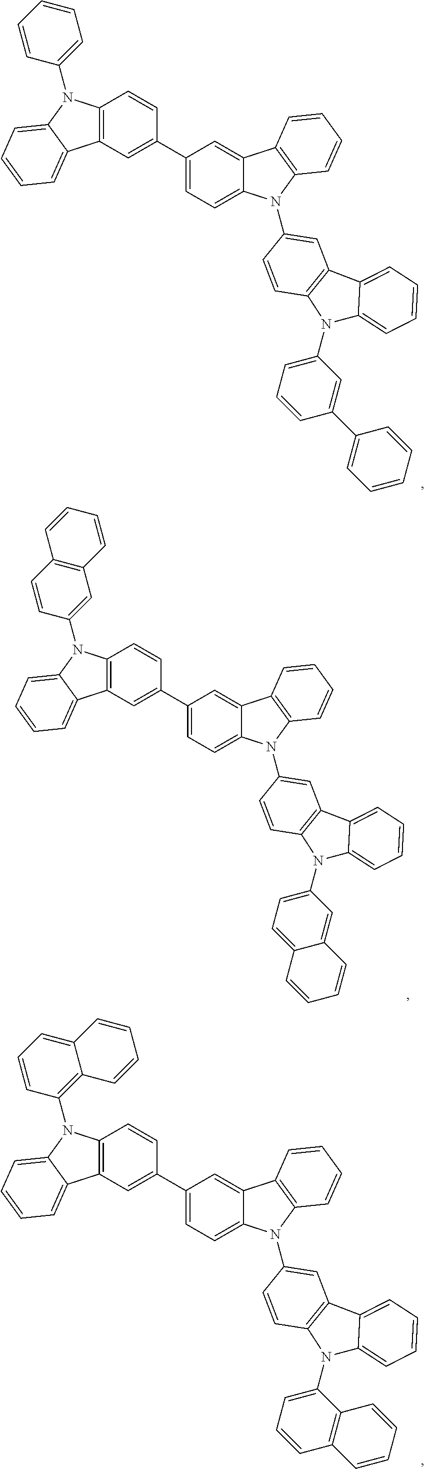 [SMILES: c1ccc(-c2cccc(-n3c4ccccc4c4cc(-n5c6ccccc6c6cc(-c7ccc8c(c7)c7ccccc7n8-c7ccccc7)ccc65)ccc43)c2)cc1 ; c1ccc2cc(-n3c4ccccc4c4cc(-c5ccc6c(c5)c5ccccc5n6-c5ccc6c(c5)c5ccccc5n6-c5ccc6ccccc6c5)ccc43)ccc2c1 ; c1ccc2c(-n3c4ccccc4c4cc(-c5ccc6c(c5)c5ccccc5n6-c5ccc6c(c5)c5ccccc5n6-c5cccc6ccccc56)ccc43)cccc2c1]

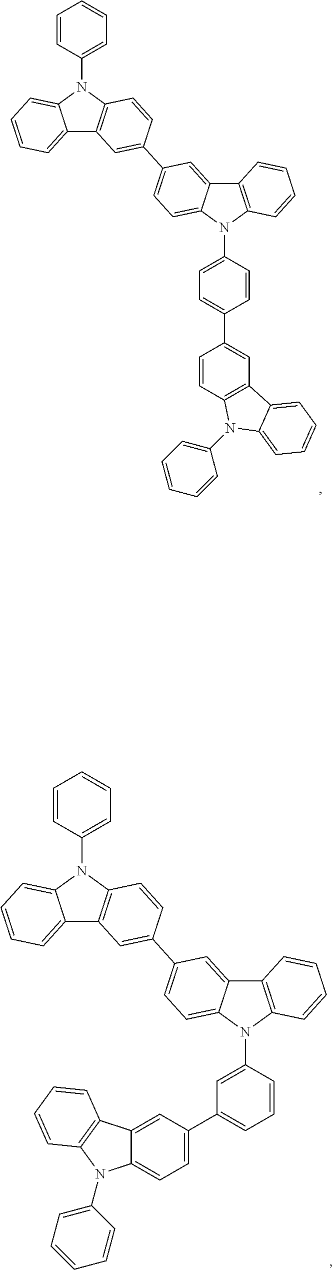 [SMILES: c1ccc(-n2c3ccccc3c3cc(-c4ccc(-n5c6ccccc6c6cc(-c7ccc8c(c7)c7ccccc7n8-c7ccccc7)ccc65)cc4)ccc32)cc1 ; c1ccc(-n2c3ccccc3c3cc(-c4cccc(-n5c6ccccc6c6cc(-c7ccc8c(c7)c7ccccc7n8-c7ccccc7)ccc65)c4)ccc32)cc1]

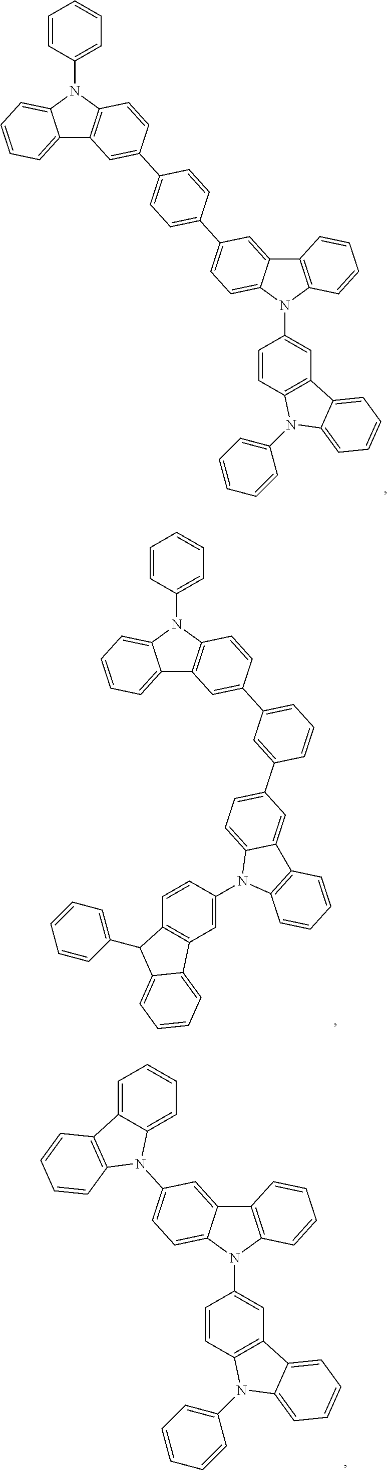

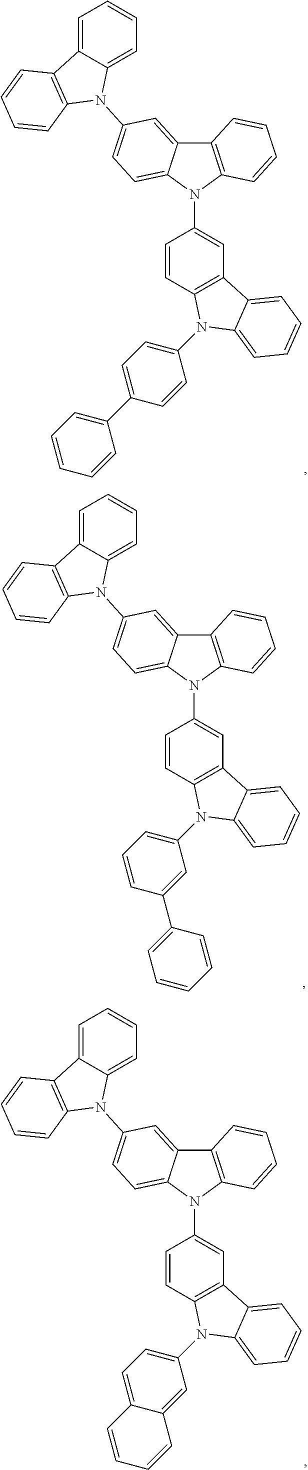

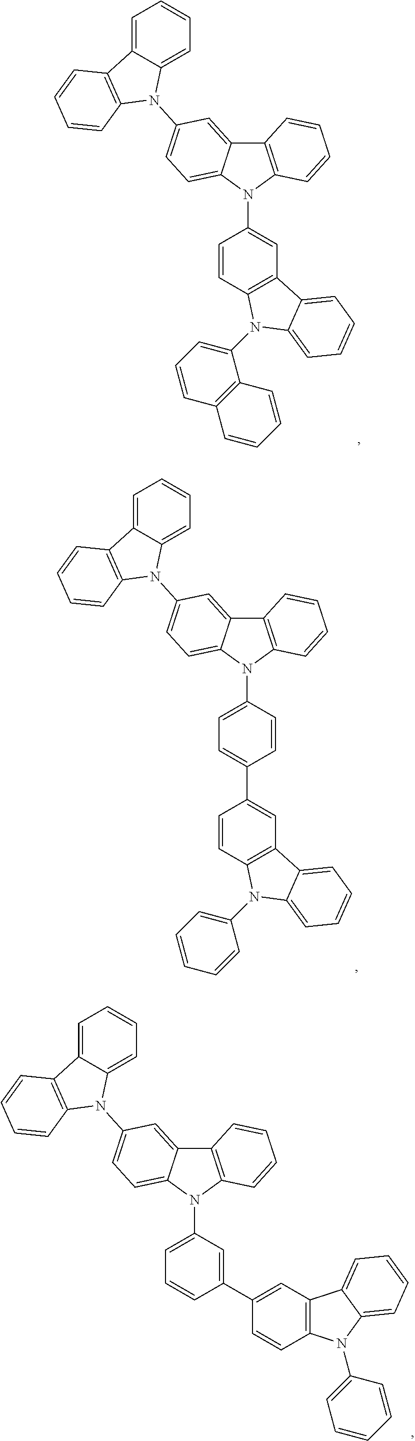 [SMILES: c1ccc2c(-n3c4ccccc4c4cc(-n5c6ccccc6c6cc(-n7c8ccccc8c8ccccc87)ccc65)ccc43)cccc2c1 ; c1ccc(-n2c3ccccc3c3cc(-c4ccc(-n5c6ccccc6c6cc(-n7c8ccccc8c8ccccc87)ccc65)cc4)ccc32)cc1 ; c1ccc(-n2c3ccccc3c3cc(-c4cccc(-n5c6ccccc6c6cc(-n7c8ccccc8c8ccccc87)ccc65)c4)ccc32)cc1]

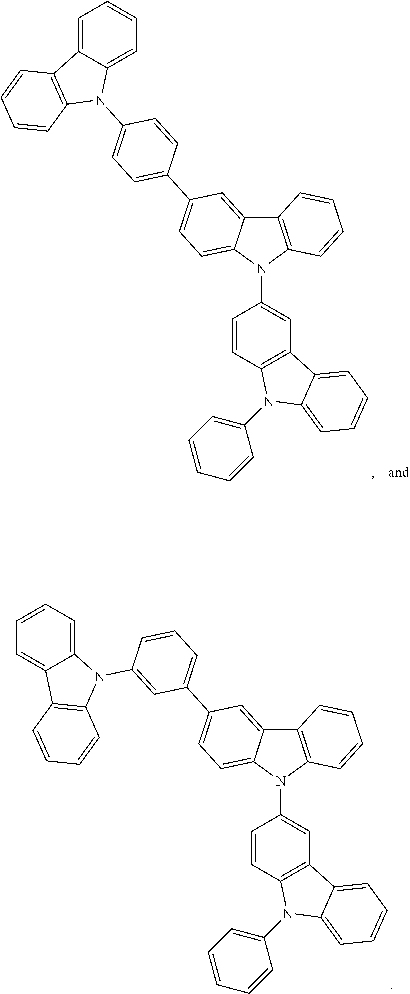 [SMILES: c1ccc(-n2c3ccccc3c3cc(-n4c5ccccc5c5cc(-c6ccc(-n7c8ccccc8c8ccccc87)cc6)ccc54)ccc32)cc1 ; c1ccc(-n2c3ccccc3c3cc(-n4c5ccccc5c5cc(-c6cccc(-n7c8ccccc8c8ccccc87)c6)ccc54)ccc32)cc1]

In some embodiments, the OLED further comprises a hole injecting layer that comprises a first hole injecting material.

In some embodiments of the OLED, the first emissive dopant comprises a fluorescent emissive dopant. In some embodiments of the OLED, the first emissive dopant comprises a delayed fluorescent emissive dopant.

In some embodiments, the OLED emits a luminescent radiation at room temperature when a voltage is applied across the OLED, where the luminescent radiation comprises a first radiation component from a fluorescent process.

In some embodiments, the OLED emits a luminescent radiation at room temperature when a voltage is applied across the OLED, where the luminescent radiation comprises a first radiation component from a delayed fluorescent process or triplet exciton harvesting process.

In some embodiments of the OLED, the EML further comprises a second emissive dopant that is a phosphorescent dopant, wherein the energy gap S₁-T₁ of the phosphorescent dopant is less than 500 meV.

In some embodiments of the OLED, the first emissive dopant comprises at least one electron donor group and at least one electron acceptor group.

In some embodiments of the OLED, the first emissive dopant is a metal complex. For phosphorescent emitters, metal complexes are preferred. In some preferred embodiments, the first emissive dopant is a Cu complex.

In some embodiments of the OLED, the first emissive dopant comprises a non-metal complex. For delayed fluorescent emitters, non-metal complexes are preferred.

In some embodiments of the OLED, the energy gap S₁-T₁ of the first emissive dopant is less than 200 meV.

In some embodiments of the OLED, the first emissive dopant comprises at least one of the chemical moieties selected from the group consisting of:

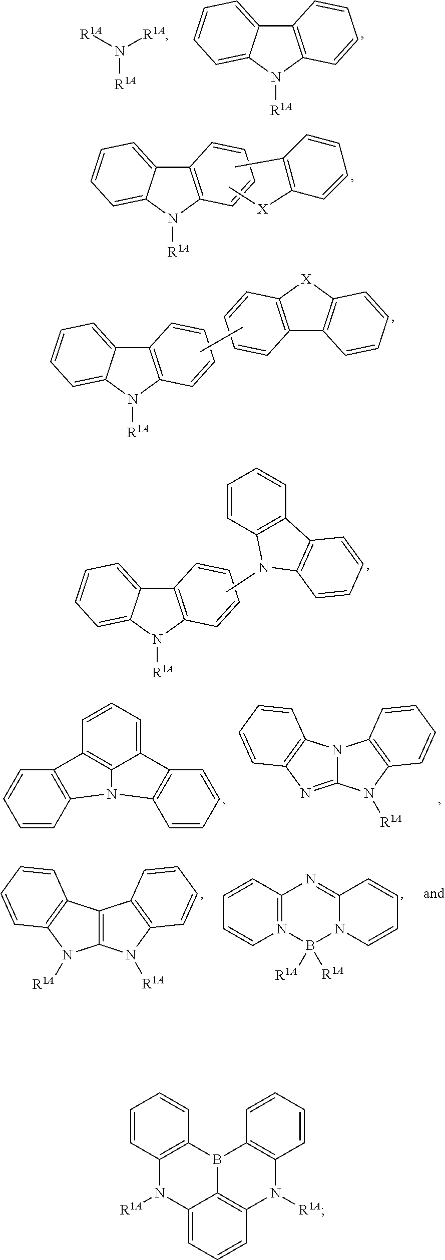

where X is selected from the group consisting of O, S, Se, and NR; and each R^{1A} can be the same or different and is an electron acceptor group, an organic linker bonded to the electron acceptor group, or a terminal group selected from the group consisting of alkyl, cycloalkyl, heteroalkyl, heterocycloalkyl, arylalkyl, aryl, heteroaryl, and combinations thereof.

In some embodiments of the OLED, the first emissive dopant comprises at least one of the chemical moieties selected from the group consisting of nitrile, isonitrile, borane, fluoride, pyridine, pyrimidine, pyrazine, triazine, aza-carbazole, aza-dibenzothiophene, aza-dibenzofuran, aza-dibenzoselenophene, aza-triphenylene, imidazole, pyrazole, oxazole, thiazole, isoxazole, isothiazole, triazole, thiadiazole, and oxadiazole.

In some embodiments of the OLED, the first emissive dopant comprises at least one organic group selected from the group consisting of:

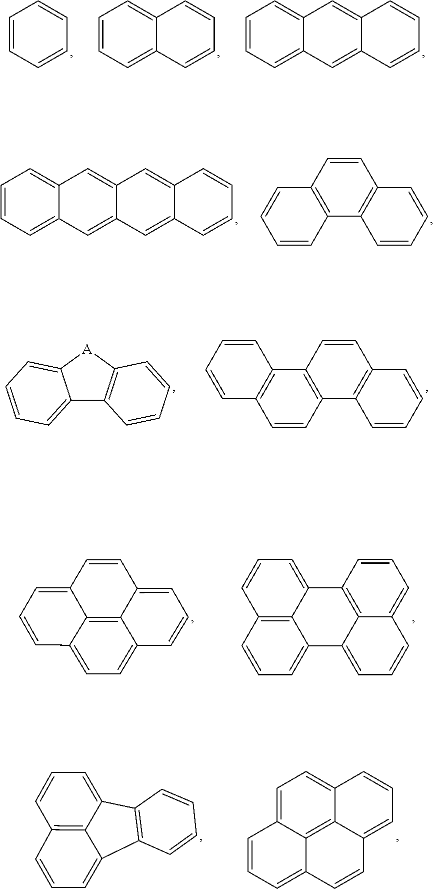

and aza analogues thereof; where, A is selected from the group consisting of O, S, Se, NR′ and CR′R″; R′ and R″ are independently selected from the group consisting of hydrogen, deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, boryl, and combinations thereof list; and two adjacent substituents of R′ and R″ are optionally joined to form a ring.

In some embodiments of the OLED, the first emissive dopant is selected from the group consisting of:

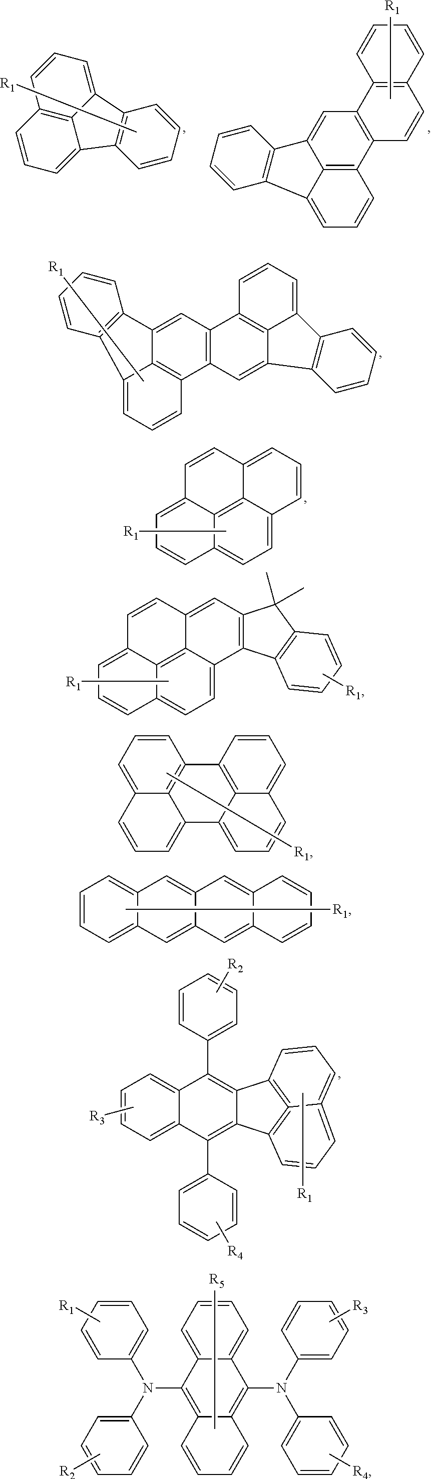

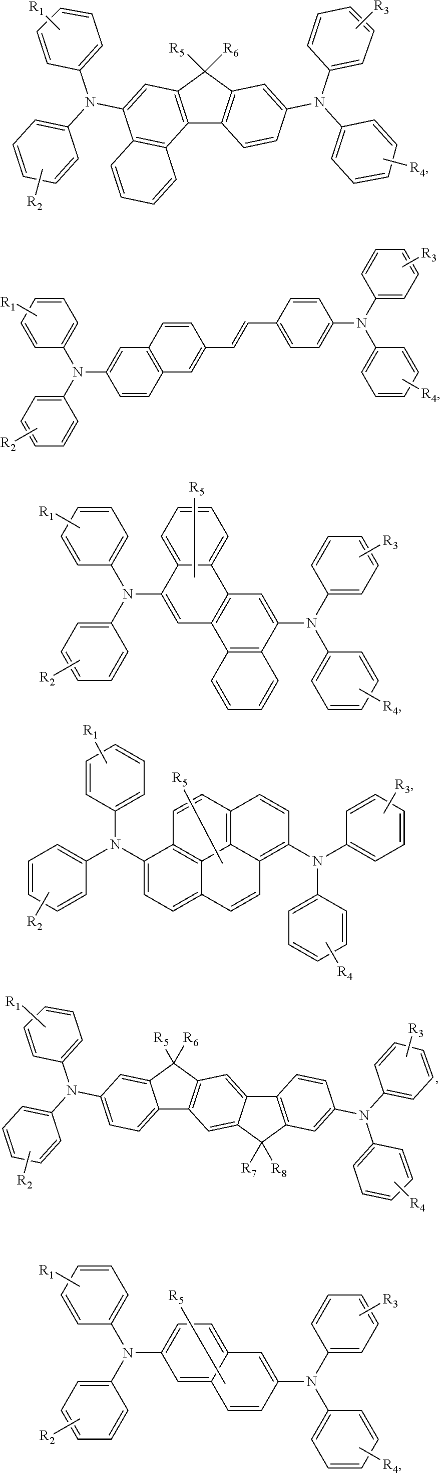

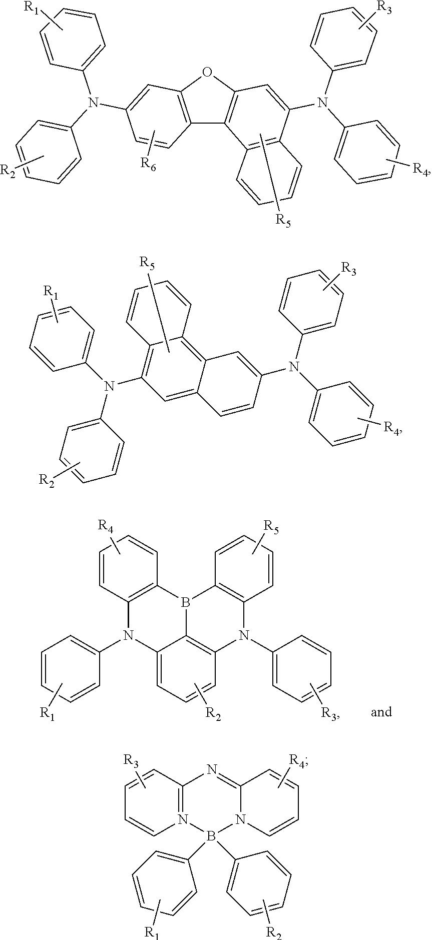

where each R₁ to R₈ independently represents from mono to the maximum allowable substitutions, or no substitution; each R₁ to R₈ is independently a hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, boryl, and combinations thereof; and any two substituents can be joined or fused to form a ring.

In some embodiments of the OLED, the first emissive dopant is a phosphorescent emitter. In some embodiments of the OLED, the first emissive dopant has the formula of M(L¹)ₓ(L²)_{y}(L³)_{z}; where, L¹, L² and L³ can be the same or different; x is 1, 2, or 3; y is 0, 1, or 2; z is 0, 1, or 2; x+y+z is the oxidation state of the metal M; L¹, L², and L³ are each independently selected from the group consisting of:

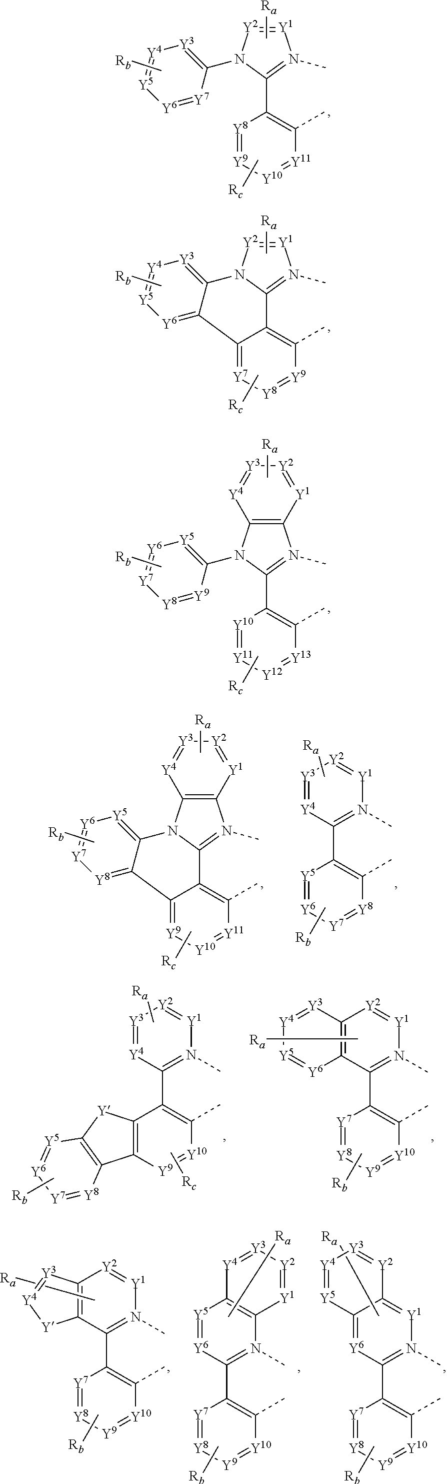

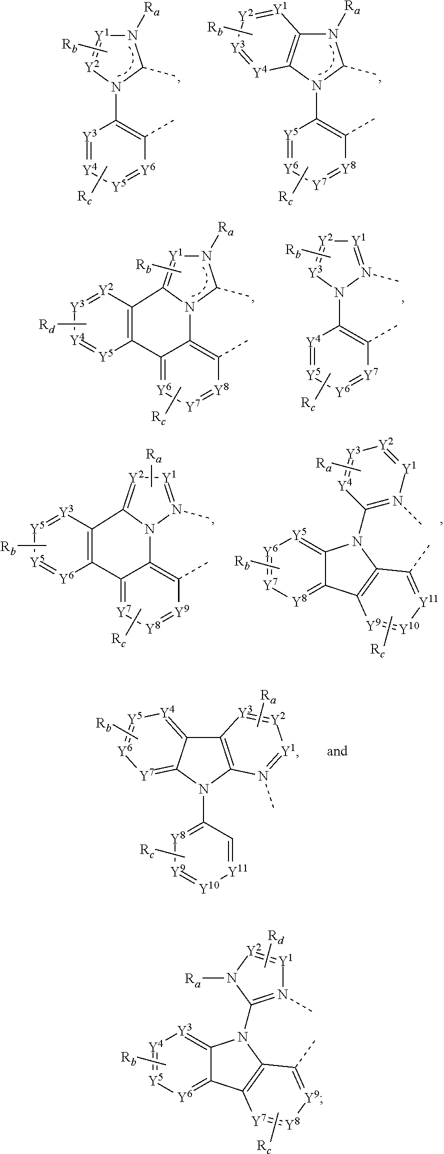

wherein each Y¹ to Y¹³ are independently selected from the group consisting of carbon and nitrogen; Y′ is selected from the group consisting of BRₑ, NRₑ, PRₑ, O, S, Se, C═O, S═O, SO₂, CRₑR_{f}, SiRₑR_{f}, and GeRₑR_{f}; Rₑ and R_{f} are optionally fused or joined to form a ring; each Rₐ, R_{b}, R_{c}, and R_{d} independently represent from zero, mono, or up to a maximum allowed substitution to its associated ring; Rₐ, R_{b}, R_{c}, R_{d}, Rₑ and R_{f} are each independently hydrogen or a substituent selected from the group consisting of the general substituents defined herein; and two adjacent substituents of Rₐ, R_{b}, R_{c}, and R_{d} are optionally fused or joined to form a ring or form a multidentate ligand.

In some embodiments of the OLED where the first emissive dopant has the formula of M(L¹)ₓ(L²)_{y}(L³)_{z}, the emitter can have the formula selected from the group consisting of Ir(L¹)(L²)(L³), Ir(L¹)₂(L²), and Ir(L¹)₃, where L¹, L², and L³ are different and each is independently selected from the group consisting of:

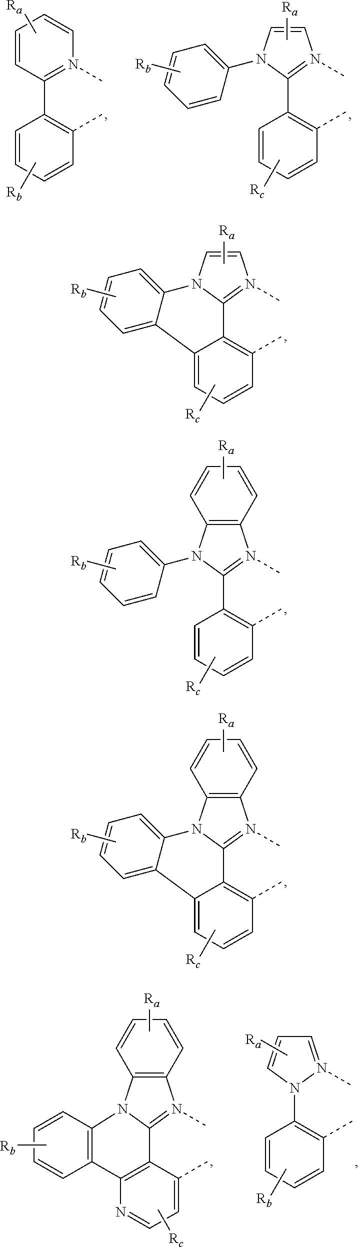

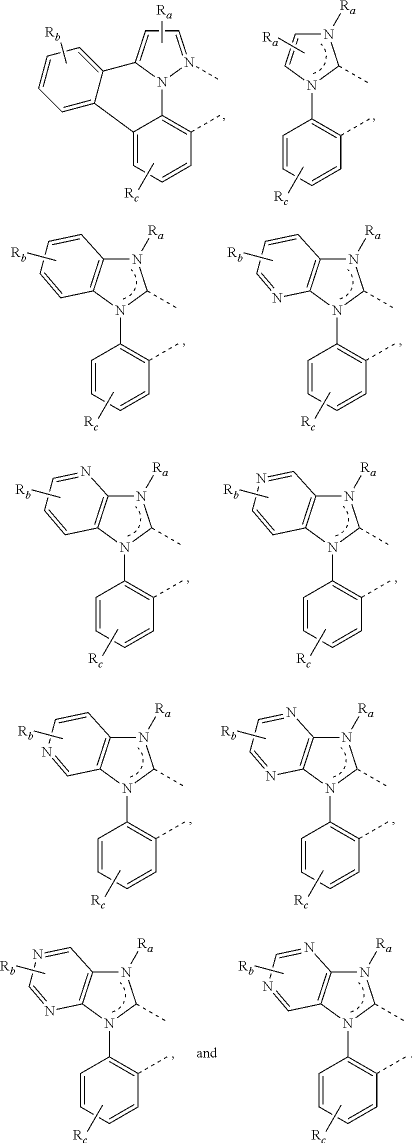

In some embodiments of the OLED where the first emissive dopant has the formula of M(L¹)ₓ(L²)_{y}(L³)_{z}, the first emissive dopant can have the formula of Pt(L¹)₂ or Pt(L¹)(L²) and L¹ and L² are each a different bidentate ligand. In some embodiments, L¹ is connected to the other L¹ or L² to form a tetradentate ligand. In some embodiments of the OLED, the first emissive dopant has the formula of M(L¹)₂ or M(L¹)(L²), where M is Ir, Rh, Re, Ru, or Os, and L¹ and L² are each a different tridentate ligand. In some embodiments of the OLED where the first emissive dopant has the formula of Pt(L¹)₂ or Pt(L¹)(L²), the emitter is selected from the group consisting of:

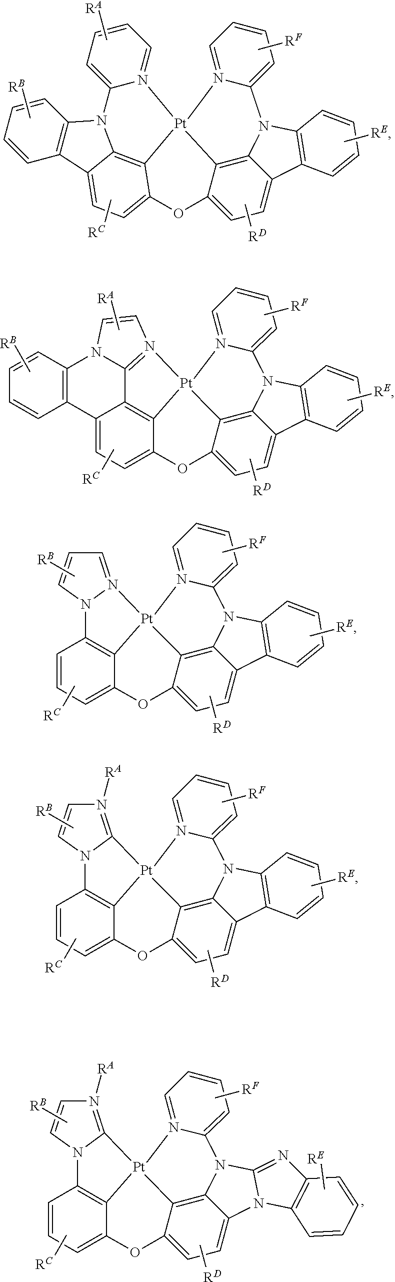

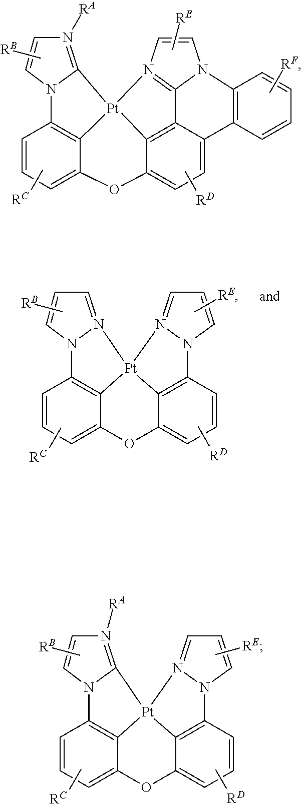

where each R^{A} to R^{F} may represent from mono substitution to the possible maximum number of substitution, or no substitution; R^{A} to R^{F} are each independently a hydrogen or a substitution selected from the group consisting of the general substituents defined herein; and any two R^{A} to R^{F} are optionally fused or joined to form a ring or form a multidentate ligand.

In some embodiments of the OLED, the EML can further comprise a host.

In some embodiments of the OLED, the EBL has a thickness greater than or equal to 1 nm and less than or equal to 100 nm. In some embodiments, the EBL has a thickness greater than or equal to 1 nm and less than or equal to 30 nm. In some embodiments, the EBL has a thickness greater than or equal to 1 nm and less than or equal to 25 nm. In some embodiments, the EBL preferably has a thickness greater than or equal to 1 nm and less than or equal to 20 nm.

In some embodiments of the OLED, the HTL does not include a compound of Formula I or Formula II.

In some embodiments of the OLED, the first emissive dopant comprises a phosphorescent emissive dopant. In some embodiments, the first emissive dopant can be selected from the group consisting of a phosphorescent emitter, a fluorescent emitter, and a TADF emitter, or the first emissive dopant can comprise a combination of these emitter classes.

### C. Embodiment of OLED with a Sensitizer

In some embodiments of the OLED, the first emissive dopant in the EML is an electron acceptor and the EML further comprises a phosphorescent dopant that functions as a sensitizer. The presence of the sensitizer in the OLED is primarily to improve harvesting excitons from the EML and does not directly emit light. In some embodiments of the sensitized OLED, the first emissive dopant is a phosphorescent emissive dopant, and the emissive region further comprises a second phosphorescent dopant whose energy gap S₁-T₁ is less than 400 meV that functions as the sensitizer. The second phosphorescent dopant functions as a sensitizer in the OLED and only contributes no more than 10% of the total emission from the EML in the OLED and preferably <5% of the total emission from the EML in the OLED. Sensitizers generally improves harvesting excitons from EML and improve the EQE of the OLED. In some embodiments, the second phosphorescent dopant has an energy gap S₁-T₁ of less than 300 meV. In some embodiments, the second phosphorescent dopant has an energy gap S₁-T₁ of less than 200 meV In some embodiments, the second phosphorescent dopant has an energy gap S₁-T₁ of less than 100 meV. The second phosphorescent dopant can be in the EML or it can be provided in the emissive region in a separate layer from the EML.

In some embodiments, the OLED can further comprise a hole injecting layer (HIL) between the anode and the HTL. In some embodiments, the OLED can further comprise a HBL between the emissive region and the cathode.

In some embodiments of the OLED, preferably, the EBL is in direct contact with the emissive region. In some embodiments of the OLED, the EBL material has a T₁ energy greater than the T₁ energy of the first emissive dopant. In some embodiments of the OLED, the EBL material has a S₁ energy greater than the S₁ energy of the first emissive dopant. In some embodiment of OLED, the EBL material has a LUMO energy higher than the LUMO energy of the first emissive dopant. In some embodiments, the EML comprises a host and the EML is the only layer in the emissive region; wherein the EBL material has a LUMO energy higher than the LUMO energy of the host.

In some embodiments of the sensitized OLED in which the first emissive dopant in the EML is an acceptor and the EML further comprises a phosphorescent dopant as a sensitizer, the first emissive dopant and the sensitizer are present in the EML as a mixture.

In some embodiments of the sensitized OLED, the first emissive dopant in the EML is an acceptor and the EML further comprises a first host material, and the emissive region of the OLED further comprises a sensitizing layer in direct contact with the EML. The sensitizing layer comprises a phosphorescent dopant that functions as a sensitizer and a second host material. In these embodiments, the EML and the sensitizing layer are separate layers in the emissive region.

In some embodiments of the sensitized OLED in which the emissive dopant and the sensitizer are in separate layers, the emissive region can include a plurality of EMLs and sensitizing layers provided in an alternating arrangement. Each of the plurality of the EMLs includes a first host material and each of the plurality of the sensitizing layers includes a second host material. The first and second host materials can be the same or different.

In some embodiments of the sensitized OLED where the EML and the sensitizing layer are provided as separate adjacent layers, the total number of the EML can be the same as that of the sensitizing layers. In some embodiments, the total number of the EML can be one more or one less than the total number of the sensitizing layers. In some embodiments, the total number of alternating layers of the EMLs and the sensitizing layers in the emissive region can range from 2 to 10, preferably from 2 to 5, and more preferably from 2 to 4, or 2 to 3.

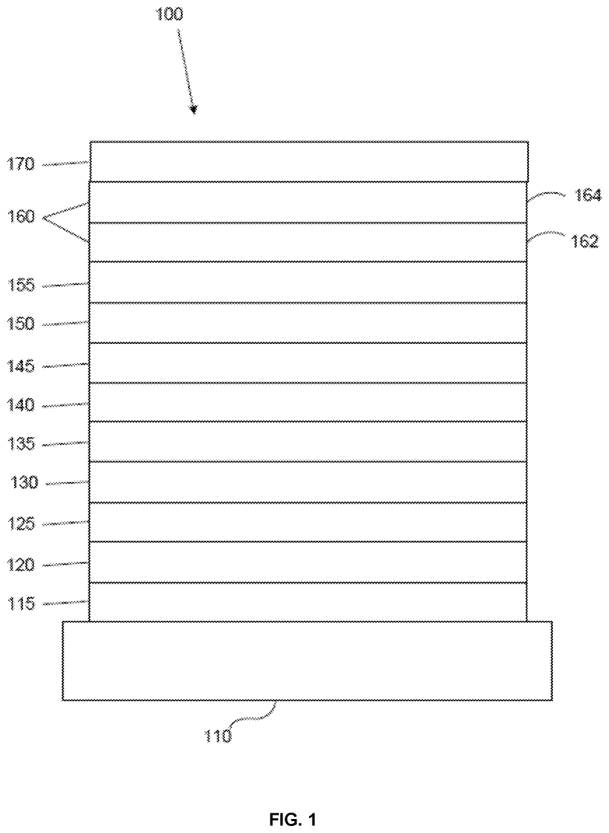

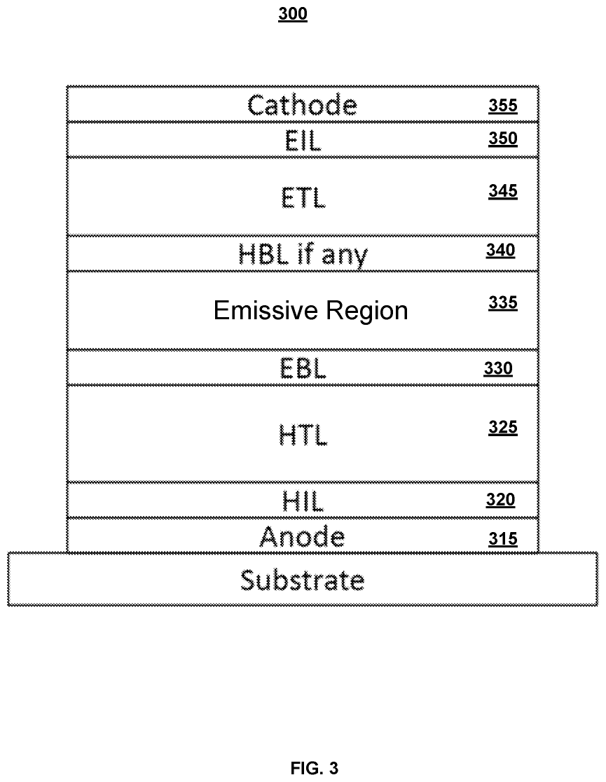

As mentioned herein with respect to OLEDs in general, in some embodiments of the sensitized OLED, the OLED can further comprise one or more of other optional functional layers such as an HIL, a HBL, an ETL, and an electron injecting layer (EIL). The positions of these functional layers in relation to the anode, cathode, and the EML in an OLED are illustrated in FIGS. 1 and 3.

In some embodiments of the sensitized OLED where the emissive region includes a plurality of EMLs and sensitizing layers provided in a stack of alternating arrangement, the host material in each of the bottom-most layer and the top-most layer of the stack can be the same material that is used in the layer adjacent to the emissive region. This applies regardless of whether the bottom-most layer and the top-most layer are the EML or the sensitizing layer. For example, in the example OLED 300 shown in FIG. 3, if the emissive region 335 is comprised of a plurality of alternating EMLs and sensitizing layers, the host material in the bottom-most layer on the anode side of the emissive region 335 (regardless of whether the bottom-most layer is an EML or a sensitizing layer), can be the electron/exciton blocking material used in the EBL 330. On the cathode side of the emissive region 335, the host material in the top-most layer on the cathode side of the emissive region 335 (regardless of whether the top-most layer is an EML or a sensitizing layer), can be the hole/exciton blocking material used in the HBL 340, if the HBL 340 is present next to the emissive region 335. If the HBL is not present, the host material in the top-most layer on the cathode side of the emissive region 335 would be the electron transporting material used in the ETL 345.

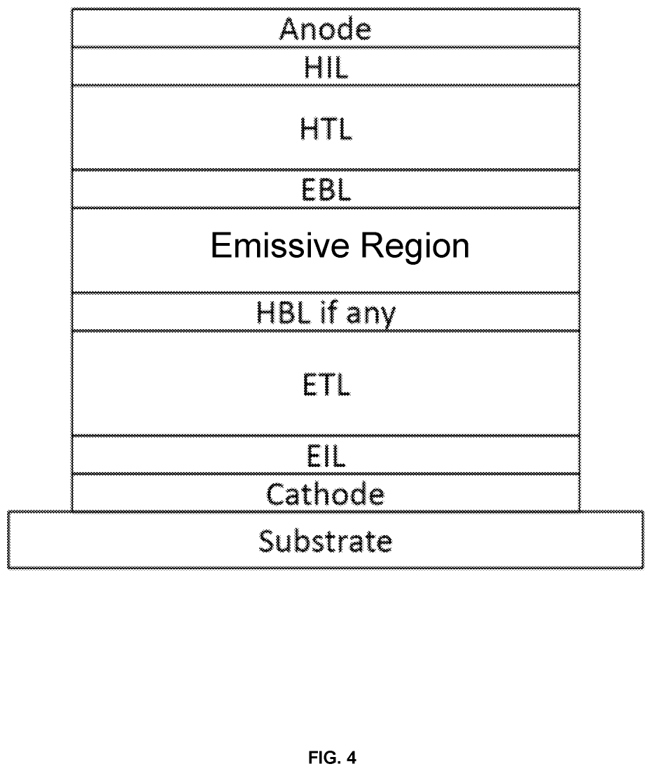

FIG. 4 shows a cross-section of an example of an inverted OLED structure where the cathode is deposited on the substrate first. The sequence of the functional layers of the OLED is the same as that in the OLED shown in FIG. 3 but in reverse order starting from the cathode layer. As in the OLED structure in FIG. 3, the EBL of the present disclosure is provided between the HTL and the EML.

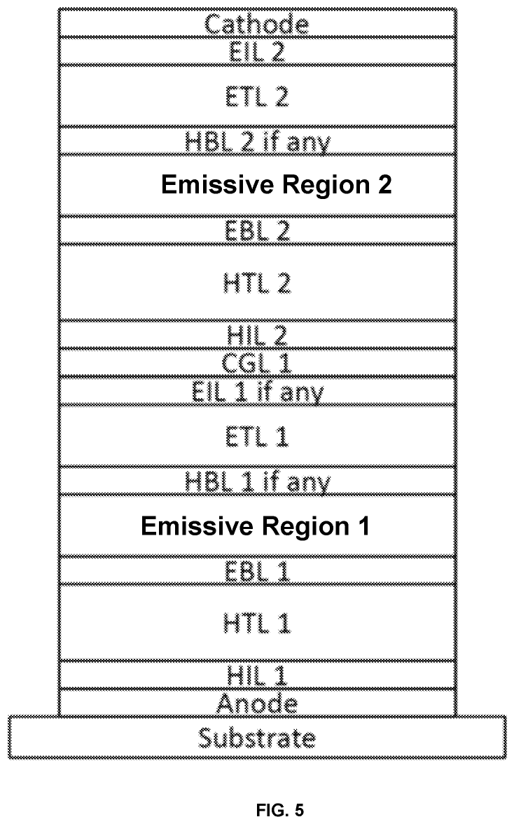

FIG. 5 shows a cross-section of an example of a tandem stacked OLED structure in which two sets of Emissive Region/EBL/HTL combination layers stacked on top of one another form the OLED. The EBL of the present disclosure is between the HTL and the Emissive Region in each set. In addition to the Emissive Region/EBL/HTL combination of layers, FIG. 5 shows additional functional layers that can be included in OLEDs as well understood by those skilled in the art.

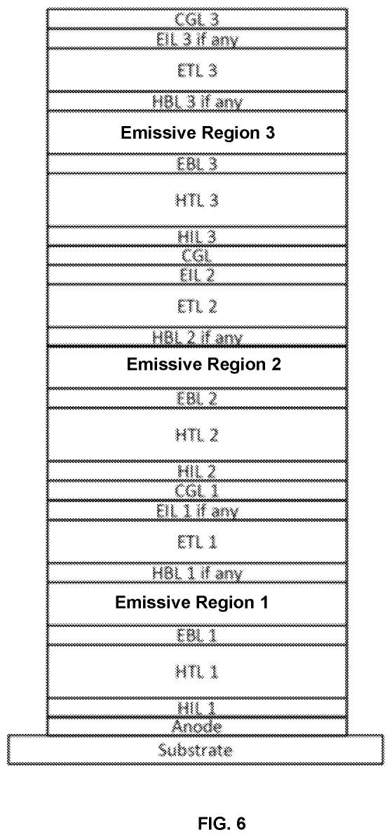

FIG. 6 shows a cross-section of another example of a stacked OLED structure in which three sets of Emissive Region/EBL/HTL combination layers stacked form the OLED. The EBL of the present disclosure is between the HTL and the Emissive Region in each set. As in the other illustrations of OLED examples, additional functional layers that can be included in OLEDs are shown.

### D. Pixel of a Display Device Embodiments

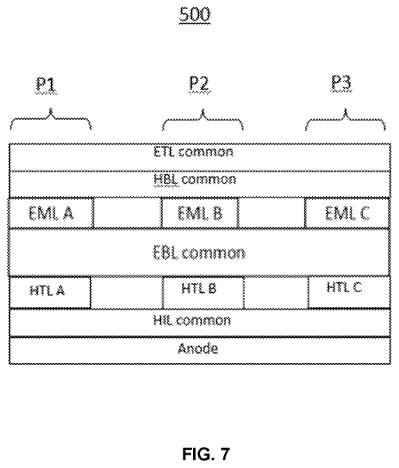

Referring to FIG. 7, according to another aspect, a cross-section of a portion of an example of a pixel in a display device 500 comprising a first pixel comprising a first OLED P1; and a second pixel comprising a second OLED P2 is disclosed. In the display device 500, 3 sub-pixels of different color are formed by the 3 OLED structures P1, P2, and P3 where one common continuous EBL comprising the electron/exciton blocking material of the present disclosure extends across the 3 OLED structures between their EML and HTL.

The OLED 300 in FIG. 3 are representative of an example of the three OLED structures P1, P2, and P3. Each OLED independently can comprise, sequentially: an anode 315; an HTL 325 comprising a hole transporting material; an EBL 330 comprising an electron/exciton blocking material; an emissive region 335 comprising an EML that comprises an emissive dopant; and a cathode 355. Returning to FIG. 7, the EML A of the first OLED P1, the EML B of the second OLED P2, and the EML C of the third OLED P3 have different emissive dopants resulting in the three OLEDs having different emission spectra.

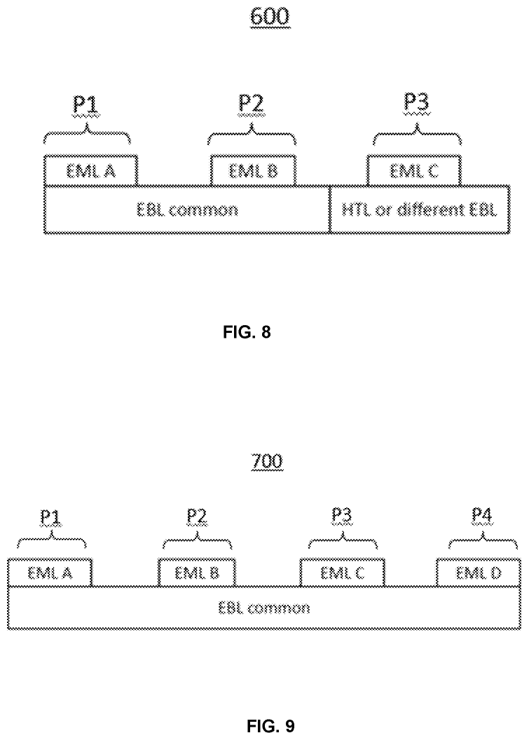

FIG. 8 shows a cross-section of a portion of another example of a pixel in a display device 600 in which 3 sub-pixels of different color are formed by 3 OLED structures P1, P2, P3 where one common EBL of the present disclosure extends across 2 adjacent OLED structures P1 and P2 of the 3 OLEDs. The common EBL is in direct contact with the EML A and EML B of the two OLEDs P1, P2, respectively. The third OLED P3 can have an EBL of a different electron/exciton blocking material or not have an EBL, in which case the third OLED P3 can have an HTL at the same location rather than an EBL.

FIG. 9 shows a cross-section of a portion of another example of a pixel in a display device 700 in which 4 sub-pixels of different color are formed by 4 OLED structures P1, P2, P3, P4 where one common EBL of the present disclosure extends across the 4 OLED structures. The common EBL is in direct contact with the EML A, EML B, EML C, and EML D of the 4 OLED structures P1, P2, P3, P4, respectively.

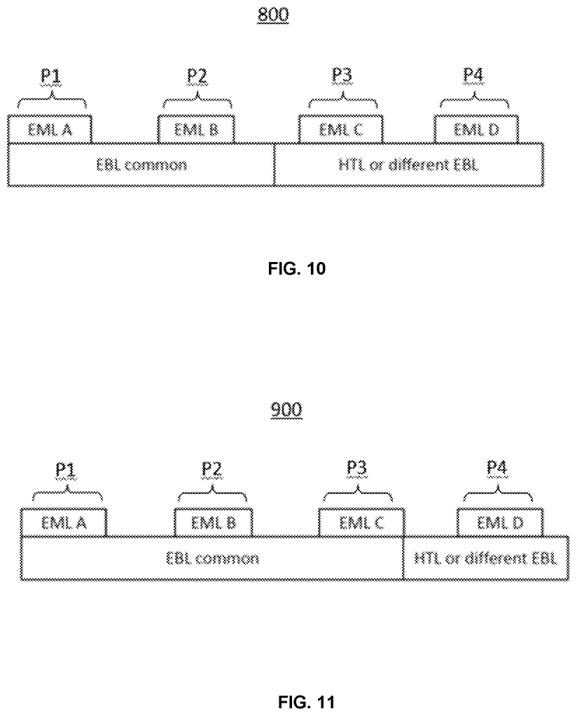

FIG. 10 shows a cross-section of a portion of another example of a pixel in a display device 800 in which 4 sub-pixels of different color are formed by 4 OLED structures P1, P2, P3, P4 where one common EBL of the present disclosure extends across 2 adjacent OLED structures P1, P2 of the 4 OLEDs. The common EBL is in direct contact with the EML A and EML B of the two OLEDs P1, P2, respectively. The remaining two OLEDs P3, P4 can have an EBL of a different electron/exciton blocking material extending across both OLEDs P3, P4 or not have an EBL, in which case the third and fourth OLEDs P3, P4 can have a common HTL at the same location rather than an EBL.

FIG. 11 shows a cross-section of a portion of another example of a pixel in a display device 900 in which 4 sub-pixels of different color are formed by 4 OLED structures P1, P2, P3, P4 where one common EBL of the present disclosure extends across 3 adjacent OLED structures P1, P2, P3 of the 4 OLEDs. The common EBL is in direct contact with the EML A, EML B, and EML C of the three OLEDs P1, P2, P3, respectively. The remaining fourth OLED P4 can have an EBL of a different electron/exciton blocking material or not have an EBL, in which case the fourth OLED P4 can have an HTL at the same location rather than an EBL.

In the display devices 500, 600, 700, 800, 900, the electron/exciton blocking material is a compound of

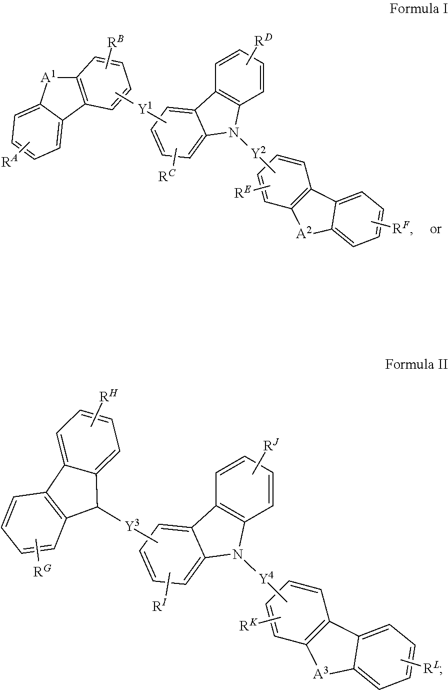

wherein, A¹, A², and A³ are each independently selected from the group consisting of O, S, and NR; Y¹, Y², Y³, and Y⁴ are each independently a direct bond, O, S, NR, or an organic linker comprising 1 to 18 carbon atoms; R^{A} to R^{L} each independently represents mono to the maximum allowable substitutions, or no substitution; each R, R^{A} to R^{L} is independently a hydrogen or a substituent selected from the group consisting of the general substituents defined herein; and any two substituents can be joined or fused together to form a ring.

In the embodiments of the display device comprising multiple OLED structures of different color forming sub-pixels of a pixel in the display device, such as illustrated in FIGS. 7-11, where two or more of those multiple OLEDs share a common EBL, the OLEDs sharing the common EBL preferably have the same sequence of functional layers in the OLED stack to make the fabrication process practical as each layers in the OLED stack are deposited.

In some embodiments of the display device having a pixel formed by two or more OLEDs forming sub-pixels that emit different color, the EML of a first OLED can emits light having a peak wavelength in the visible spectrum of 400-500 nm and the EML of the second OLED can emit light having a peak wavelength in the visible spectrum of 500-700 nm.

In some embodiments of the display device having a pixel formed by three OLEDs forming sub-pixels that emit different color, the EML of a first OLED can emit light having a peak wavelength in the visible spectrum of 400-500 nm, the EML of the second OLED can emit light having a peak wavelength in the visible spectrum of 500-600 nm, and the EML of the third OLED can emit light having a peak wavelength in the visible spectrum of 600-700 nm.

In some embodiments of the display device having a pixel formed by two or more OLEDs forming sub-pixels that emit different color, the emissive dopant in the EML of a first OLED and the emissive dopant in the EML of a second OLED can independently be a phosphorescent material.

In some embodiments of the display device having a pixel formed by two or more OLEDs forming sub-pixels that emit different color, the emissive dopant in the EML of a first OLED can be a fluorescent or a delayed fluorescent material and the emissive dopant in the EML of a second OLED can be a phosphorescent material.

In some embodiments of the display device having a pixel formed by two or more OLEDs forming sub-pixels that emit different color, the emissive dopant in the EML of a first OLED and the emissive dopant in the EML of a second OLED can independently be a fluorescent or a delayed fluorescent material.

In some embodiments of the display device having a pixel formed by two or more OLEDs forming sub-pixels that emit different color, the emissive dopants of the two or more OLEDs can all be phosphorescent materials.

In some embodiments of the display device having a pixel formed by two or more OLEDs forming sub-pixels that emit different color, the emissive dopant of at least one of the two or more OLEDs can be a phosphorescent material; and the emissive dopant of at least one of the other of the two or more OLEDs can be a fluorescent or a delayed fluorescent material.

The embodiments of the display device having a pixel formed by two or more OLEDs forming sub-pixels that emit different color described herein can have three OLEDs forming three sub-pixels that form the one pixel or can have four OLEDs forming four sub-pixels that form the one pixel.

In some embodiments of the display device having a pixel formed by two or more OLEDs forming sub-pixels that emit different color, the two or more OLEDs comprise the same sequence of layers and the two or more OLEDs all share one common EBL comprising one electron/exciton blocking material.

All of the embodiments of an OLED structure comprising an EBL of the electron/exciton blocking material of the present disclosure disclosed herein are equally applicable to any of the OLEDs that form sub-pixels in the display device embodiments in which the OLEDs comprise an EBL. Additionally, all of the embodiments of a sensitized OLED structure with EBL or without EBL disclosed herein are equally applicable to any of the OLEDs that form sub-pixels in the display device embodiments disclosed herein. For example, in FIGS. 7-11 showing examples of the display devices, each OLED portions show EMLs labeled as EML A, EML B, EML C, or EML D. Each of those EMLs represent emissive regions comprising one emissive layer or a plurality of emissive layers containing emissive dopants as well as one or more sensitizing layers according to the sensitized OLED embodiments disclosed herein.

According to another aspect, a method of depositing a device is disclosed, where the device comprises: a first pixel comprising a first OLED; a second pixel comprising a second OLED; wherein each OLED independently comprises, sequentially: an anode; a HTL comprising a hole transporting material; an EBL comprising an electron/exciton blocking material; an EML comprising an emissive dopant; and a cathode; where the EML of the first OLED and the EML of the second OLED have different emissive dopants resulting in the two OLEDs having different emission spectra; wherein the EBLs of the first and second OLEDs comprise the same electron/exciton blocking material; the method comprises: depositing a single continuous layer of the EBL where a first portion of the single continuous layer is the EBL of the first OLED and a second portion of the single continuous layer is the EBL of the second OLED.

The single continuous layer of EBL can be shared by all pixels in a display device or as many as desired. One, two, three, or four select color type of color pixels (e.g., blue) can share a continuous EBL material layer. All pixels on the display device can share the single continuous layer of EBL material but the thickness of the EBL material can be different for different color types. The single continuous EBL of the disclosed compositions work for both phosphorescent and fluorescent emitters, as well as TADF emitters.

In some embodiments of the method, the device further comprises additional pixels, wherein each additional pixel comprises an OLED that shares the single continuous layer of EBL.

According to another aspect, the present disclosure also provides a consumer product comprising an OLED of the present disclosure. Such consumer product comprises an OLED comprising sequentially: an anode; a hole transporting layer comprising a first hole transporting material; an EBL comprising an electron/exciton blocking material; an emissive region comprising an EML that comprises a first emissive dopant; and a cathode, wherein the electron/exciton blocking material comprising a compound of

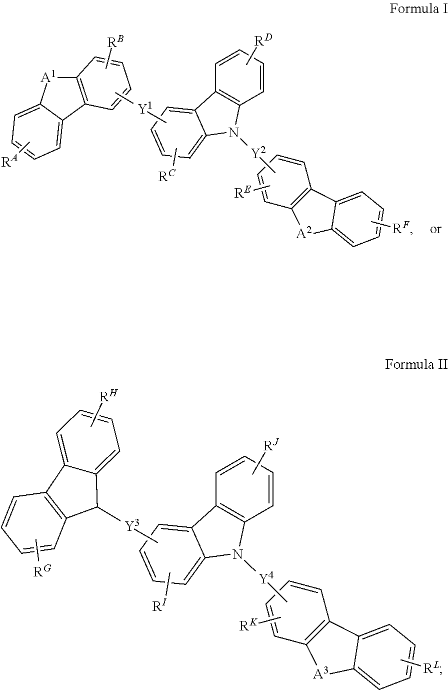

wherein, A¹, A², and A³ are each independently selected from the group consisting of O, S, and NR; Y¹, Y², Y³, and Y⁴ are each independently a direct bond, O, S, NR, or an organic linker comprising 1 to 18 carbon atoms; R^{A} to R^{L} each independently represents mono to the maximum allowable substitutions, or no substitution; each R, R^{A} to R^{L} is independently a hydrogen or a substituent selected from the group consisting of the general substituents defined herein; and any two substituents can be joined or fused together to form a ring.

In some embodiments, the consumer product can be one of a flat panel display, a computer monitor, a medical monitor, a television, a billboard, a light for interior or exterior illumination and/or signaling, a heads-up display, a fully or partially transparent display, a flexible display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video wall comprising multiple displays tiled together, a theater or stadium screen, a light therapy device, and a sign.

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

Several OLED materials and configurations are described in U.S. Pat. Nos. 5,844,363, 6,303,238, and 5,707,745, which are incorporated herein by reference in their entirety.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated herein by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

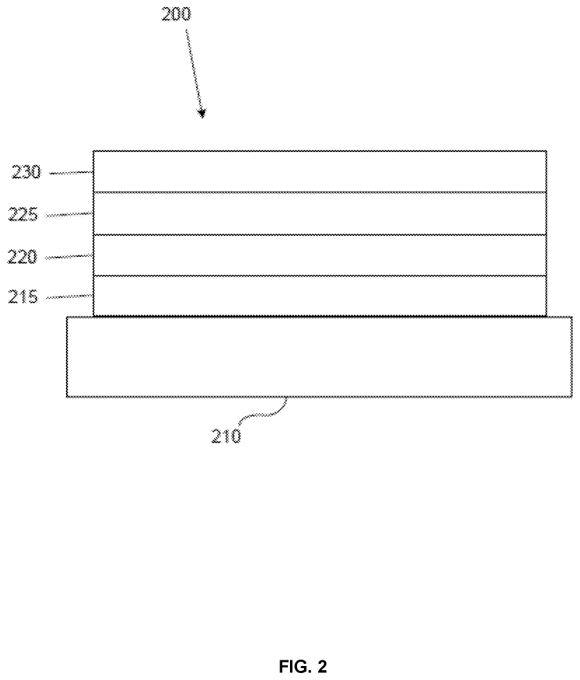

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the present disclosure may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and organic vapor jet printing (OVJP). Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons are a preferred range. Materials with asymmetric structures may have better solution processability than those having symmetric structures, because asymmetric materials may have a lower tendency to recrystallize. Dendrimer substituents may be used to enhance the ability of small molecules to undergo solution processing.

Devices fabricated in accordance with embodiments of the present disclosure may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the present disclosure can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the present disclosure can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include flat panel displays, curved displays, computer monitors, medical monitors, televisions, billboards, lights for interior or exterior illumination and/or signaling, heads-up displays, fully or partially transparent displays, flexible displays, rollable displays, foldable displays, stretchable displays, laser printers, telephones, mobile phones, tablets, phablets, personal digital assistants (PDAs), wearable devices, laptop computers, digital cameras, camcorders, viewfinders, micro-displays (displays that are less than 2 inches diagonal), 3-D displays, virtual reality or augmented reality displays, vehicles, video walls comprising multiple displays tiled together, theater or stadium screen, a light therapy device, and a sign. Various control mechanisms may be used to control devices fabricated in accordance with the present disclosure, including passive matrix and active matrix. Many of the devices are intended for use in a temperature range comfortable to humans, such as 18° C. to 30° C., and more preferably at room temperature (20-25° C.), but could be used outside this temperature range, for example, from −40° C. to +80° C.

More details on OLEDs, and the definitions described above, can be found in U.S. Pat. No. 7,279,704, which is incorporated herein by reference in its entirety.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence; see, e.g., U.S. application Ser. No. 15/700,352, which is hereby incorporated by reference in its entirety), triplet-triplet annihilation, or combinations of these processes. In some embodiments, the emissive dopant can be a racemic mixture, or can be enriched in one enantiomer. In some embodiments, the compound can be homoleptic (each ligand is the same). In some embodiments, the compound can be heteroleptic (at least one ligand is different from others). When there are more than one ligand coordinated to a metal, the ligands can all be the same in some embodiments. In some other embodiments, at least one ligand is different from the other ligands. In some embodiments, every ligand can be different from each other. This is also true in embodiments where a ligand being coordinated to a metal can be linked with other ligands being coordinated to that metal to form a tridentate, tetradentate, pentadentate, or hexadentate ligands. Thus, where the coordinating ligands are being linked together, all of the ligands can be the same in some embodiments, and at least one of the ligands being linked can be different from the other ligand(s) in some other embodiments.

In some embodiments, the compound can be used as one component of an exciplex to be used as a sensitizer.

In some embodiments, the sensitizer is a single component, or one of the components to form an exciplex.

According to another aspect, a formulation comprising the compound described herein is also disclosed.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

In yet another aspect of the present disclosure, a formulation that comprises the novel compound disclosed herein is described. The formulation can include one or more components selected from the group consisting of a solvent, a host, a hole injection material, hole transport material, electron blocking material, hole blocking material, and an electron transport material, disclosed herein.

The present disclosure encompasses any chemical structure comprising the novel compound of the present disclosure, or a monovalent or polyvalent variant thereof. In other words, the inventive compound, or a monovalent or polyvalent variant thereof, can be a part of a larger chemical structure. Such chemical structure can be selected from the group consisting of a monomer, a polymer, a macromolecule, and a supramolecule (also known as supermolecule). As used herein, a “monovalent variant of a compound” refers to a moiety that is identical to the compound except that one hydrogen has been removed and replaced with a bond to the rest of the chemical structure. As used herein, a “polyvalent variant of a compound” refers to a moiety that is identical to the compound except that more than one hydrogen has been removed and replaced with a bond or bonds to the rest of the chemical structure. In the instance of a supramolecule, the inventive compound can also be incorporated into the supramolecule complex without covalent bonds.

### D. Combination of the Compounds of the Present Disclosure with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

### a) Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

Non-limiting examples of the conductivity dopants that may be used in an OLED in combination with materials disclosed herein are exemplified below together with references that disclose those materials: EP01617493, EP01968131, EP2020694, EP2684932, US20050139810, US20070160905, US20090167167, US2010288362, WO06081780, WO2009003455, WO2009008277, WO2009011327, WO2014009310, US2007252140, US2015060804, US20150123047, and US2012146012.

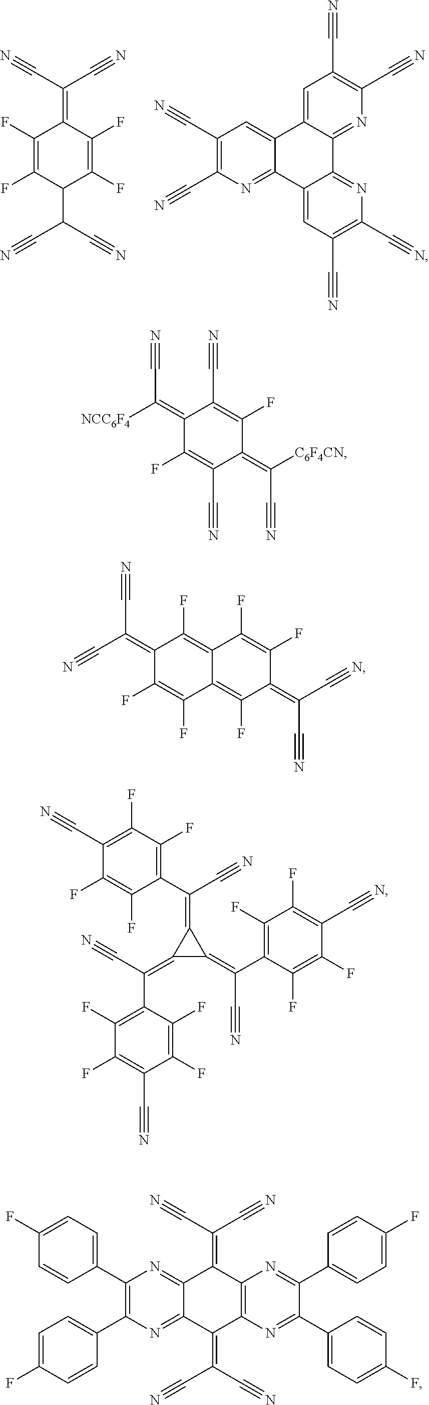

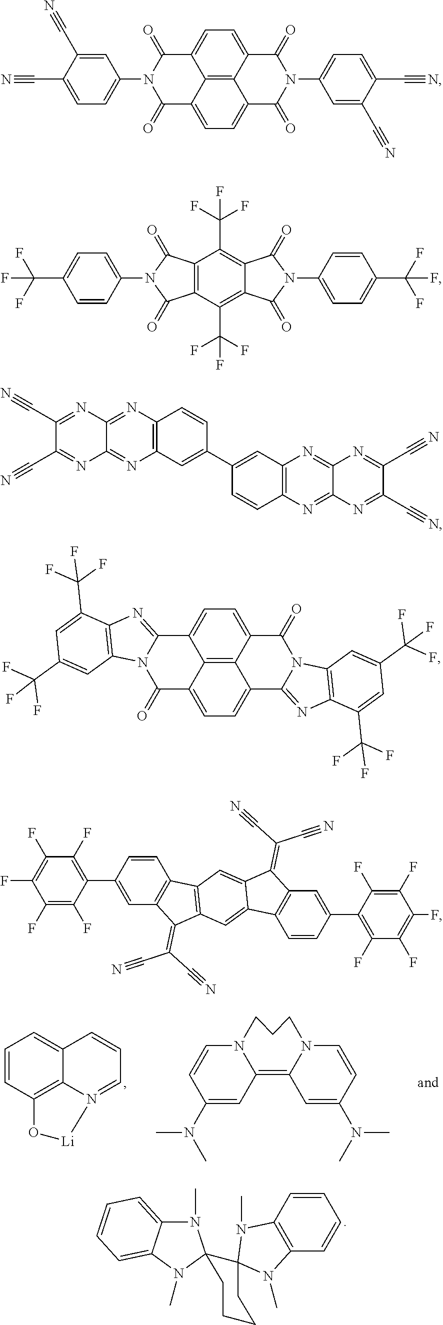

### b) HIL/HTL:

A hole injecting/transporting material to be used in the present disclosure is not particularly limited, and any compound may be used as long as the compound is typically used as a hole injecting/transporting material. Examples of the material include, but are not limited to: a phthalocyanine or porphyrin derivative; an aromatic amine derivative; an indolocarbazole derivative; a polymer containing fluorohydrocarbon; a polymer with conductivity dopants; a conducting polymer, such as PEDOT/PSS; a self-assembly monomer derived from compounds such as phosphonic acid and silane derivatives; a metal oxide derivative, such as MoOₓ; a p-type semiconducting organic compound, such as 1,4,5,8,9,12-Hexaazatriphenylenehexacarbonitrile; a metal complex, and a cross-linkable compounds.

Examples of aromatic amine derivatives used in HIL or HTL include, but not limit to the following general structures:

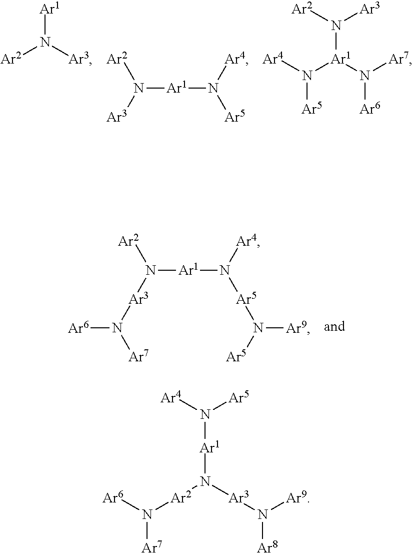

Each of Ar¹ to Ar⁹ is selected from the group consisting of aromatic hydrocarbon cyclic compounds such as benzene, biphenyl, triphenyl, triphenylene, naphthalene, anthracene, phenalene, phenanthrene, fluorene, pyrene, chrysene, perylene, and azulene; the group consisting of aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine; and the group consisting of 2 to 10 cyclic structural units which are groups of the same type or different types selected from the aromatic hydrocarbon cyclic group and the aromatic heterocyclic group and are bonded to each other directly or via at least one of oxygen atom, nitrogen atom, sulfur atom, silicon atom, phosphorus atom, boron atom, chain structural unit and the aliphatic cyclic group. Each Ar may be unsubstituted or may be substituted by a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof.

In one aspect, Ar¹ to Ar⁹ is independently selected from the group consisting of:

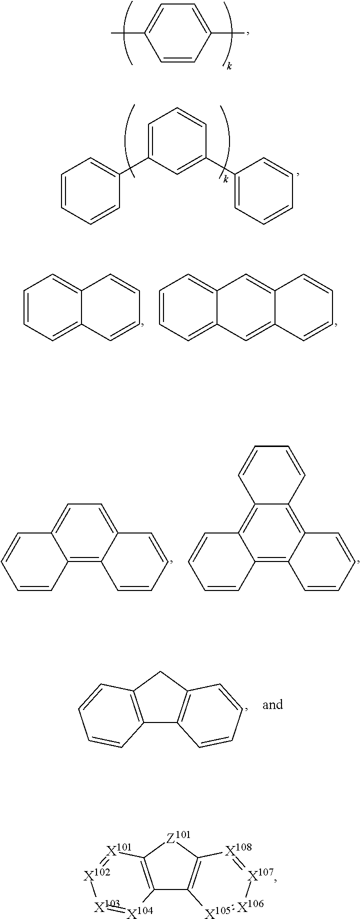

wherein k is an integer from 1 to 20; X¹⁰¹ to X¹⁰⁸ is C (including CH) or N; Z¹⁰¹ is NAr¹, O, or S; Ar¹ has the same group defined above.

Examples of metal complexes used in HIL or HTL include, but are not limited to the following general formula:

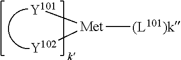

wherein Met is a metal, which can have an atomic weight greater than 40; (Y¹⁰¹-Y¹⁰²) is a bidentate ligand, Y¹⁰¹ and Y¹⁰² are independently selected from C, N, O, P, and S; L¹⁰¹ is an ancillary ligand; k′ is an integer value from 1 to the maximum number of ligands that may be attached to the metal; and k′+k″ is the maximum number of ligands that may be attached to the metal.

In one aspect, (Y¹⁰¹-Y¹⁰²) is a 2-phenylpyridine derivative. In another aspect, (Y¹⁰¹-Y¹⁰²) is a carbene ligand. In another aspect, Met is selected from Ir, Pt, Os, and Zn. In a further aspect, the metal complex has a smallest oxidation potential in solution vs. Fc⁺/Fc couple less than about 0.6 V.

Non-limiting examples of the HIL and HTL materials that may be used in an OLED in combination with materials disclosed herein are exemplified below together with references that disclose those materials: CN102702075, DE102012005215, EP01624500, EP01698613, EP01806334, EP01930964, EP01972613, EP01997799, EP02011790, EP02055700, EP02055701, EP1725079, EP2085382, EP2660300, EP650955, JP07-073529, JP2005112765, JP2007091719, JP2008021687, JP2014-009196, KR20110088898, KR20130077473, TW201139402, U.S. Ser. No. 06/517,957, US20020158242, US20030162053, US20050123751, US20060182993, US20060240279, US20070145888, US20070181874, US20070278938, US20080014464, US20080091025, US20080106190, US20080124572, US20080145707, US20080220265, US20080233434, US20080303417, US2008107919, US20090115320, US20090167161, US2009066235, US2011007385, US20110163302, US2011240968, US2011278551, US2012205642, US2013241401, US20140117329, US2014183517, U.S. Pat. Nos. 5,061,569, 5,639,914, WO05075451, WO07125714, WO08023550, WO08023759, WO2009145016, WO2010061824, WO2011075644, WO2012177006, WO2013018530, WO2013039073, WO2013087142, WO2013118812, WO2013120577, WO2013157367, WO2013175747, WO2014002873, WO2014015935, WO2014015937, WO2014030872, WO2014030921, WO2014034791, WO2014104514, WO2014157018.

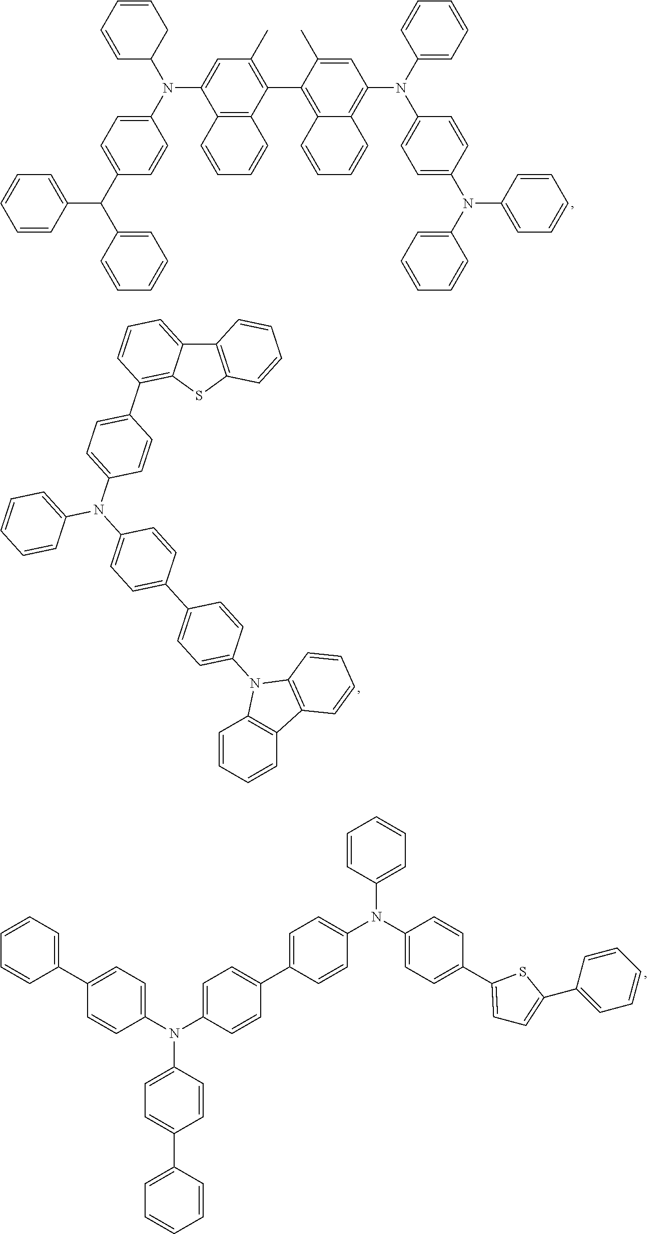

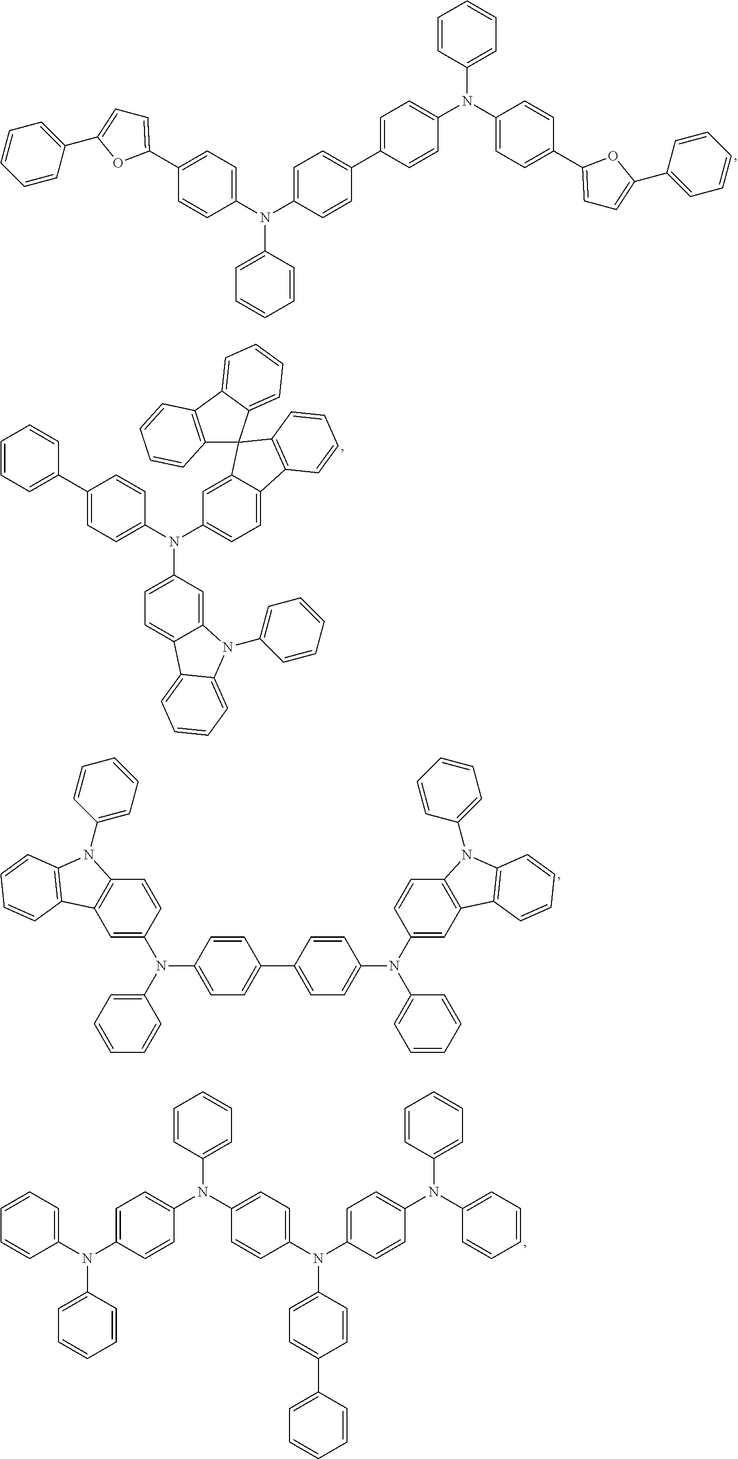

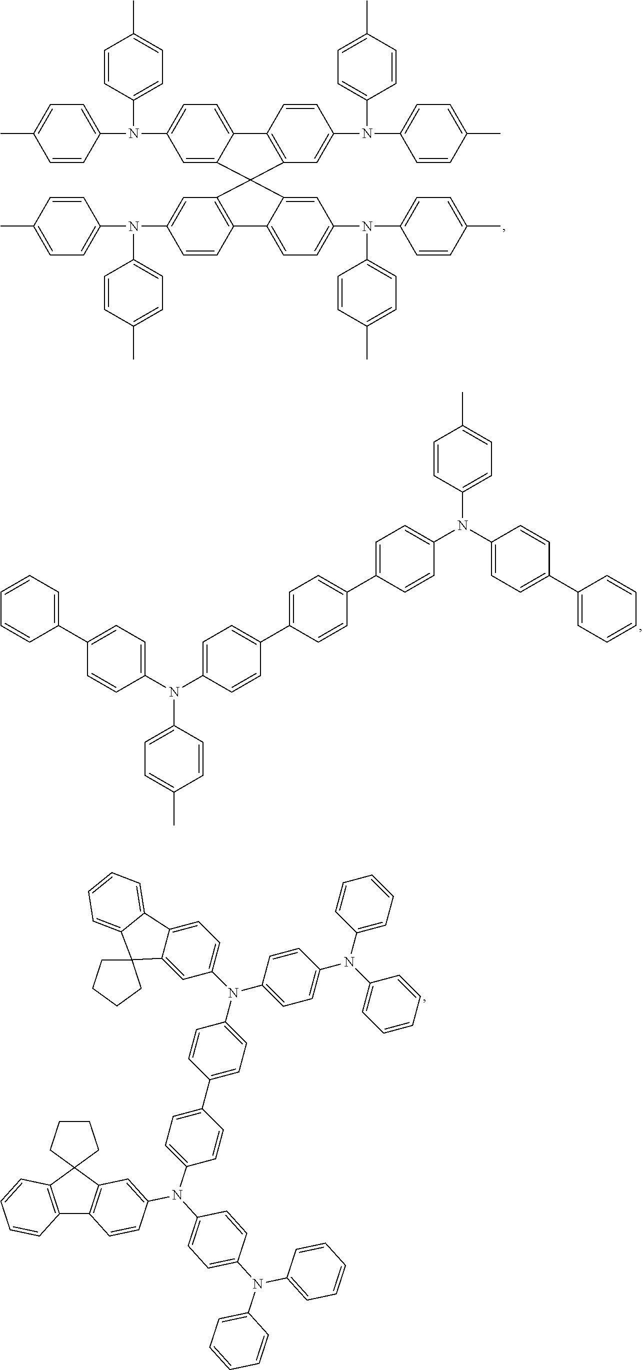

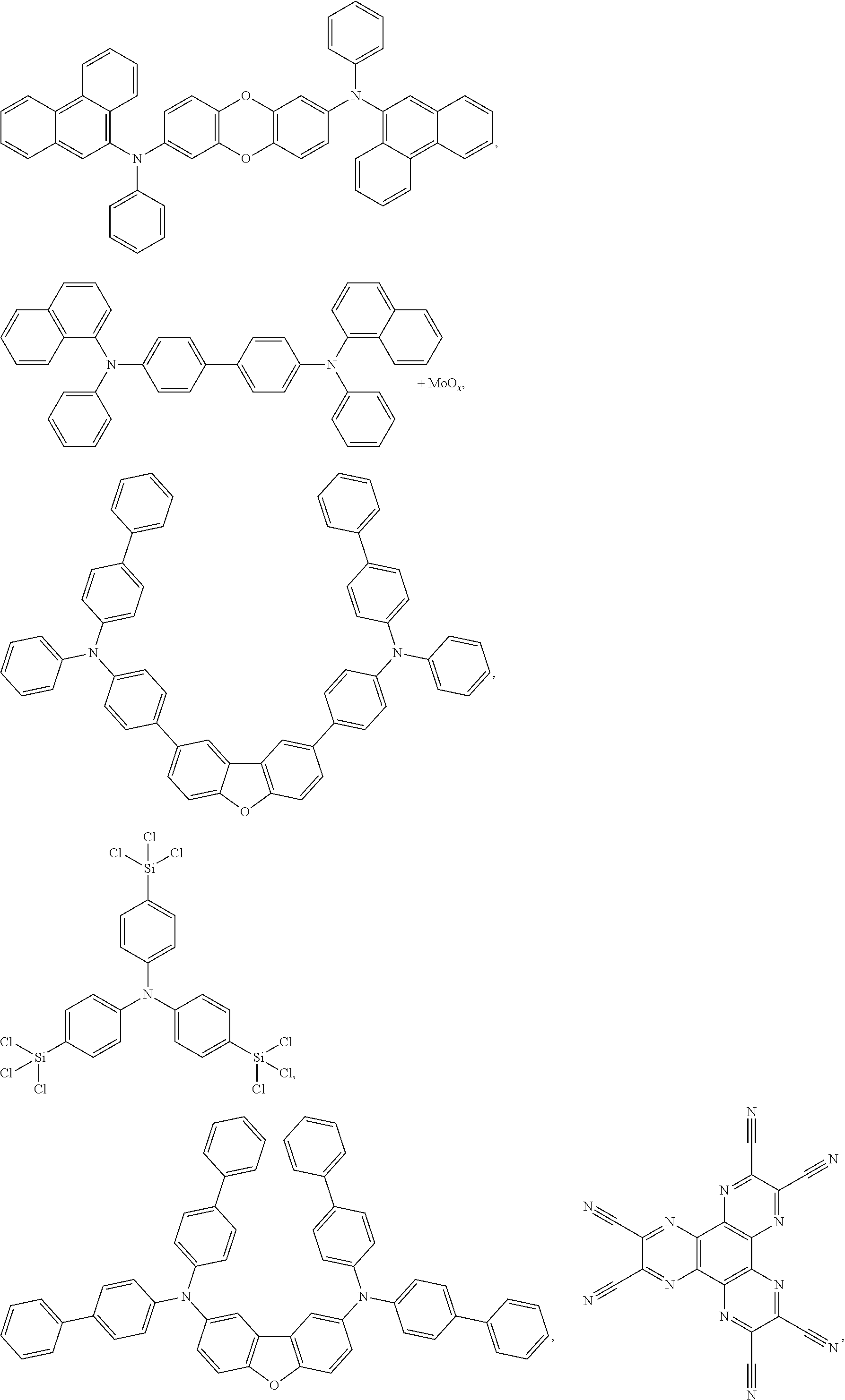

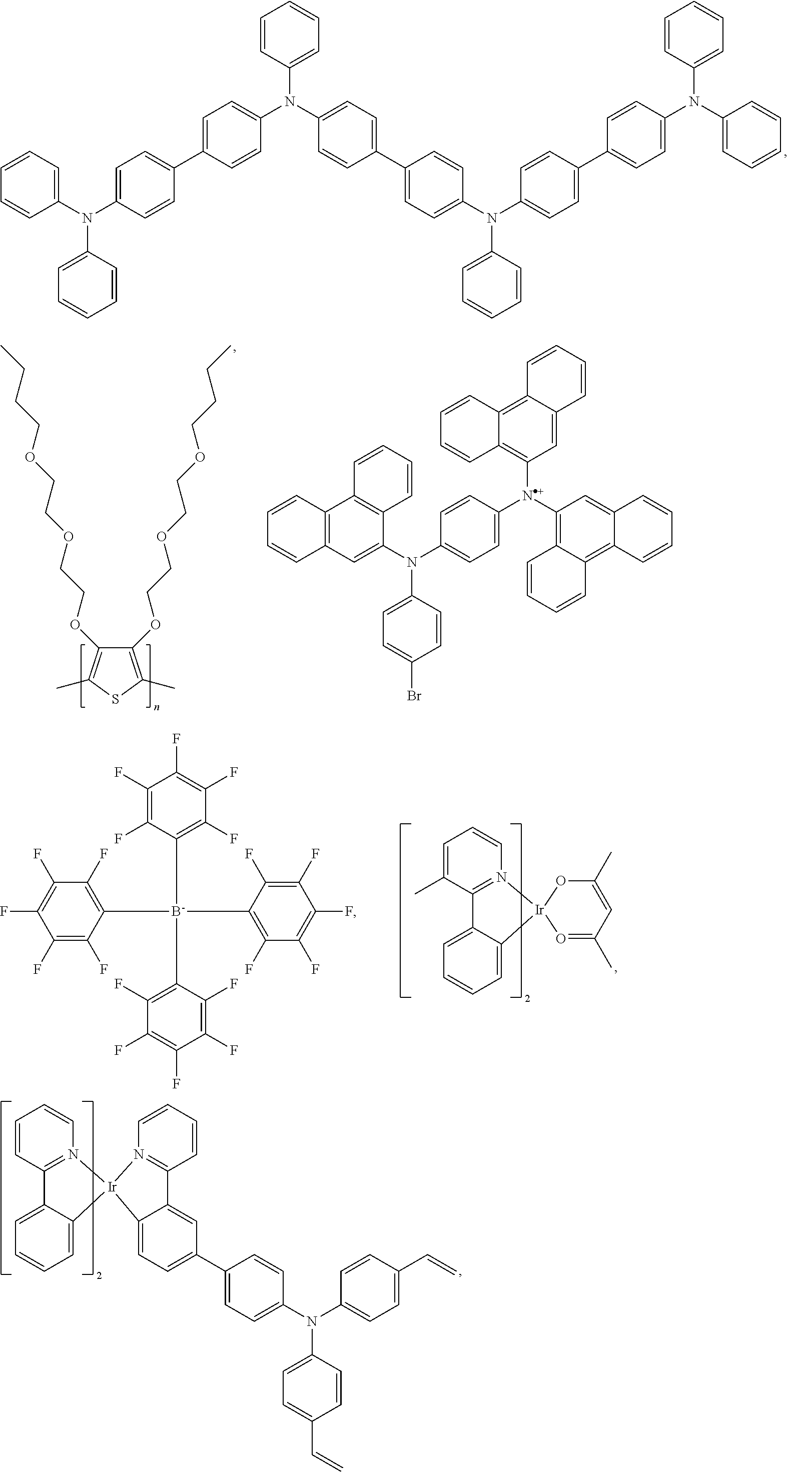

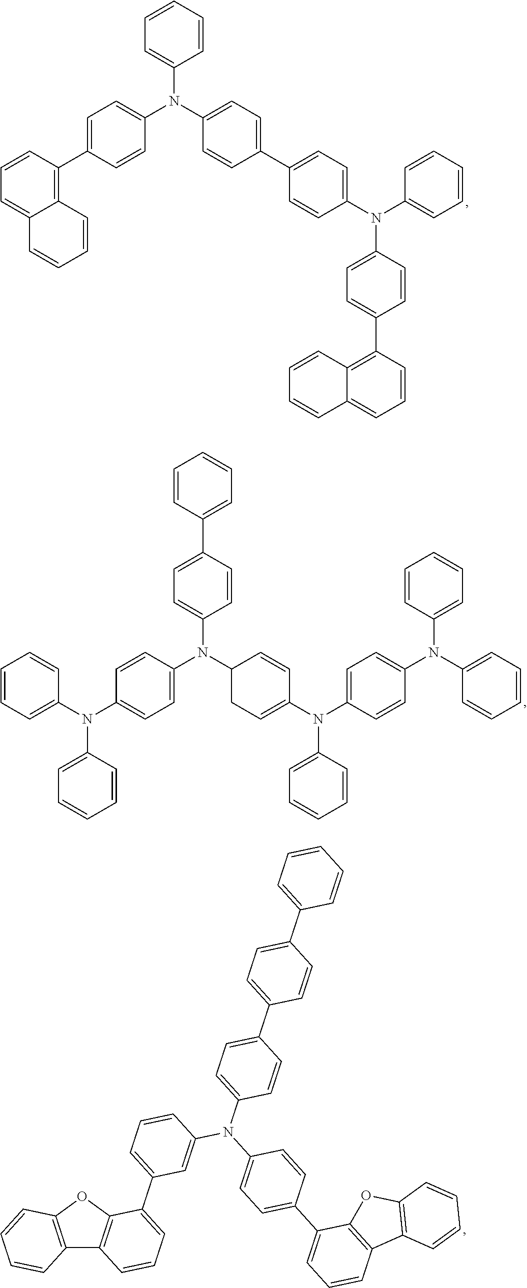

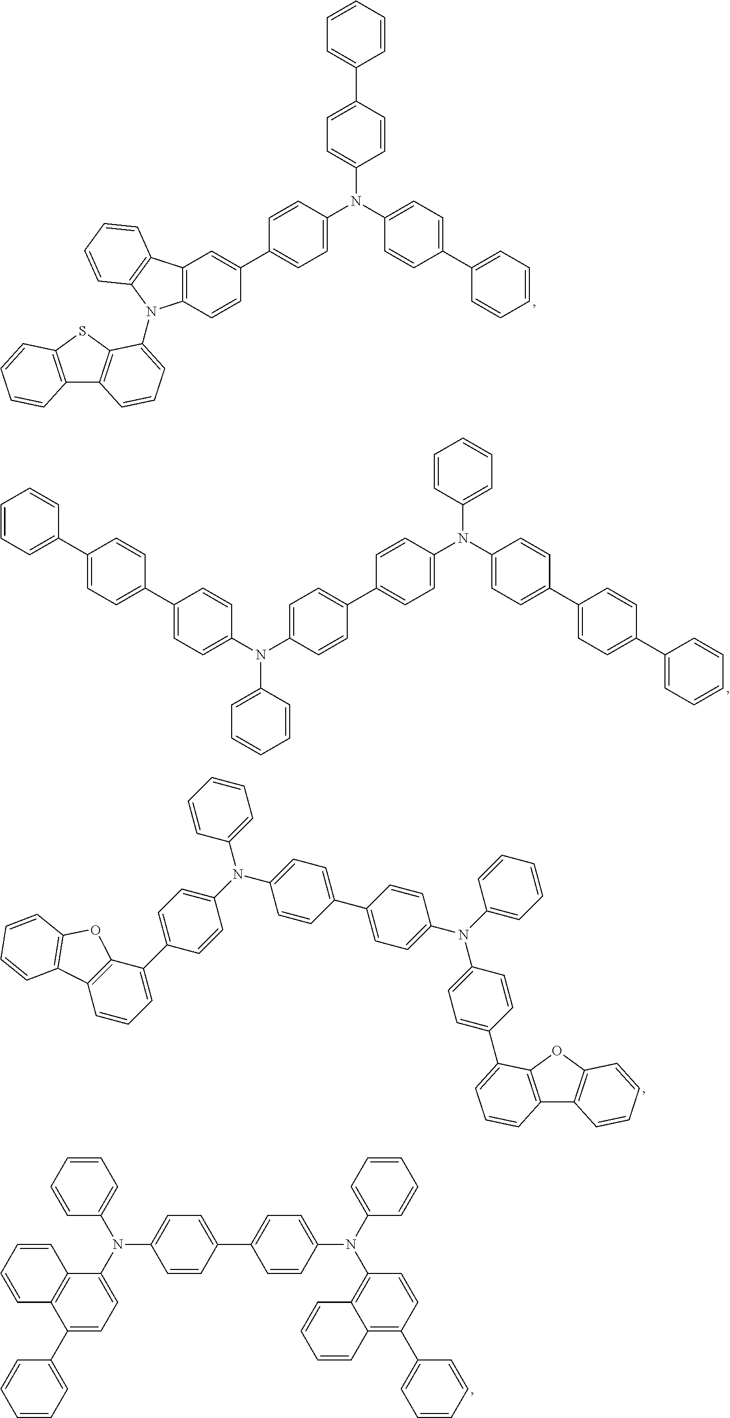

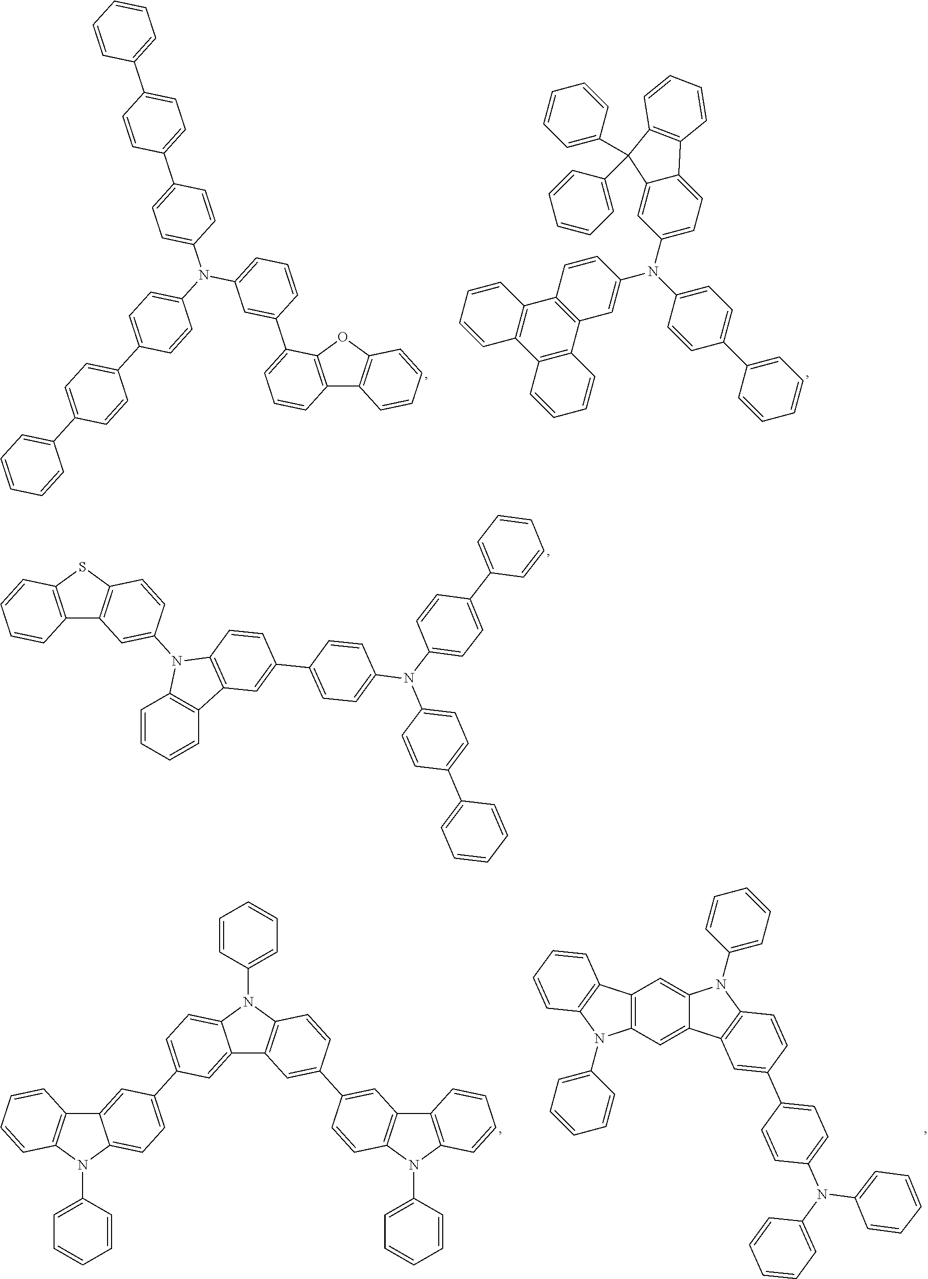 [SMILES: c1ccc(-c2ccc(-c3ccc(N(c4ccc(-c5ccc(-c6ccccc6)cc5)cc4)c4cccc(-c5cccc6c5oc5ccccc56)c4)cc3)cc2)cc1 ; c1ccc(-c2ccc(N(c3ccc4c(c3)C(c3ccccc3)(c3ccccc3)c3ccccc3-4)c3ccc4c5ccccc5c5ccccc5c4c3)cc2)cc1 ; c1ccc(-c2ccc(N(c3ccc(-c4ccccc4)cc3)c3ccc(-c4ccc5c(c4)c4ccccc4n5-c4ccc5sc6ccccc6c5c4)cc3)cc2)cc1 ; c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1 ; c1ccc(N(c2ccccc2)c2ccc(-c3ccc4c(c3)c3cc5c(cc3n4-c3ccccc3)c3ccccc3n5-c3ccccc3)cc2)cc1]

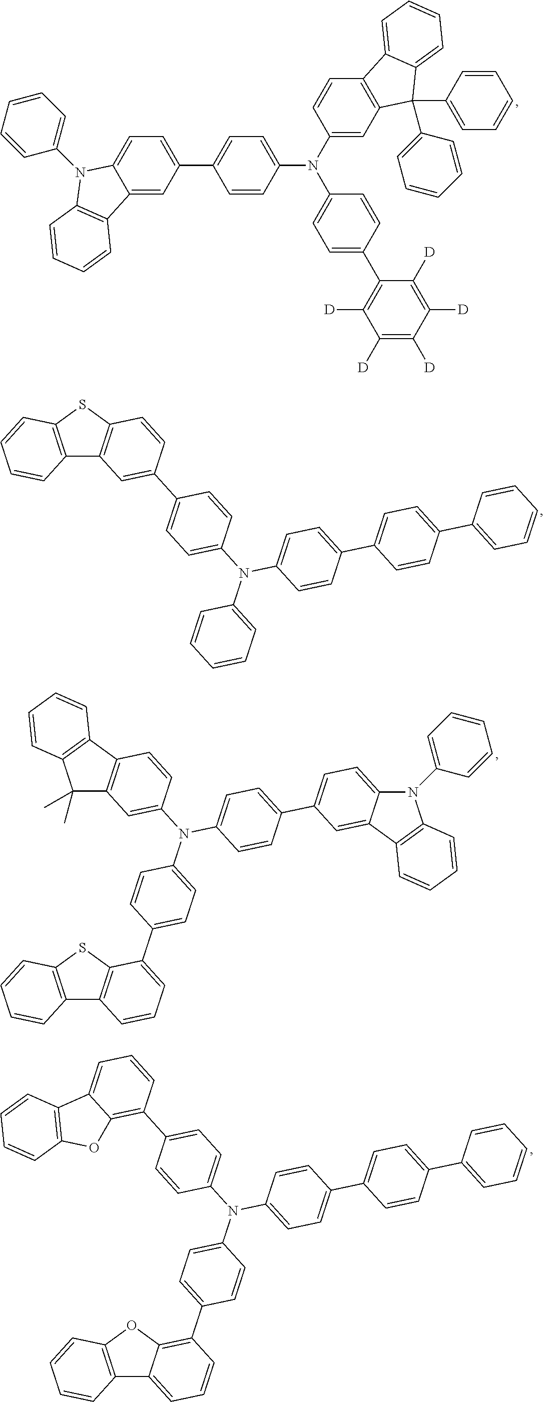

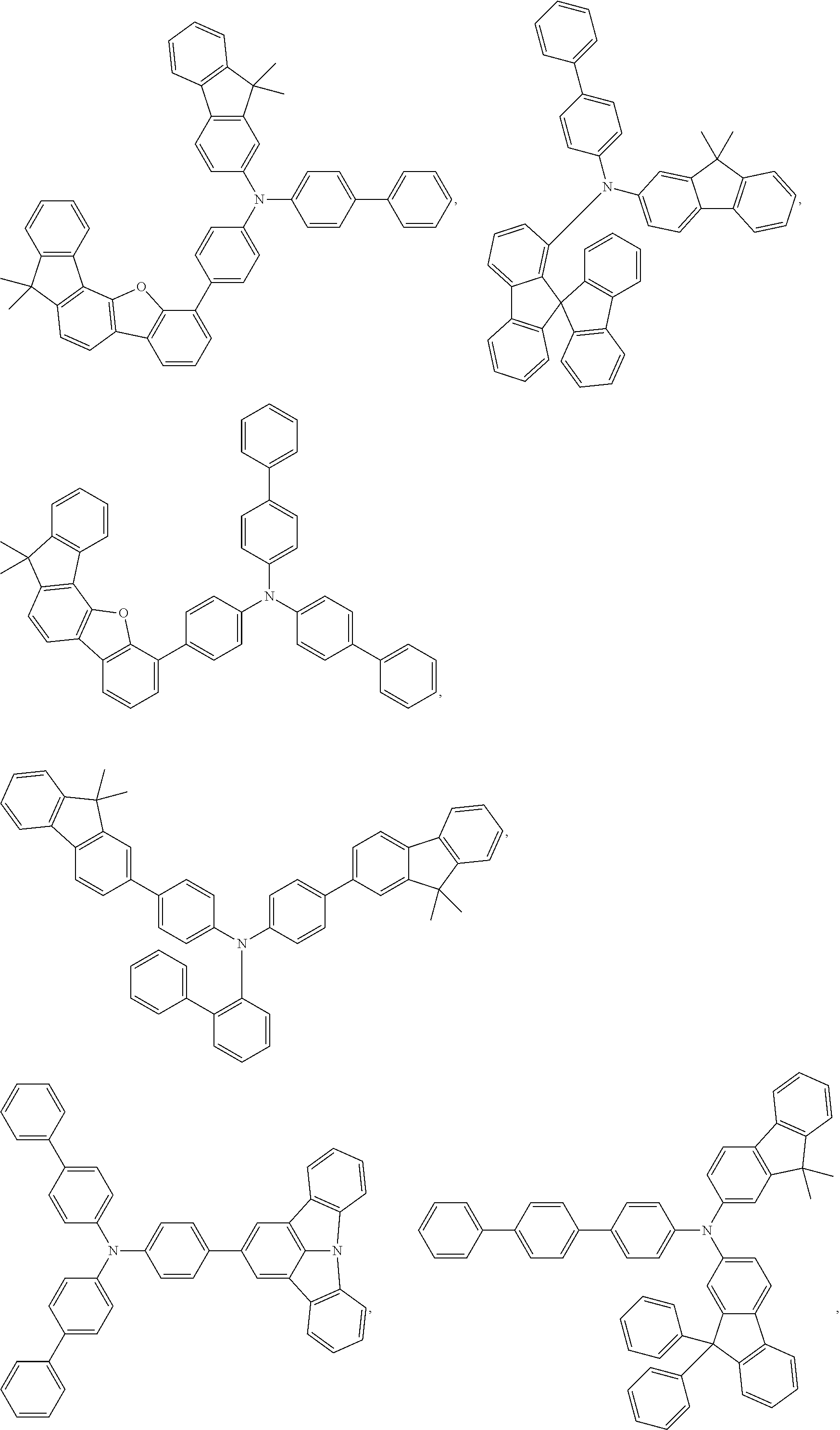

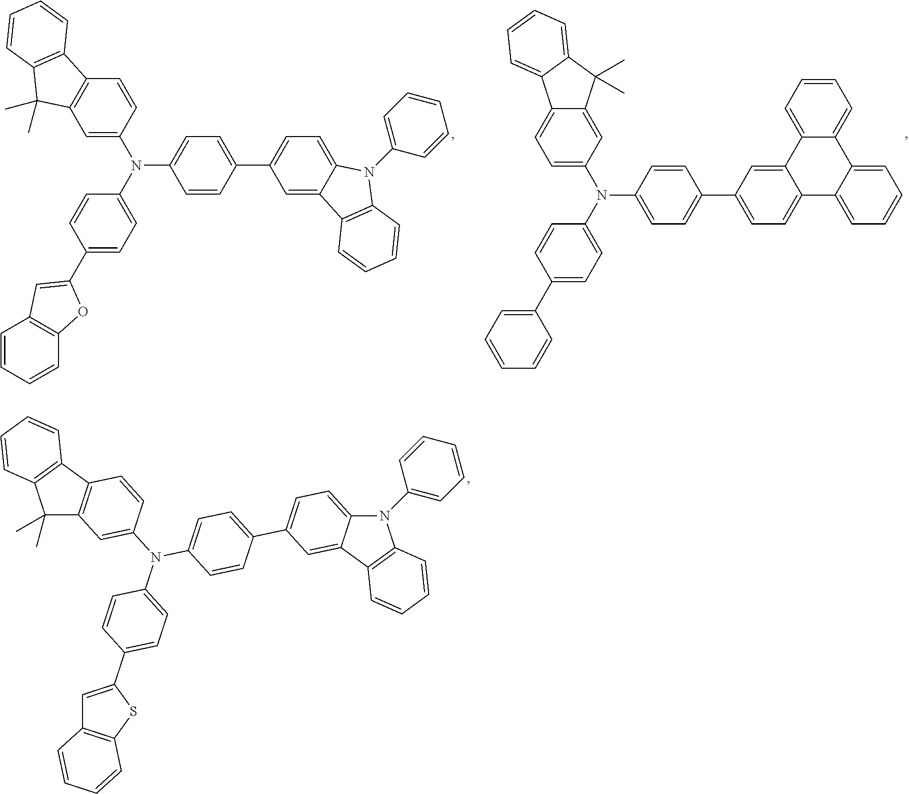

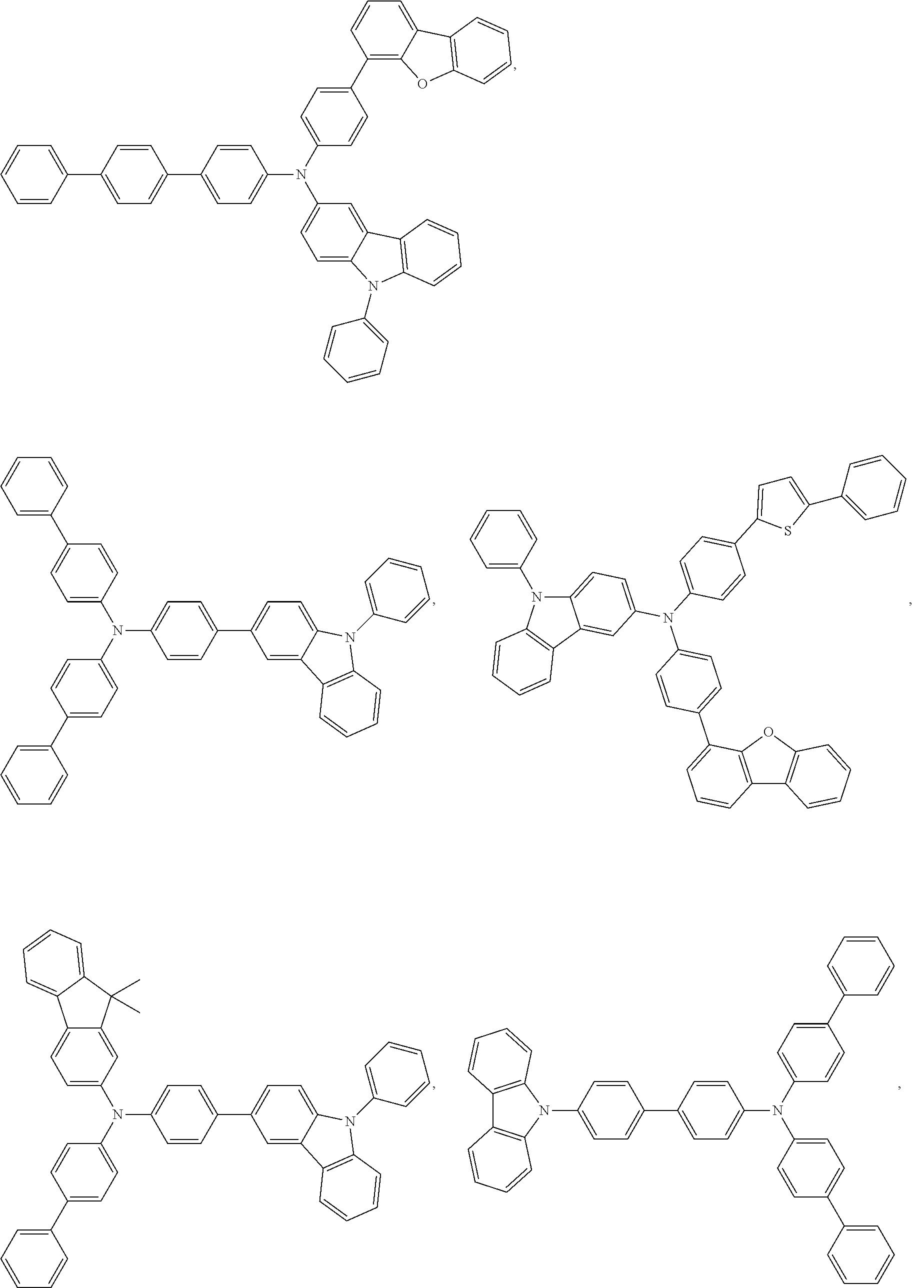

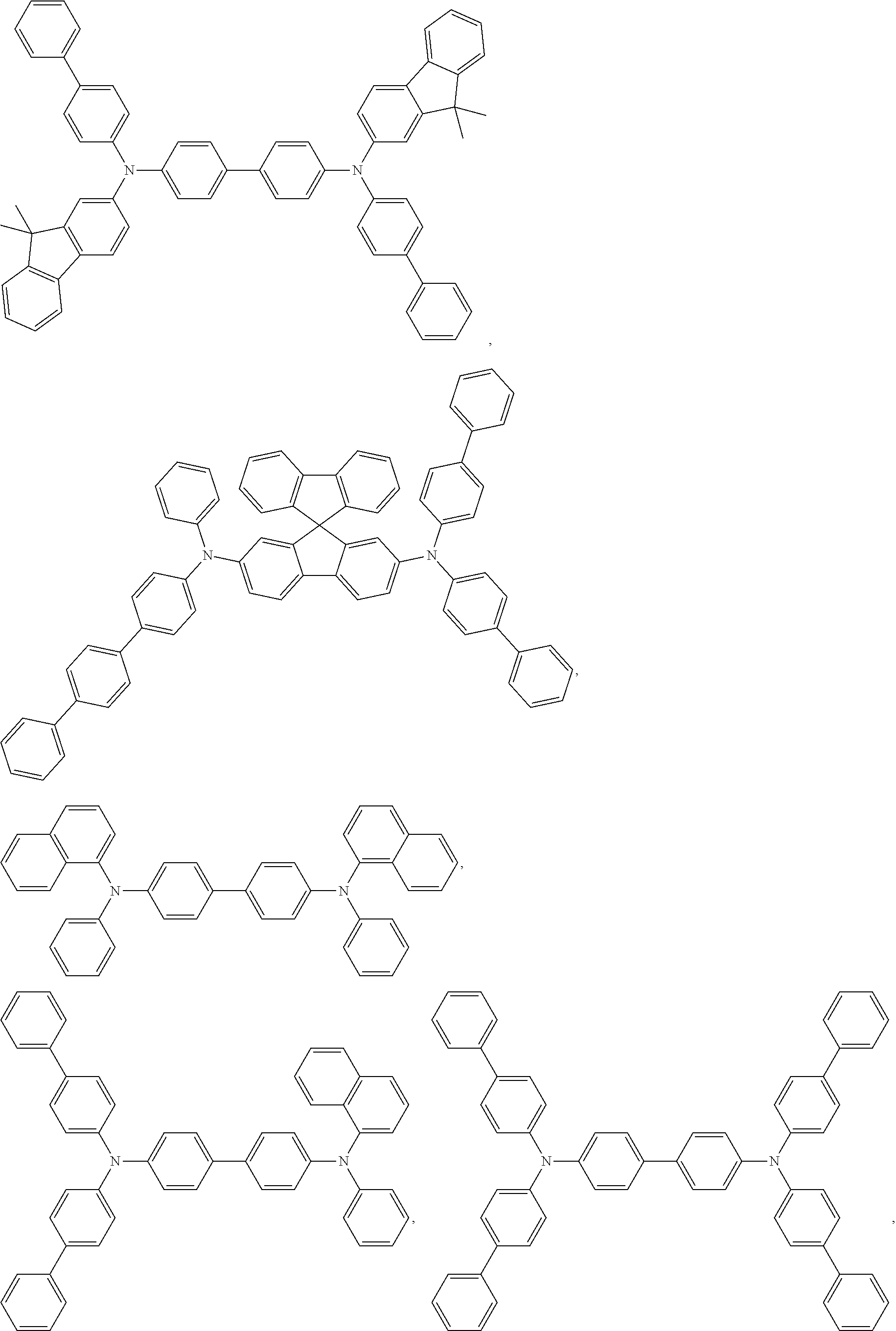

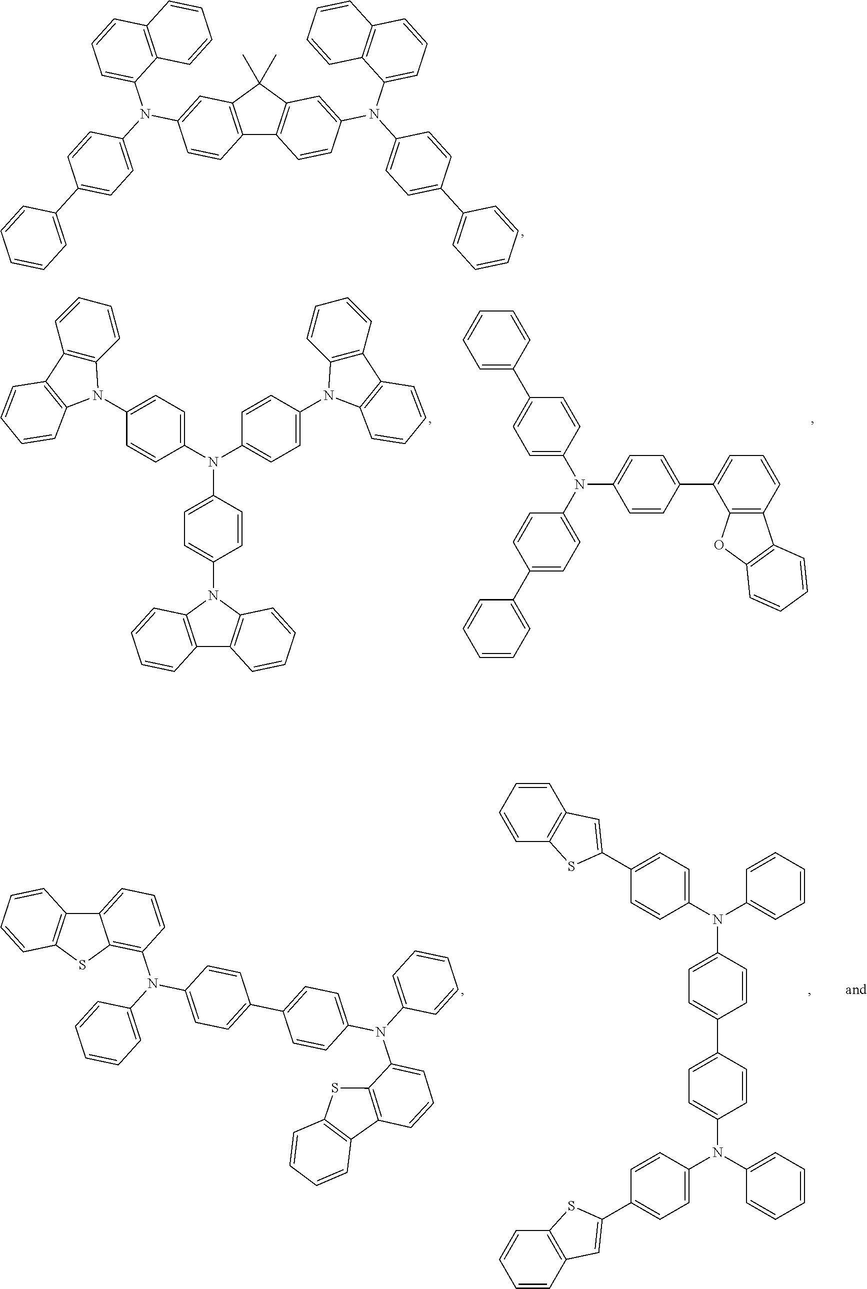

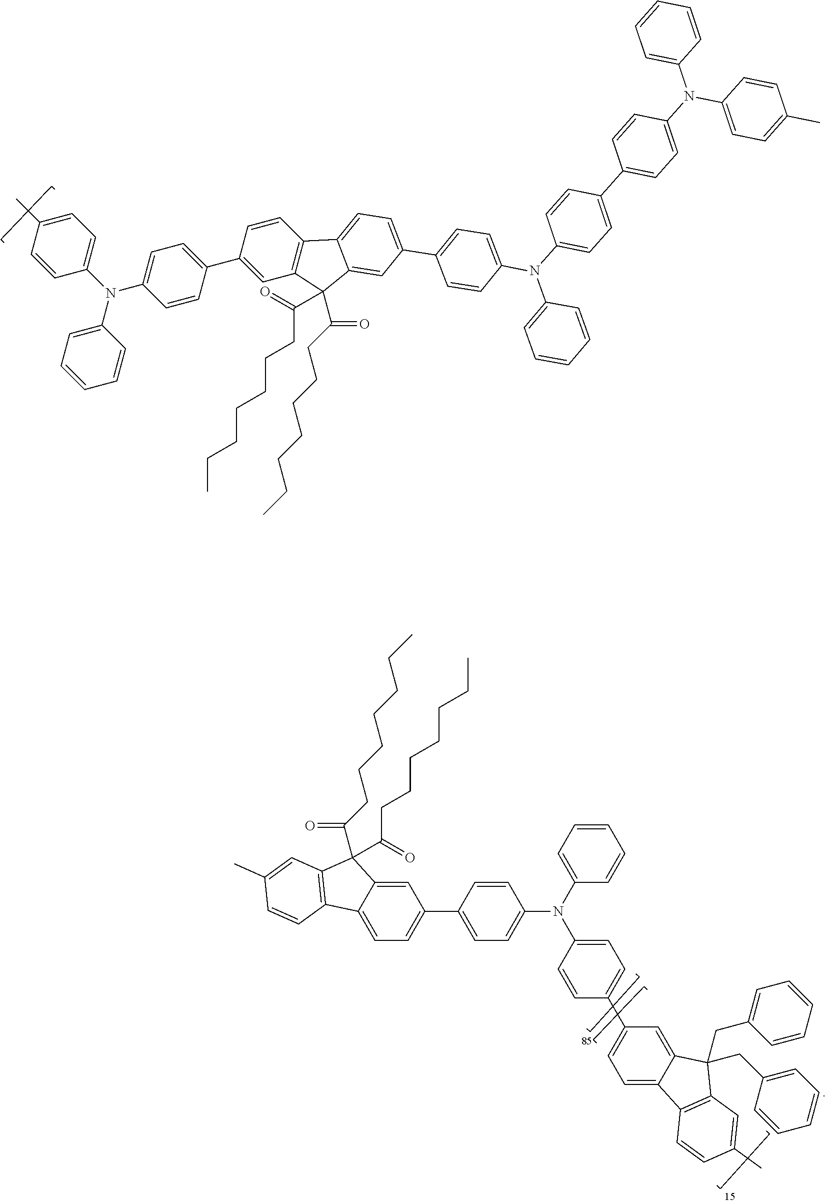

### c) EBL:

An electron blocking layer (EBL) may be used to reduce the number of electrons and/or excitons that leave the emissive layer. The presence of such a blocking layer in a device may result in substantially higher efficiencies, and/or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and/or higher triplet energy than one or more of the hosts closest to the EBL interface. In one aspect, the compound used in EBL contains the same molecule or the same functional groups used as one of the hosts described below.

### d) Hosts:

The light emitting layer of the organic EL device of the present disclosure preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

Examples of metal complexes used as host are preferred to have the following general formula:

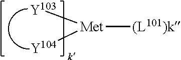

wherein Met is a metal; (Y¹⁰³-Y¹⁰⁴) is a bidentate ligand, Y¹⁰³ and Y¹⁰⁴ are independently selected from C, N, O, P, and S; L¹⁰¹ is an another ligand; k′ is an integer value from 1 to the maximum number of ligands that may be attached to the metal; and k′+k″ is the maximum number of ligands that may be attached to the metal.

In one aspect, the metal complexes are:

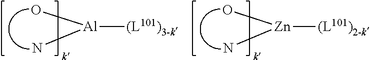

wherein (O—N) is a bidentate ligand, having metal coordinated to atoms O and N.

In another aspect, Met is selected from Ir and Pt. In a further aspect, (Y¹⁰³-Y¹⁰⁴) is a carbene ligand.

In one aspect, the host compound contains at least one of the following groups selected from the group consisting of aromatic hydrocarbon cyclic compounds such as benzene, biphenyl, triphenyl, triphenylene, tetraphenylene, naphthalene, anthracene, phenalene, phenanthrene, fluorene, pyrene, chrysene, perylene, and azulene; the group consisting of aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine; and the group consisting of 2 to 10 cyclic structural units which are groups of the same type or different types selected from the aromatic hydrocarbon cyclic group and the aromatic heterocyclic group and are bonded to each other directly or via at least one of oxygen atom, nitrogen atom, sulfur atom, silicon atom, phosphorus atom, boron atom, chain structural unit and the aliphatic cyclic group. Each option within each group may be unsubstituted or may be substituted by a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof.

In one aspect, the host compound contains at least one of the following groups in the molecule:

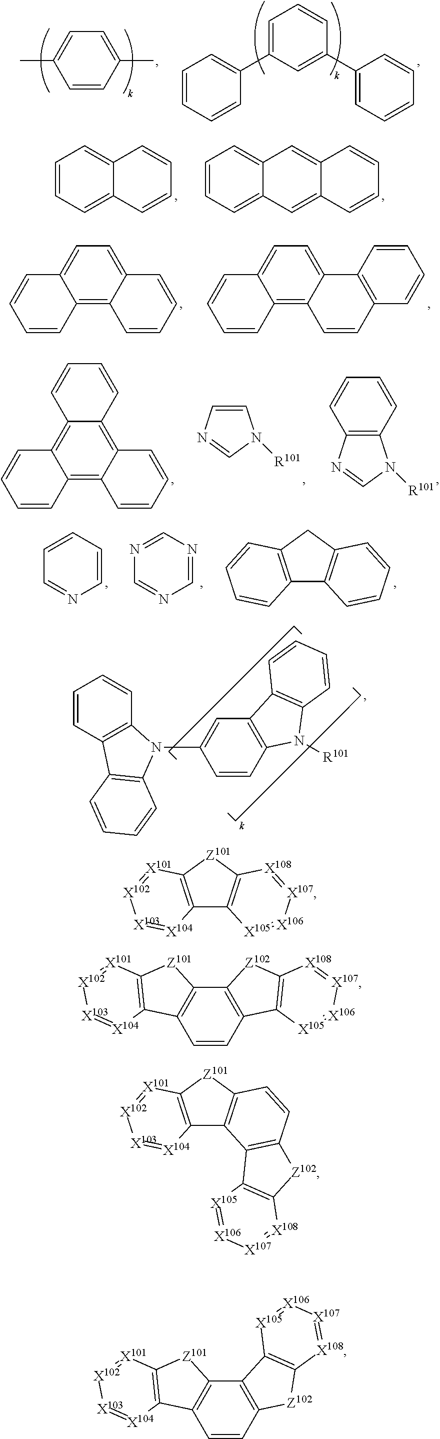

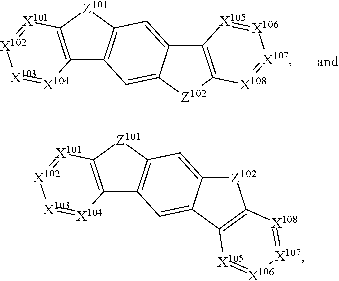

wherein R¹⁰¹ is selected from the group consisting of hydrogen, deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof, and when it is aryl or heteroaryl, it has the similar definition as Ar's mentioned above. k is an integer from 0 to 20 or 1 to 20. X¹⁰¹ to X¹⁰⁸ are independently selected from C (including CH) or N. Z¹⁰¹ and Z¹⁰² are independently selected from NR¹⁰¹, O, or S.

Non-limiting examples of the host materials that may be used in an OLED in combination with materials disclosed herein are exemplified below together with references that disclose those materials: EP2034538, EP2034538A, EP2757608, JP2007254297, KR20100079458, KR20120088644, KR20120129733, KR20130115564, TW201329200, US20030175553, US20050238919, US20060280965, US20090017330, US20090030202, US20090167162, US20090302743, US20090309488, US20100012931, US20100084966, US20100187984, US2010187984, US2012075273, US2012126221, US2013009543, US2013105787, US2013175519, US2014001446, US20140183503, US20140225088, US2014034914, U.S. Pat. No. 7,154,114, WO2001039234, WO2004093207, WO2005014551, WO2005089025, WO2006072002, WO2006114966, WO2007063754, WO2008056746, WO2009003898, WO2009021126, WO2009063833, WO2009066778, WO2009066779, WO2009086028, WO2010056066, WO2010107244, WO2011081423, WO2011081431, WO2011086863, WO2012128298, WO2012133644, WO2012133649, WO2013024872, WO2013035275, WO2013081315, WO2013191404, WO2014142472, US20170263869, US20160163995, U.S. Pat. No. 9,466,803,

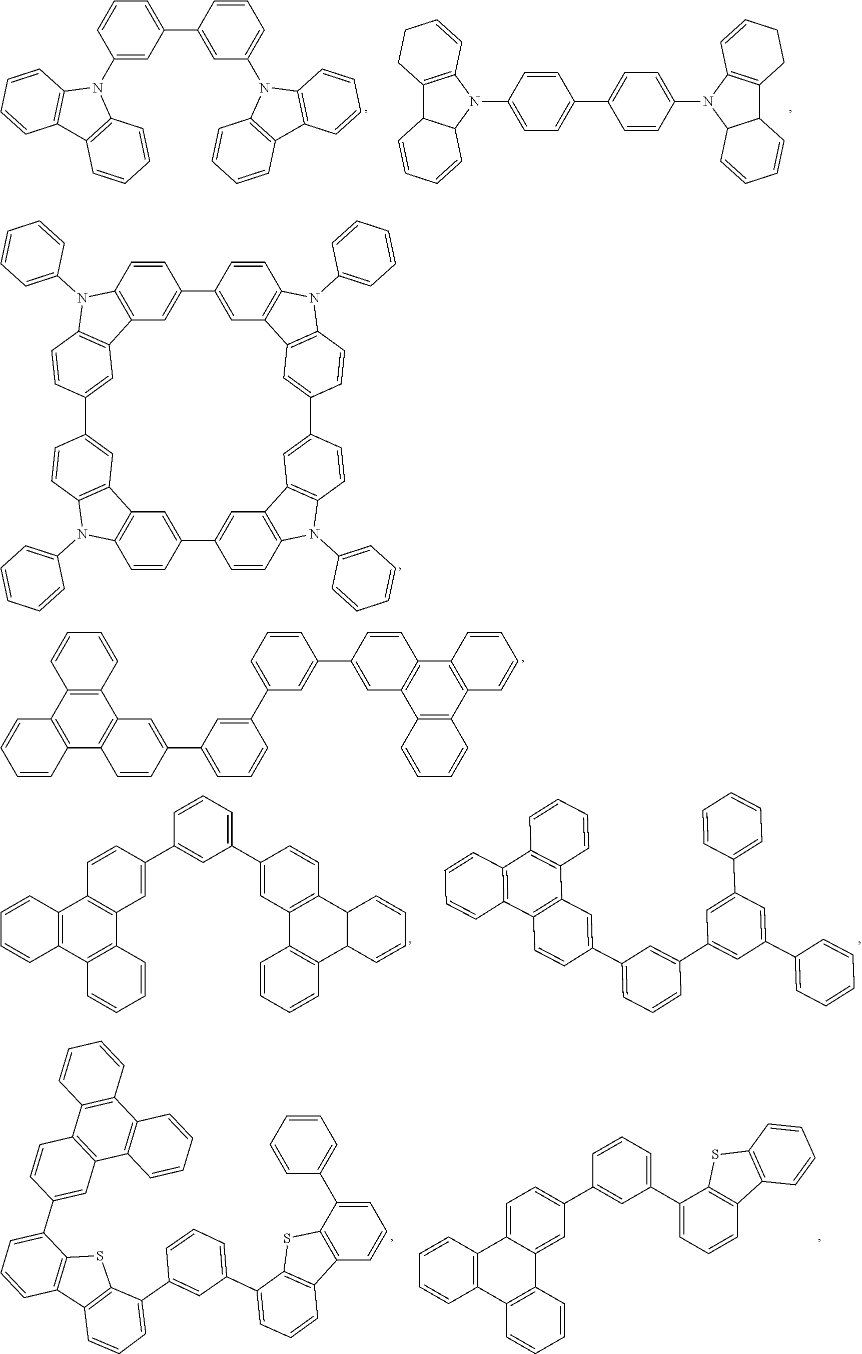

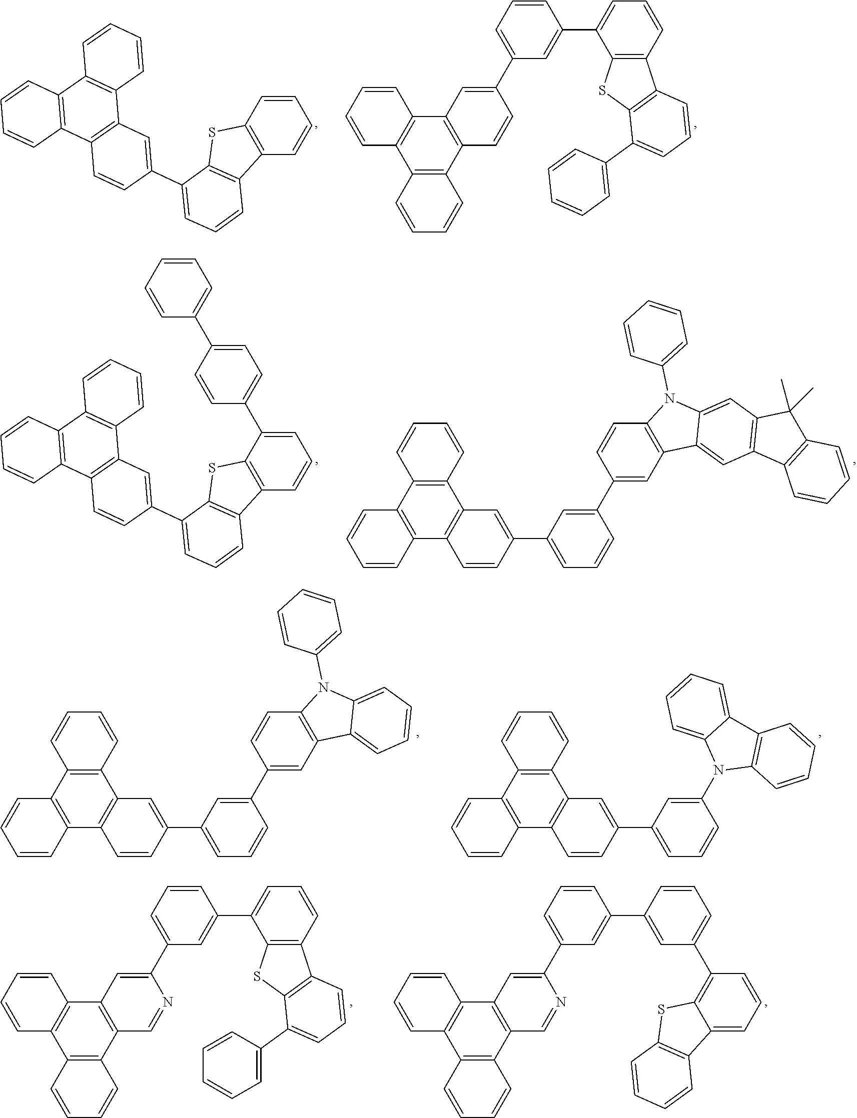

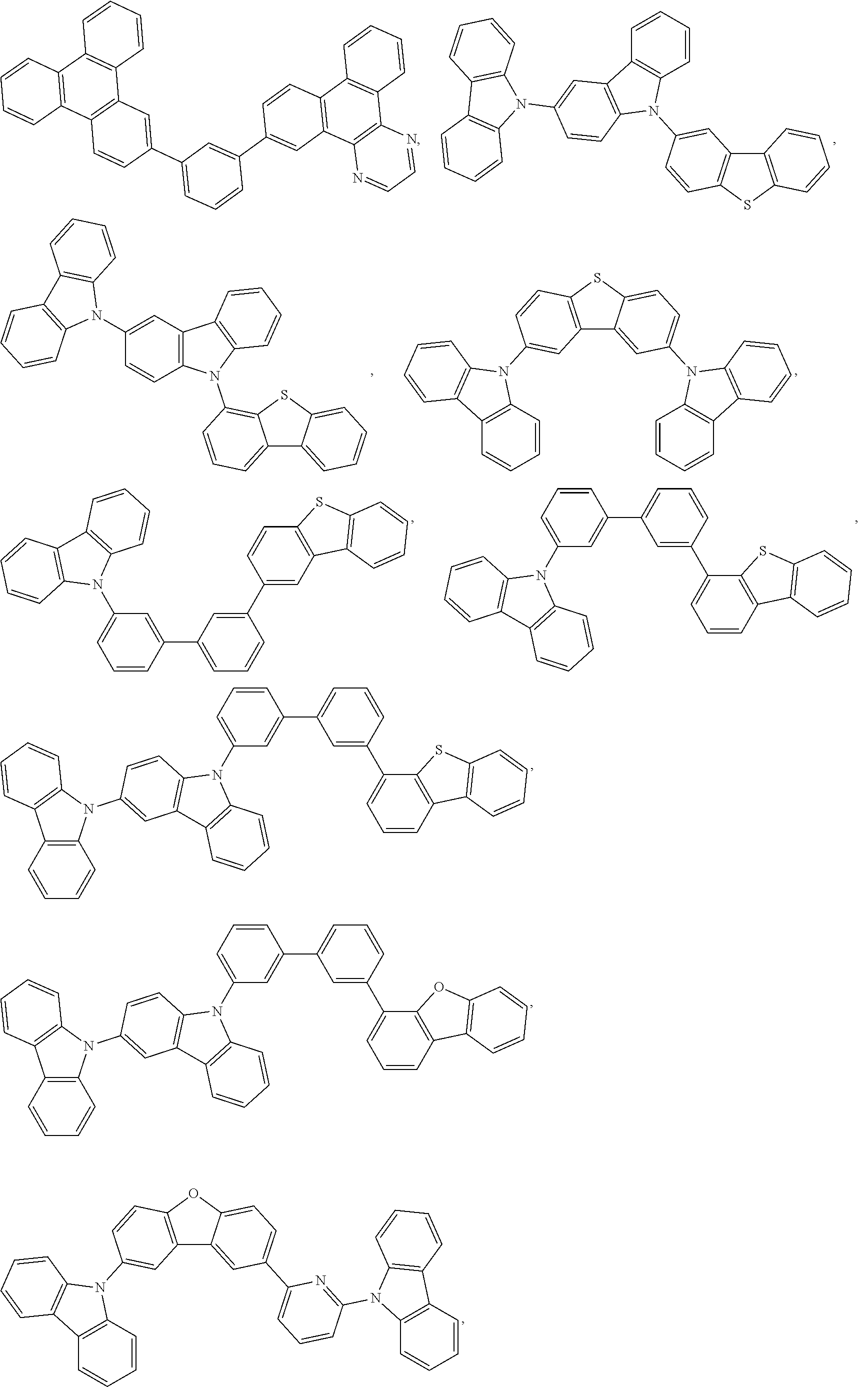

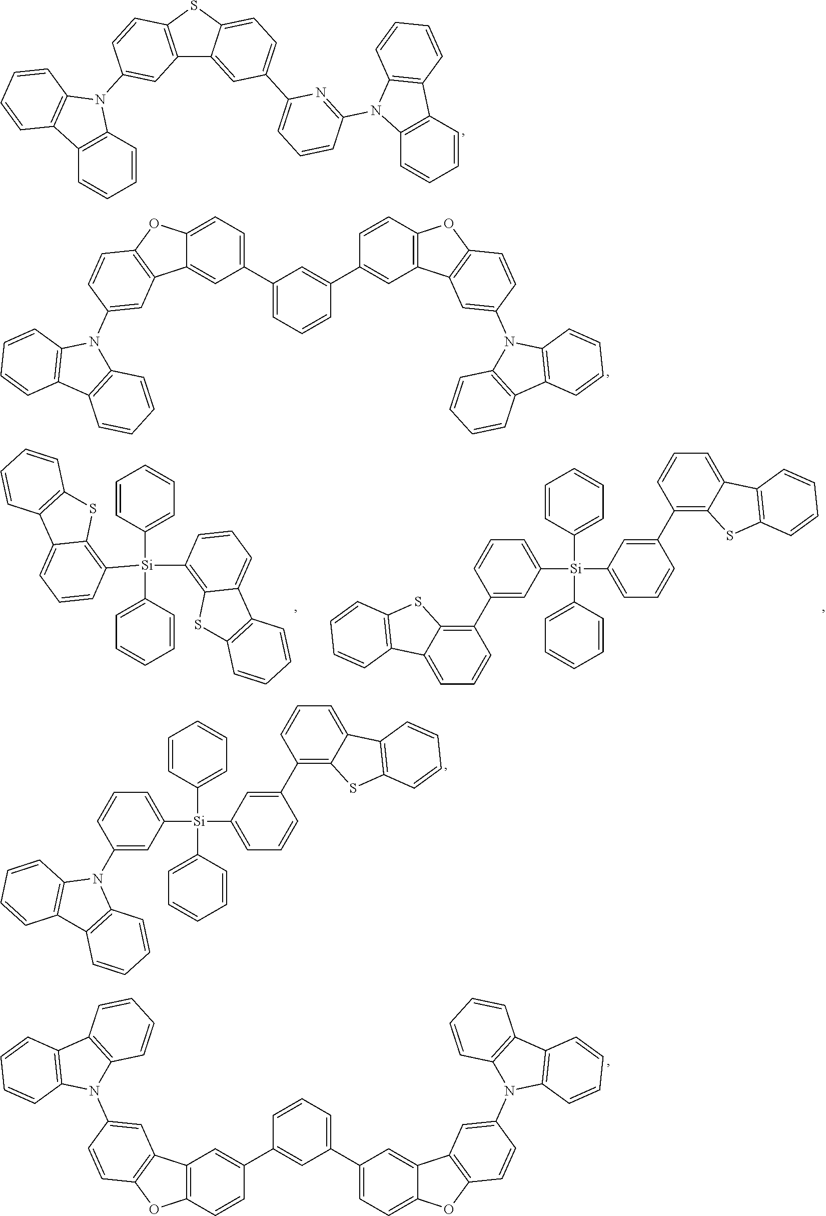

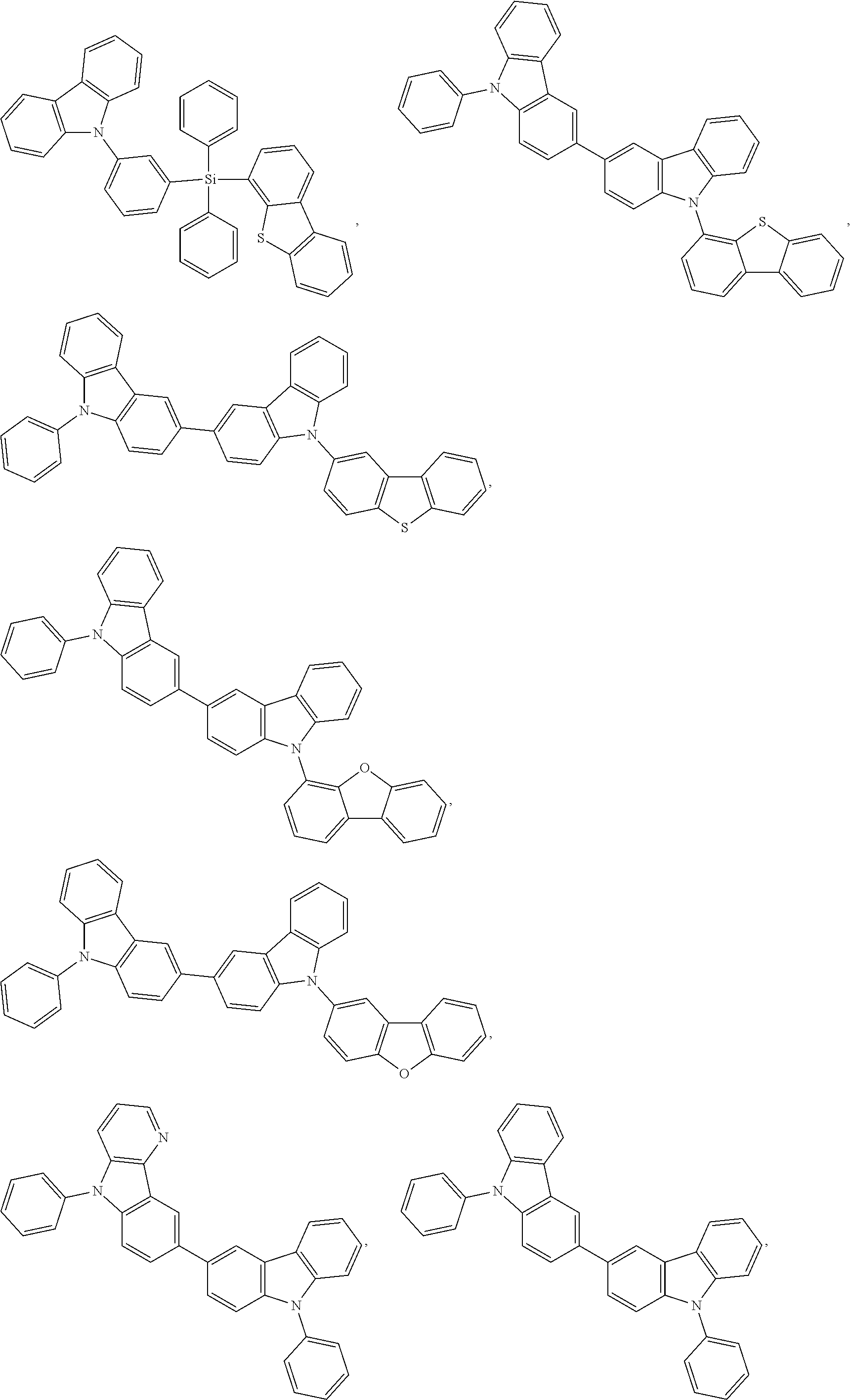

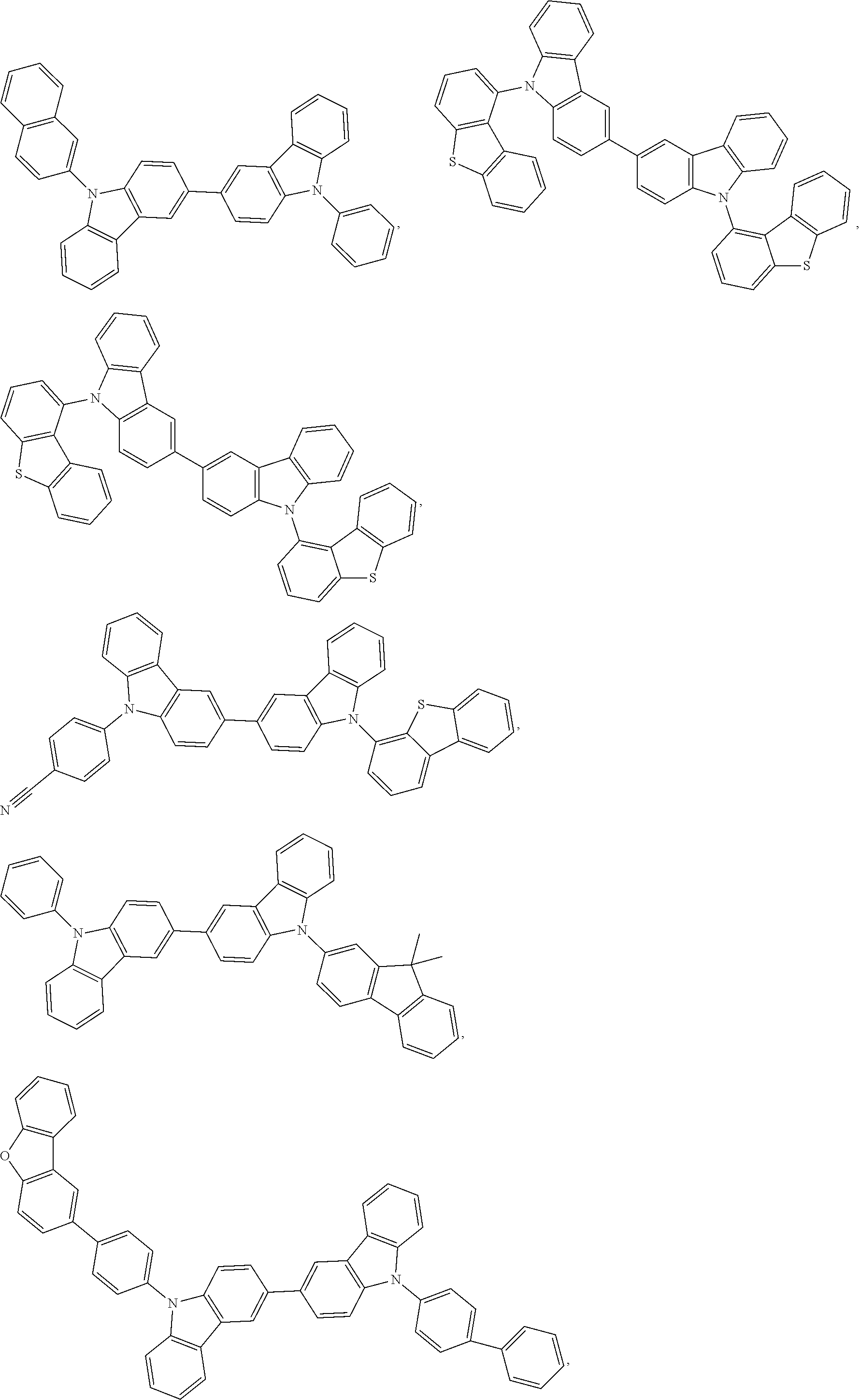

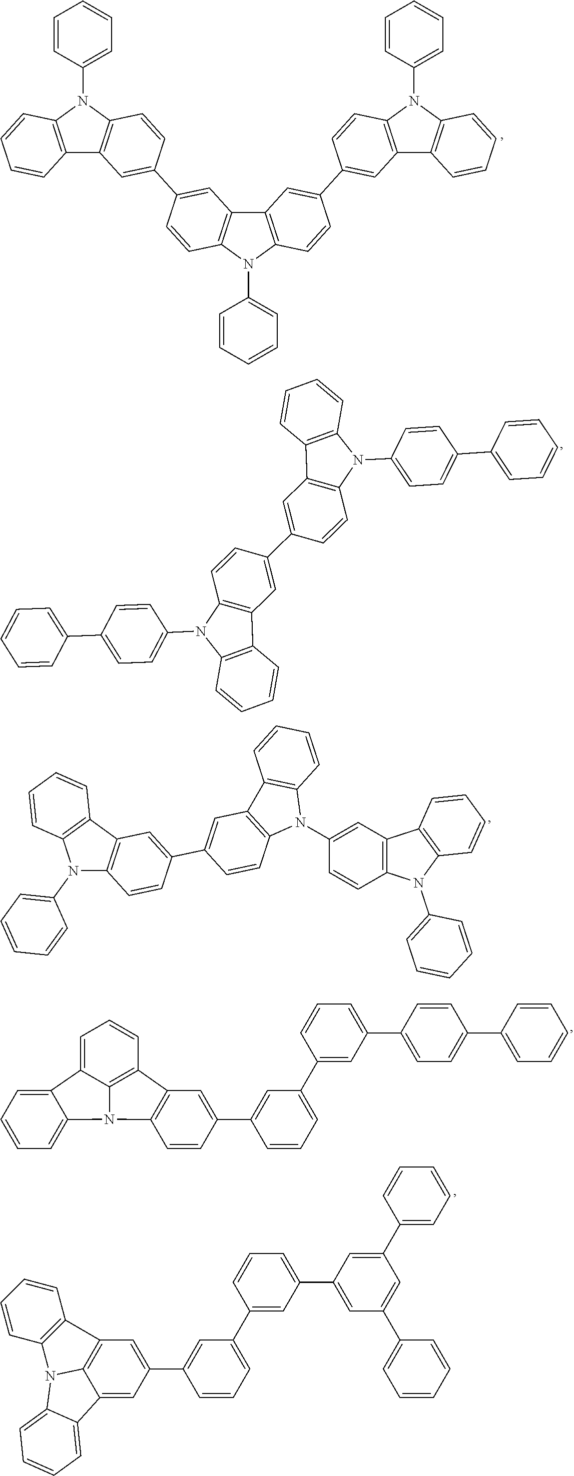

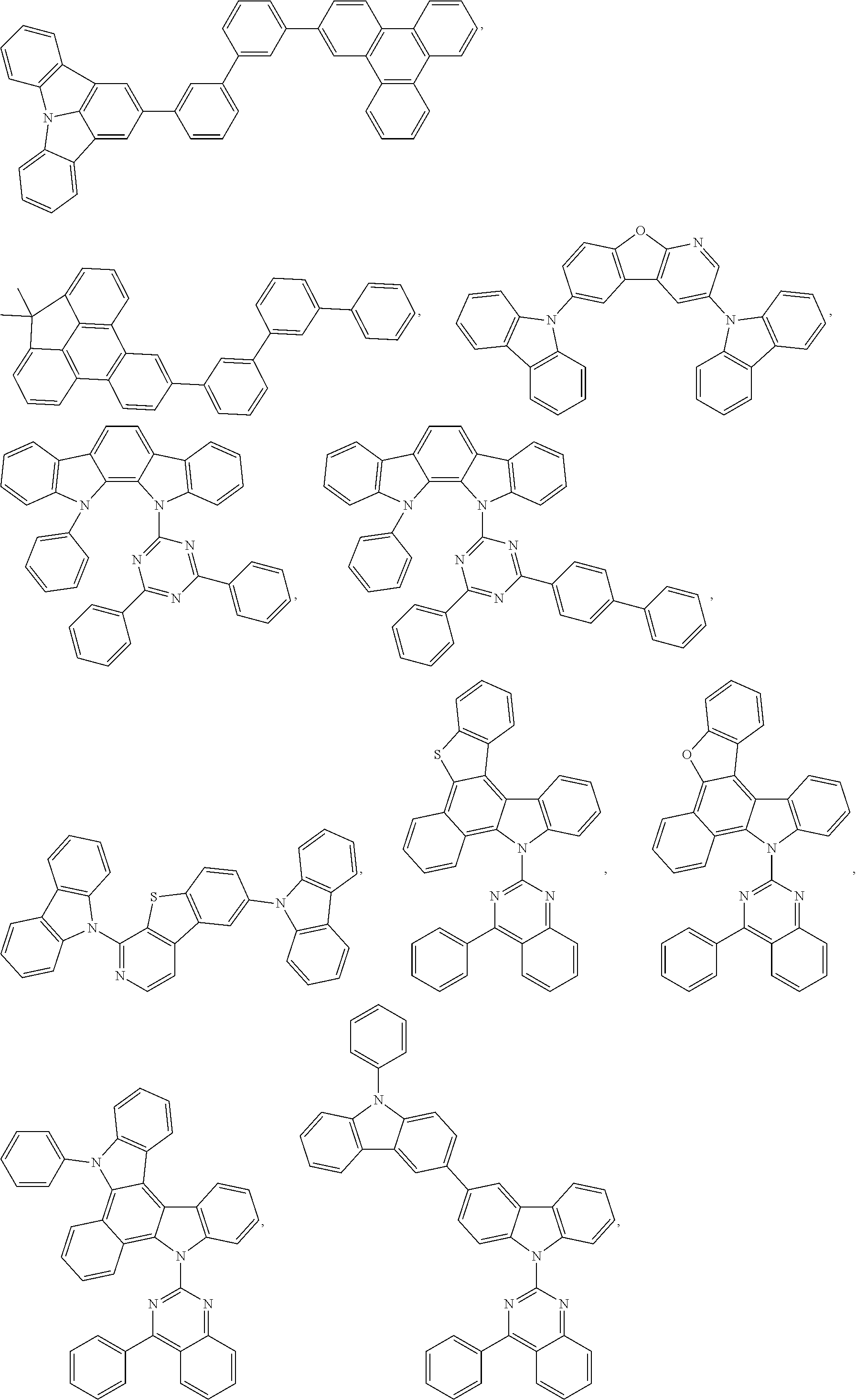

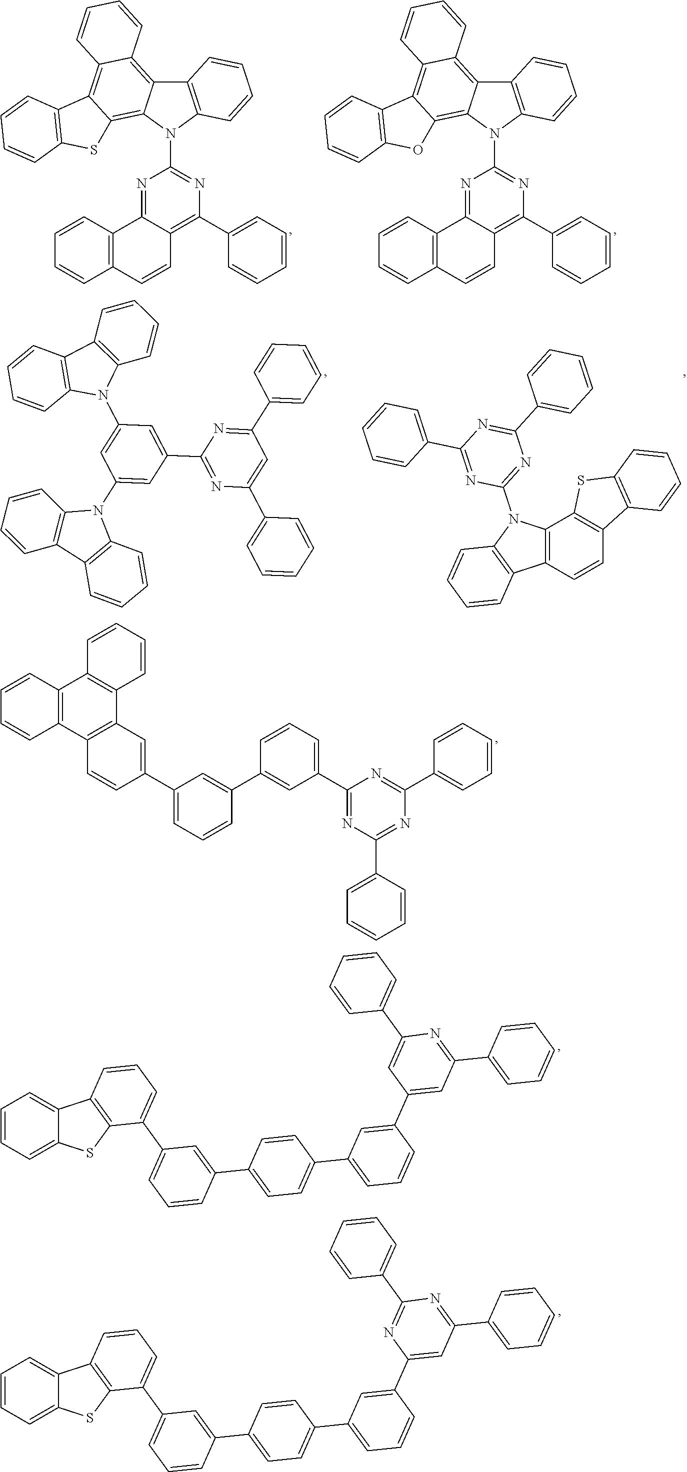

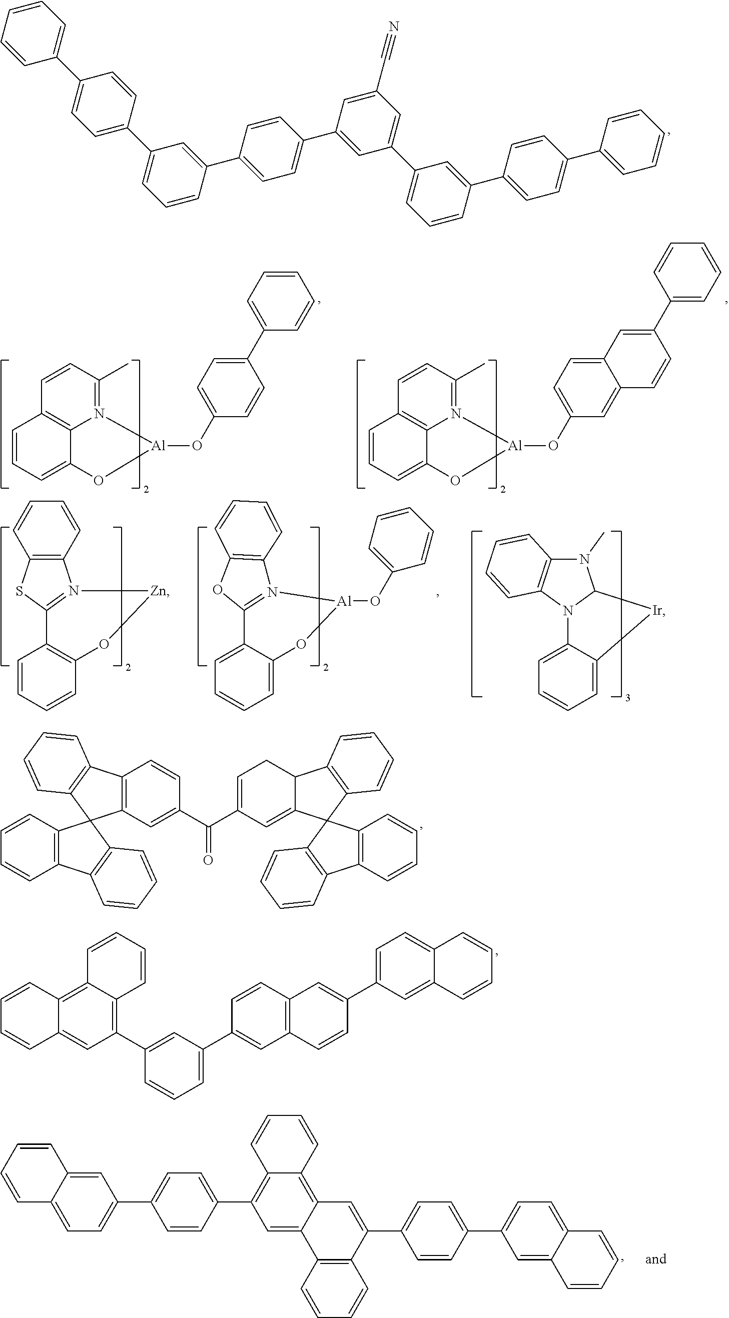

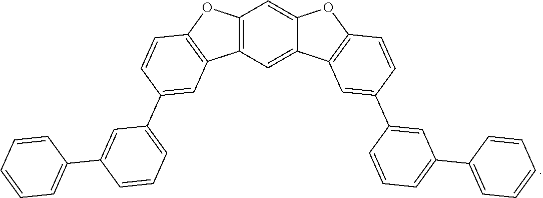 [SMILES: c1ccc(-c2cccc(-c3ccc4oc5cc6oc7ccc(-c8cccc(-c9ccccc9)c8)cc7c6cc5c4c3)c2)cc1]

### e) Additional Emitters:

One or more additional emitter dopants may be used in conjunction with the compound of the present disclosure. Examples of the additional emitter dopants are not particularly limited, and any compounds may be used as long as the compounds are typically used as emitter materials. Examples of suitable emitter materials include, but are not limited to, compounds which can produce emissions via phosphorescence, fluorescence, thermally activated delayed fluorescence, i.e., TADF (also referred to as E-type delayed fluorescence), triplet-triplet annihilation, or combinations of these processes.

Non-limiting examples of the emitter materials that may be used in an OLED in combination with materials disclosed herein are exemplified below together with references that disclose those materials: CN103694277, CN1696137, EB01238981, EP01239526, EP01961743, EP1239526, EP1244155, EP1642951, EP1647554, EP1841834, EP1841834B, EP2062907, EP2730583, JP2012074444, JP2013110263, JP4478555, KR1020090133652, KR20120032054, KR20130043460, TW201332980, U.S. Ser. No. 06/699,599, U.S. Ser. No. 06/916,554, US20010019782, US20020034656, US20030068526, US20030072964, US20030138657, US20050123788, US20050244673, US2005123791, US2005260449, US20060008670, US20060065890, US20060127696, US20060134459, US20060134462, US20060202194, US20060251923, US20070034863, US20070087321, US20070103060, US20070111026, US20070190359, US20070231600, US2007034863, US2007104979, US2007104980, US2007138437, US2007224450, US2007278936, US20080020237, US20080233410, US20080261076, US20080297033, US200805851, US2008161567, US2008210930, US20090039776, US20090108737, US20090115322, US20090179555, US2009085476, US2009104472, US20100090591, US20100148663, US20100244004, US20100295032, US2010102716, US2010105902, US2010244004, US2010270916, US20110057559, US20110108822, US20110204333, US2011215710, US2011227049, US2011285275, US2012292601, US20130146848, US2013033172, US2013165653, US2013181190, US2013334521, US20140246656, US2014103305, U.S. Pat. Nos. 6,303,238, 6,413,656, 6,653,654, 6,670,645, 6,687,266, 6,835,469, 6,921,915, 7,279,704, 7,332,232, 7,378,162, 7,534,505, 7,675,228, 7,728,137, 7,740,957, 7,759,489, 7,951,947, 8,067,099, 8,592,586, 8,871,361, WO06081973, WO06121811, WO07018067, WO07108362, WO07115970, WO07115981, WO08035571, WO2002015645, WO2003040257, WO2005019373, WO2006056418, WO2008054584, WO2008078800, WO2008096609, WO2008101842, WO2009000673, WO2009050281, WO2009100991, WO2010028151, WO2010054731, WO2010086089, WO2010118029, WO2011044988, WO2011051404, WO2011107491, WO2012020327, WO2012163471, WO2013094620, WO2013107487, WO2013174471, WO2014007565, WO2014008982, WO2014023377, WO2014024131, WO2014031977, WO2014038456, WO2014112450.

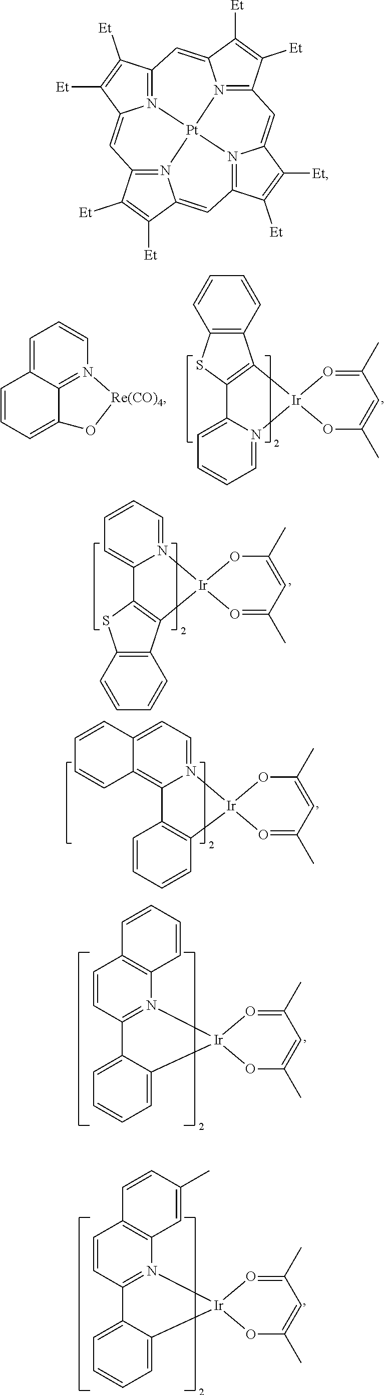

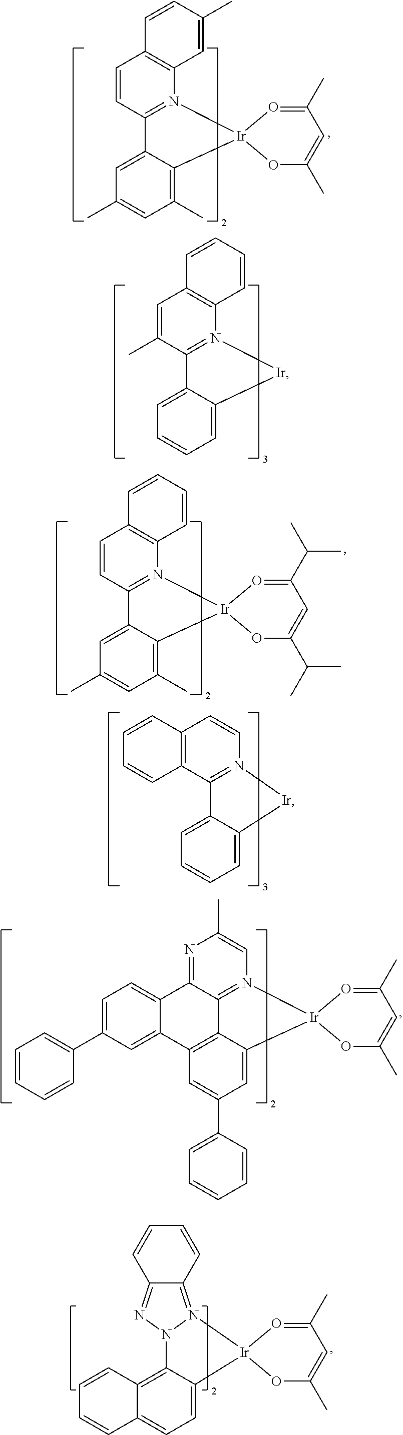

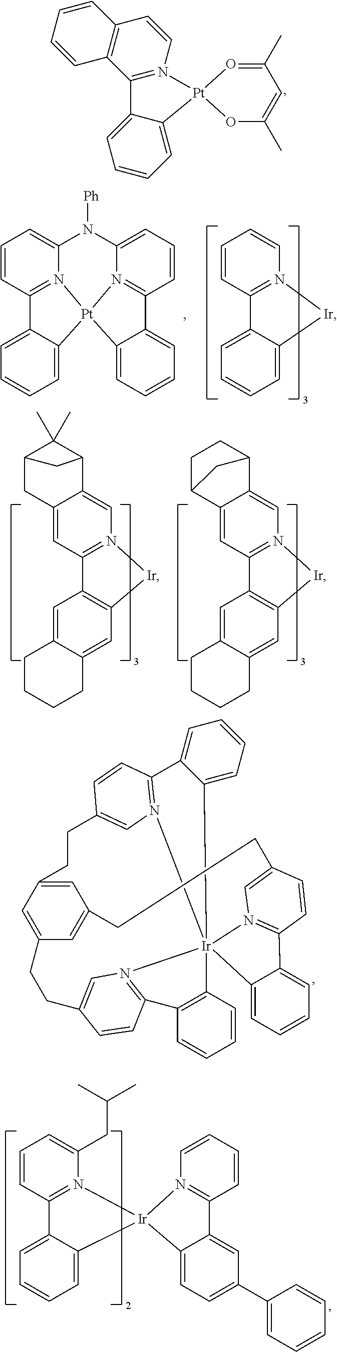

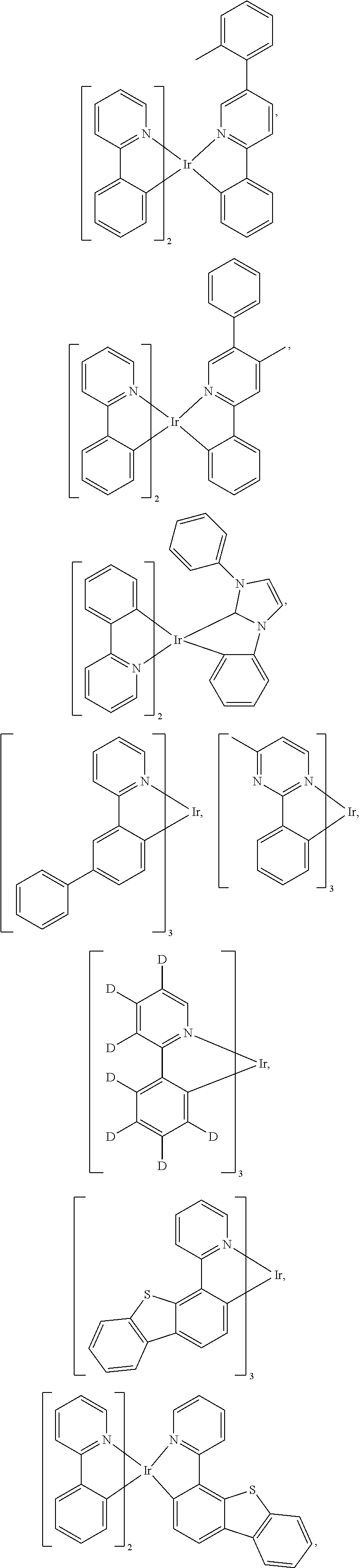

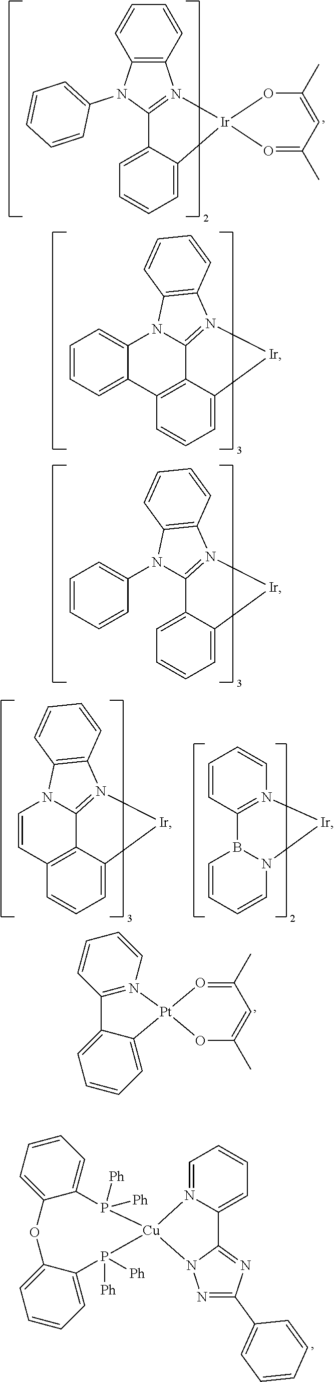

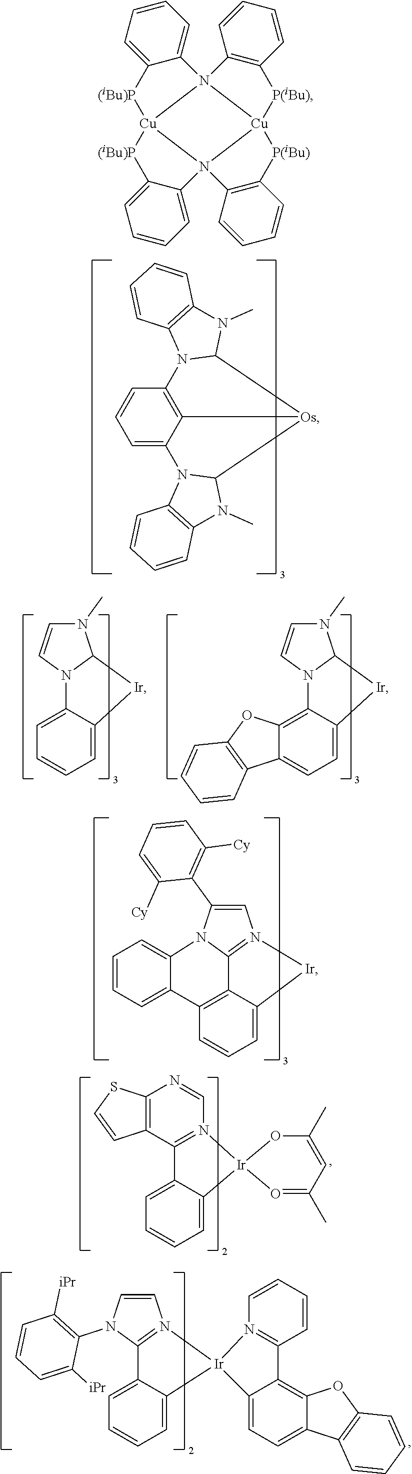

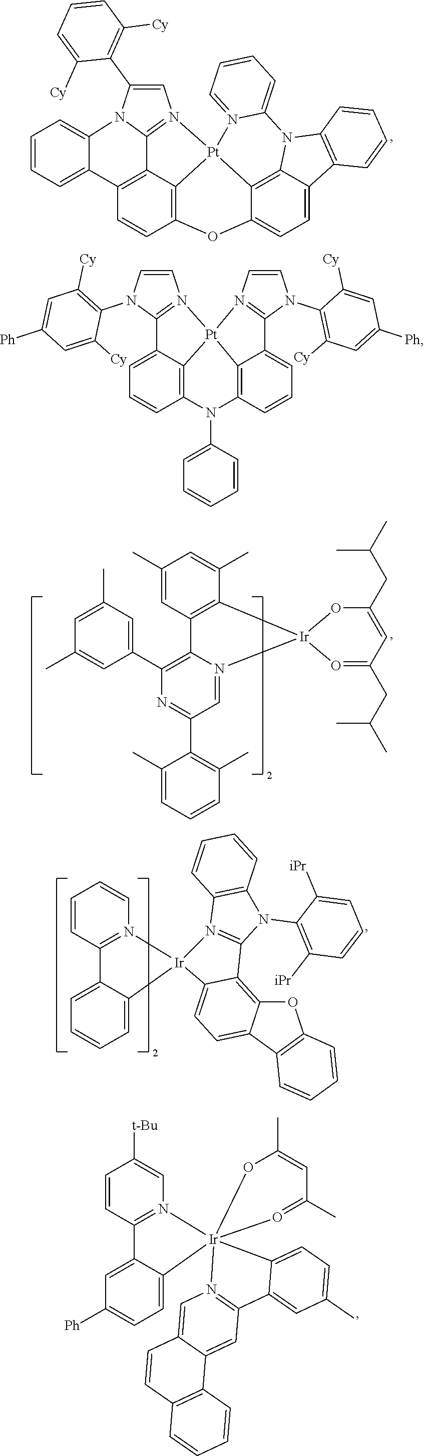

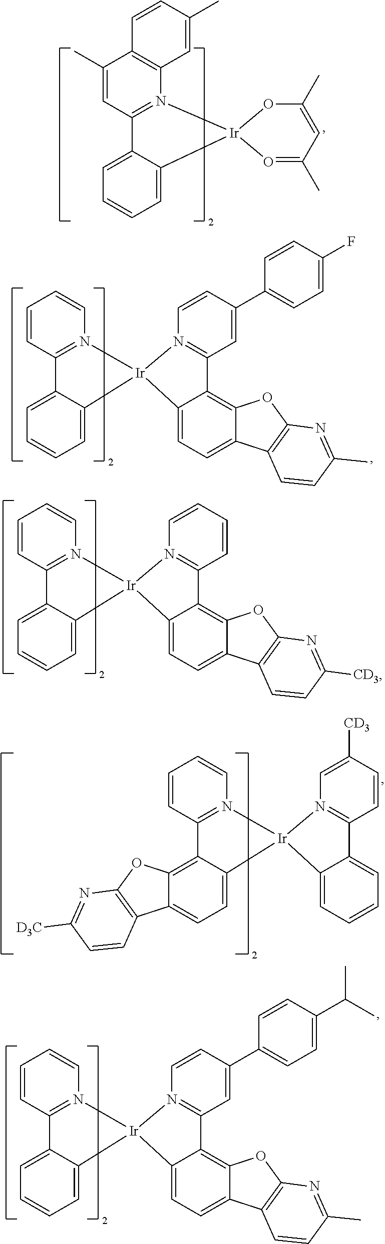

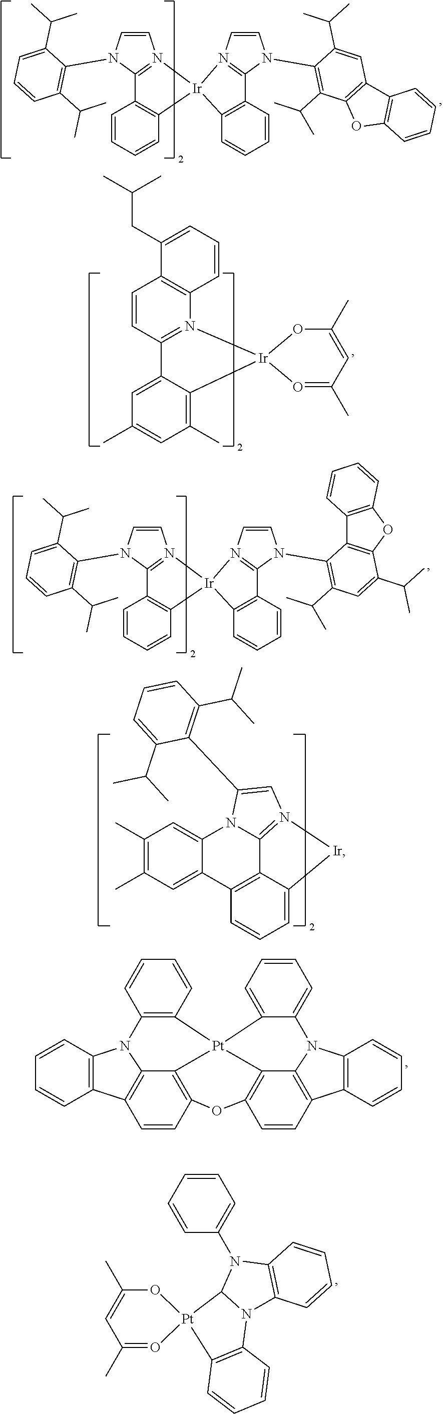

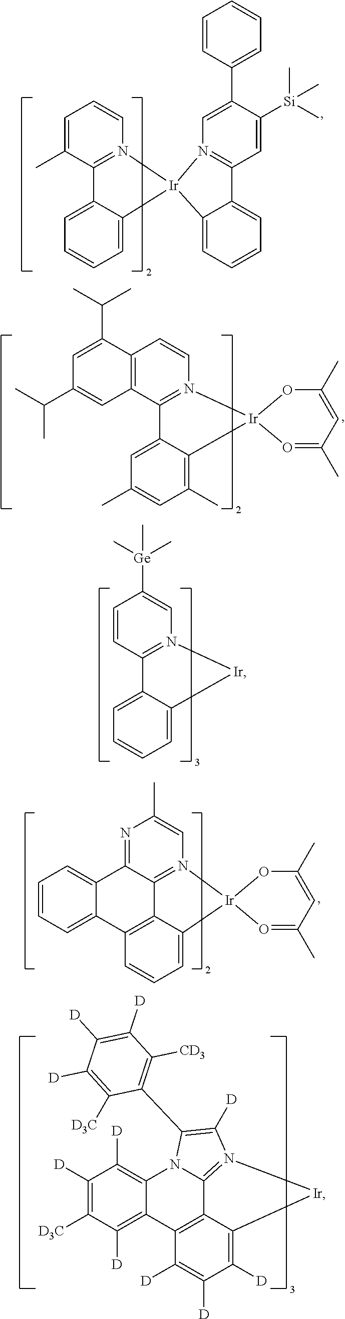

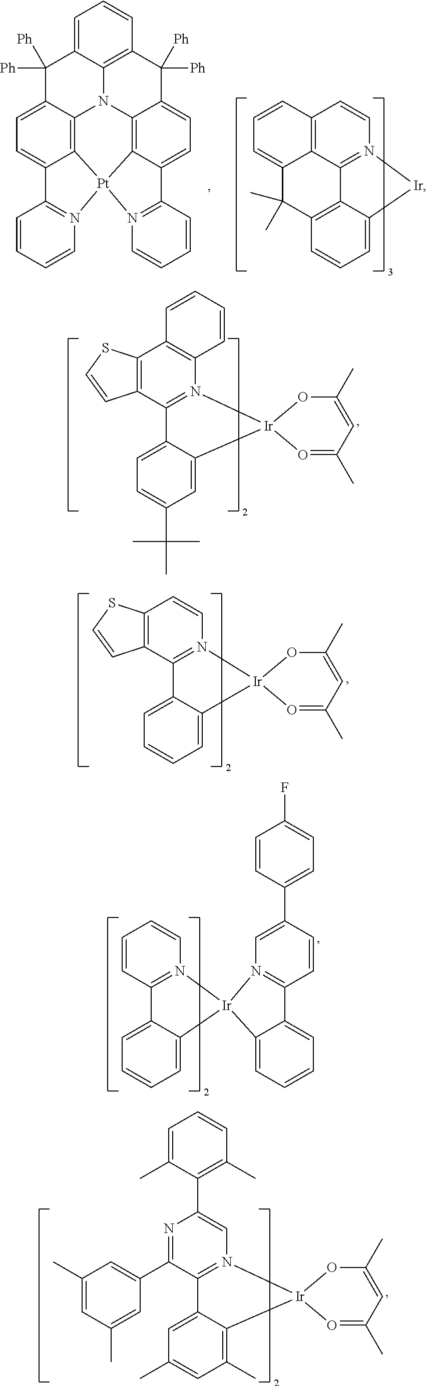

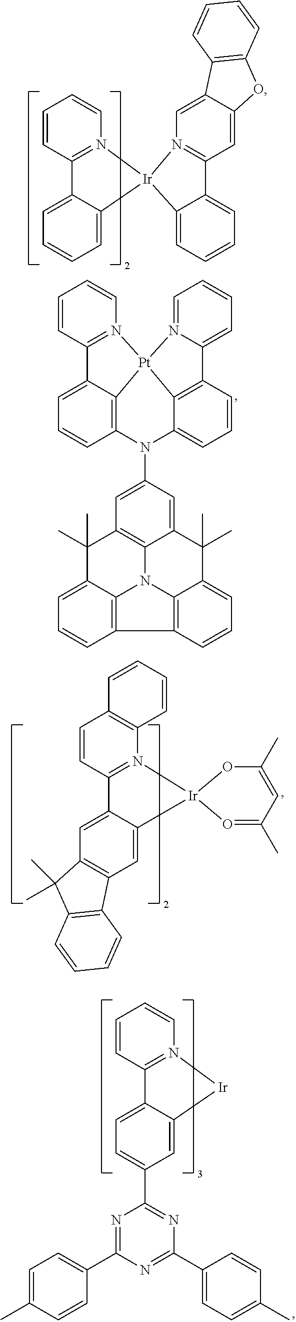

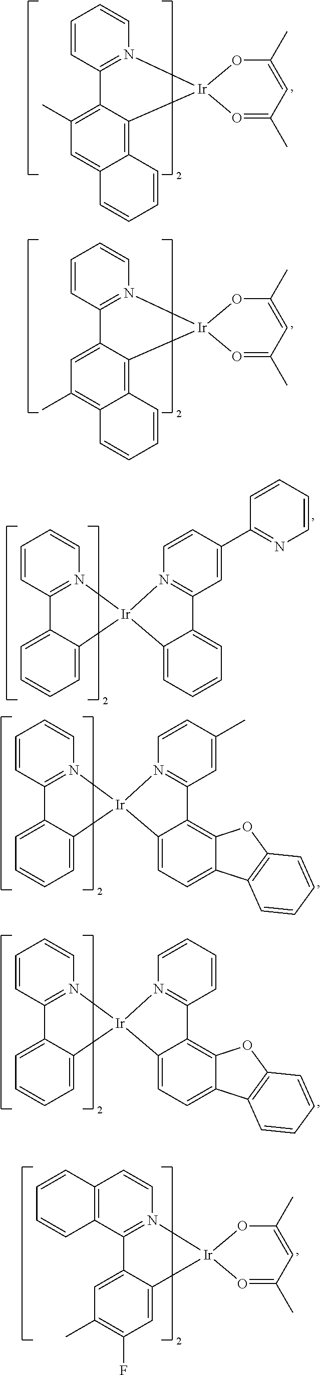

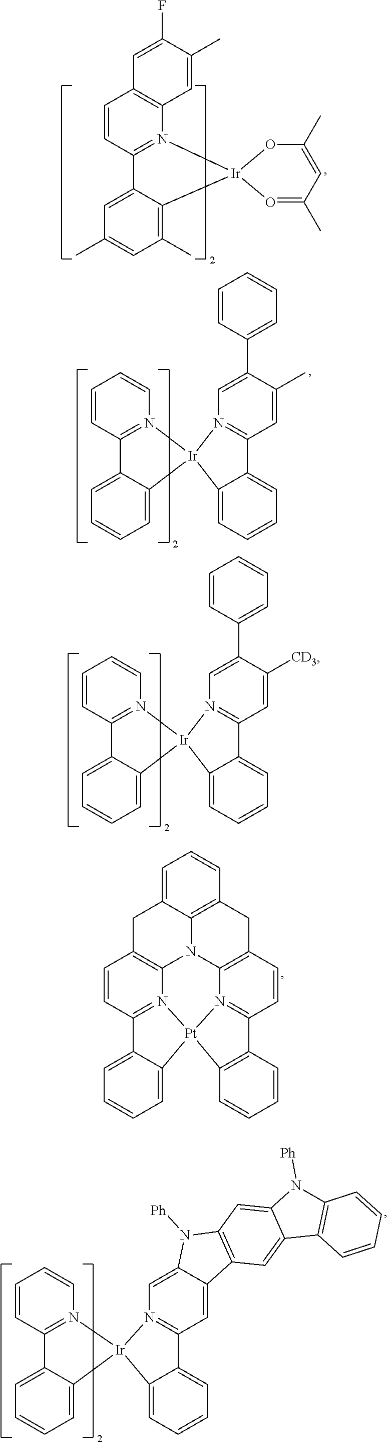

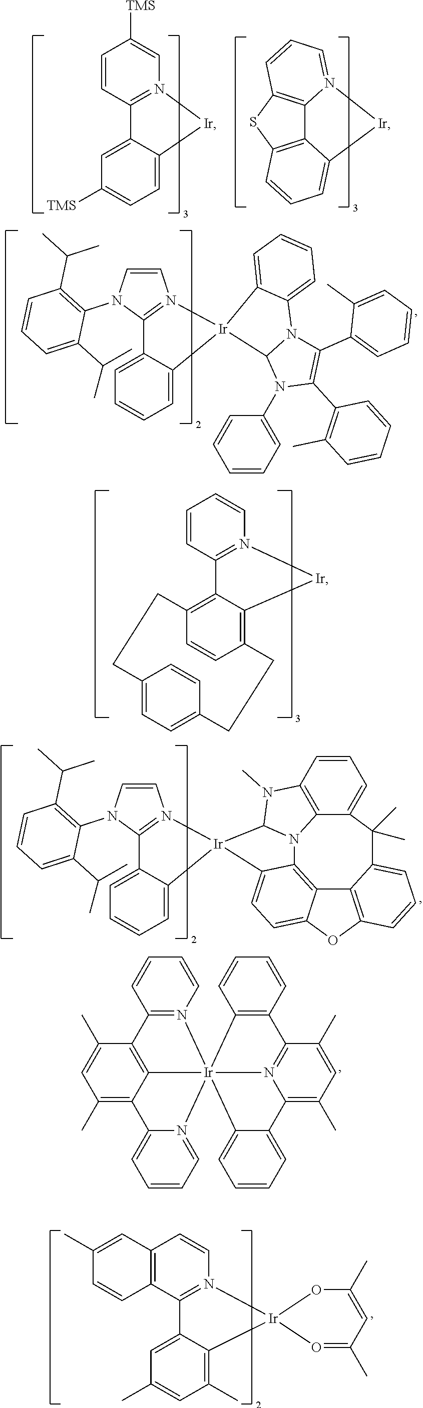

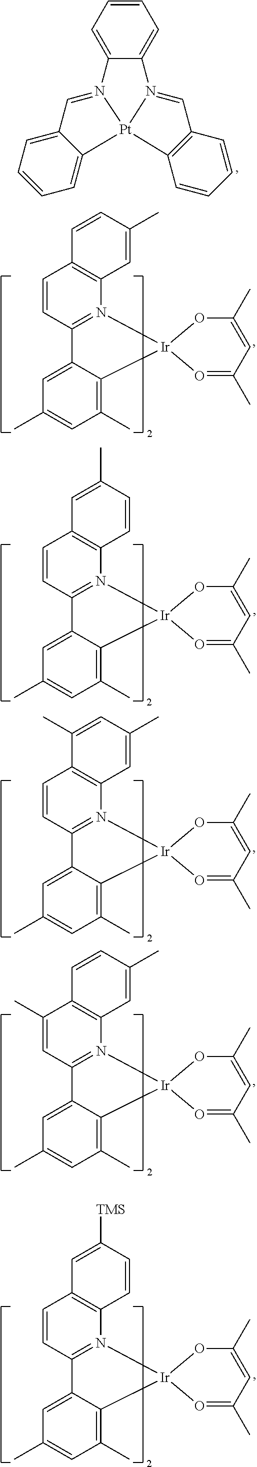

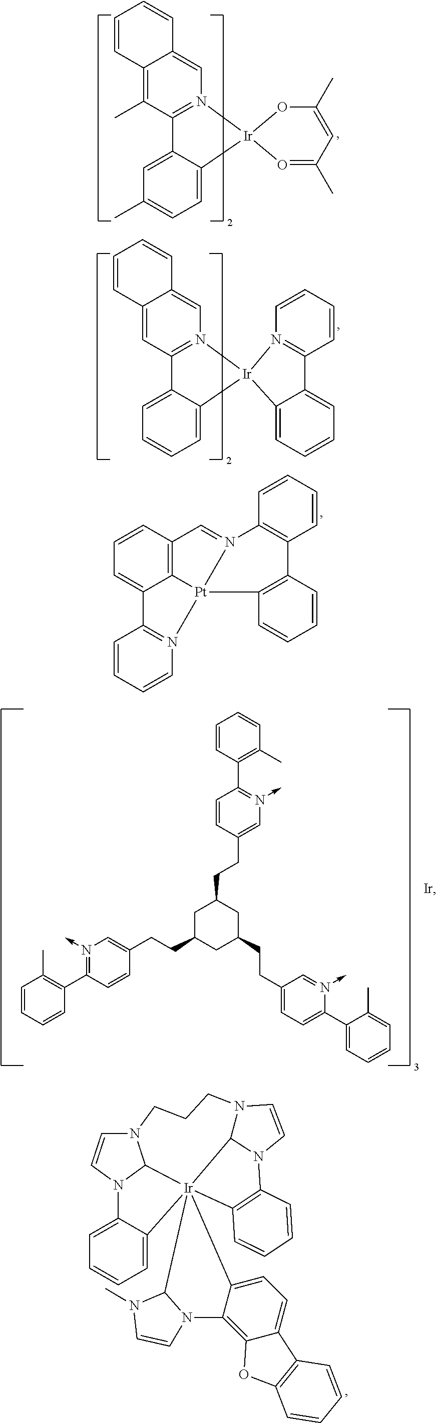

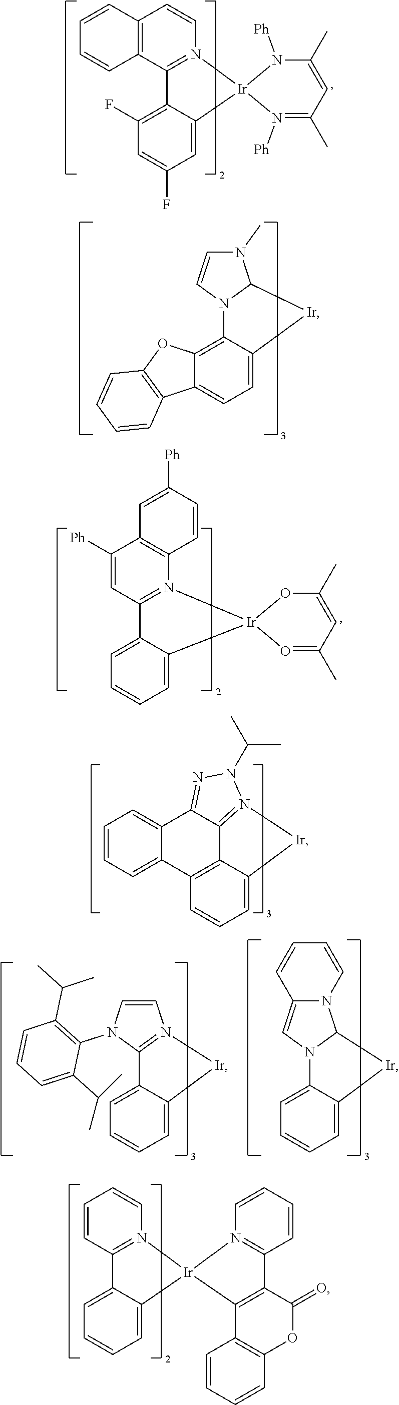

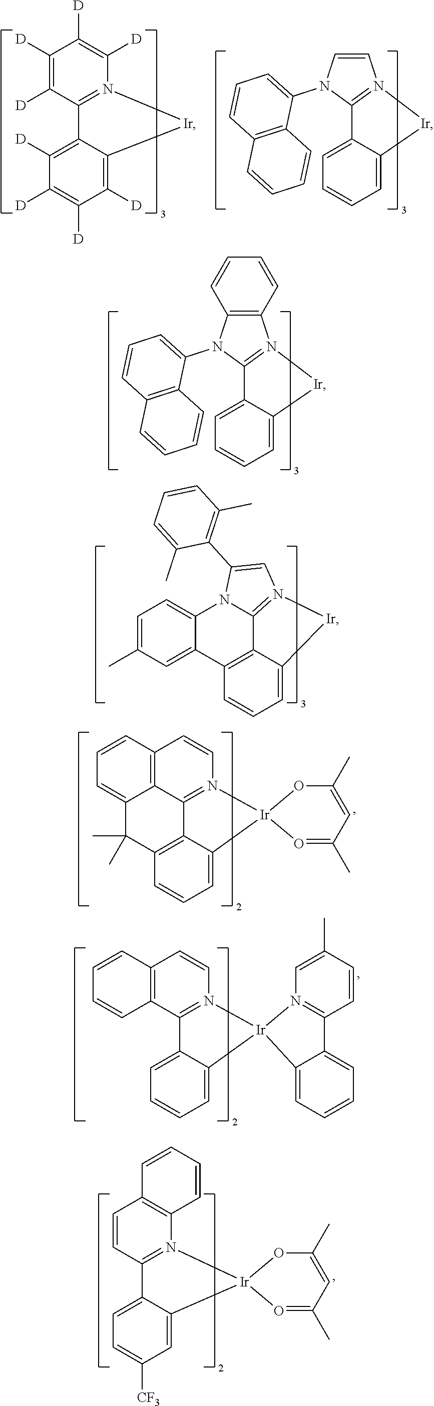

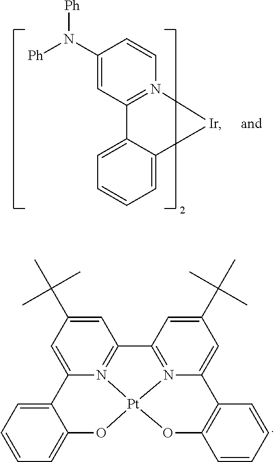

### f) HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and/or higher triplet energy than the emitter closest to the HBL interface. In some embodiments, the HBL material has a lower HOMO (further from the vacuum level) and/or higher triplet energy than one or more of the hosts closest to the HBL interface.

In one aspect, compound used in HBL contains the same molecule or the same functional groups used as host described above.

In another aspect, compound used in HBL contains at least one of the following groups in the molecule:

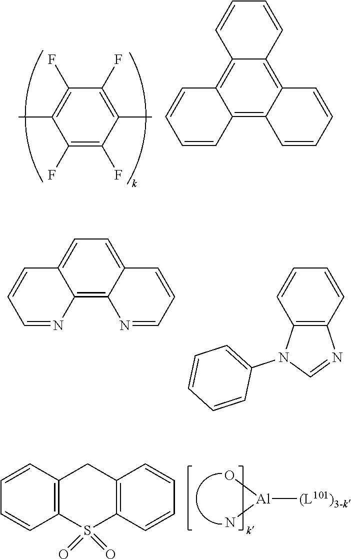

wherein k is an integer from 1 to 20; L¹⁰¹ is another ligand, k′ is an integer from 1 to 3.

### g) ETL:

Electron transport layer (ETL) may include a material capable of transporting electrons. Electron transport layer may be intrinsic (undoped), or doped. Doping may be used to enhance conductivity. Examples of the ETL material are not particularly limited, and any metal complexes or organic compounds may be used as long as they are typically used to transport electrons.

In one aspect, compound used in ETL contains at least one of the following groups in the molecule:

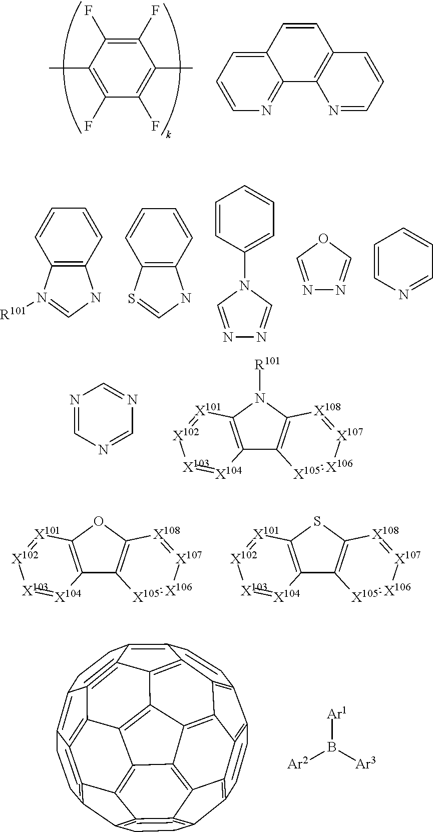

wherein R¹⁰¹ is selected from the group consisting of hydrogen, deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof, when it is aryl or heteroaryl, it has the similar definition as Ar's mentioned above. Ar¹ to Ar³ has the similar definition as Ar's mentioned above. k is an integer from 1 to 20. X¹⁰¹ to X¹⁰⁸ is selected from C (including CH) or N.

In another aspect, the metal complexes used in ETL contains, but not limit to the following general formula:

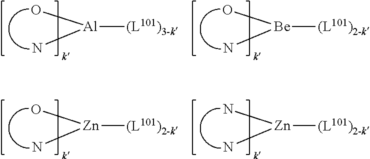

wherein (O—N) or (N—N) is a bidentate ligand, having metal coordinated to atoms O, N or N, N; L¹⁰¹ is another ligand; k′ is an integer value from 1 to the maximum number of ligands that may be attached to the metal.

Non-limiting examples of the ETL materials that may be used in an OLED in combination with materials disclosed herein are exemplified below together with references that disclose those materials: CN103508940, EP01602648, EP01734038, EP01956007, JP2004-022334, JP2005149918, JP2005-268199, KR0117693, KR20130108183, US20040036077, US20070104977, US2007018155, US20090101870, US20090115316, US20090140637, US20090179554, US2009218940, US2010108990, US2011156017, US2011210320, US2012193612, US2012214993, US2014014925, US2014014927, US20140284580, U.S. Pat. Nos. 6,656,612, 8,415,031, WO2003060956, WO2007111263, WO2009148269, WO2010067894, WO2010072300, WO2011074770, WO2011105373, WO2013079217, WO2013145667, WO2013180376, WO2014104499, WO2014104535,

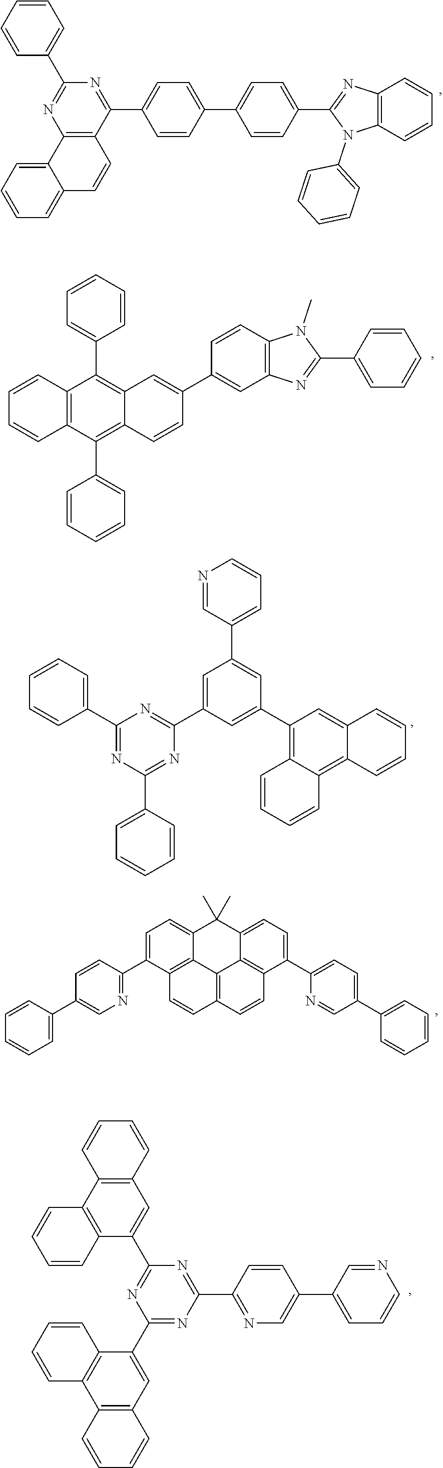 [SMILES: c1ccc(-c2nc(-c3ccc(-c4ccc(-c5nc6ccccc6n5-c5ccccc5)cc4)cc3)c3ccc4ccccc4c3n2)cc1 ; Cn1c(-c2ccccc2)nc2cc(-c3ccc4c(-c5ccccc5)c5ccccc5c(-c5ccccc5)c4c3)ccc21 ; c1ccc(-c2nc(-c3ccccc3)nc(-c3cc(-c4cccnc4)cc(-c4cc5ccccc5c5ccccc45)c3)n2)cc1 ; CC1(C)c2ccc(-c3ccc(-c4ccccc4)cn3)c3ccc4ccc5c(-c6ccc(-c7ccccc7)cn6)ccc1c5c4c23 ; c1cncc(-c2ccc(-c3nc(-c4cc5ccccc5c5ccccc45)nc(-c4cc5ccccc5c5ccccc45)n3)nc2)c1]

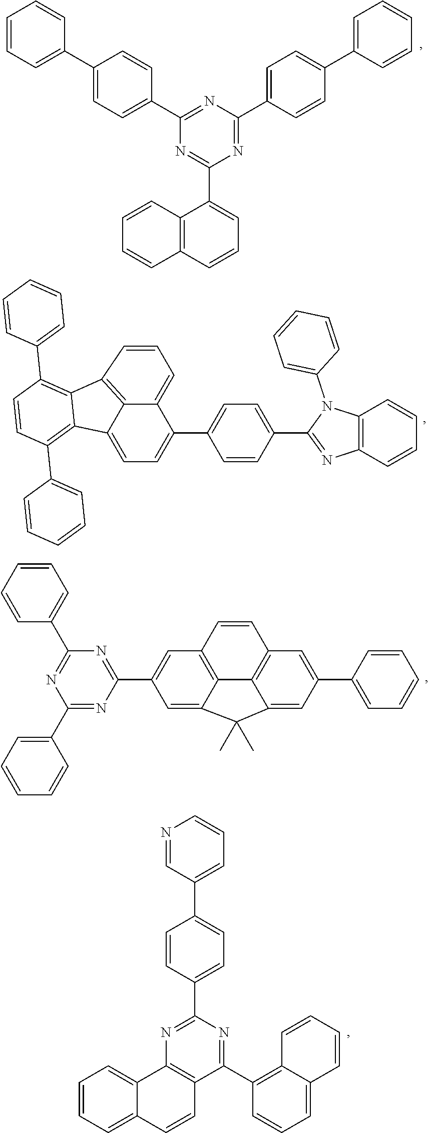

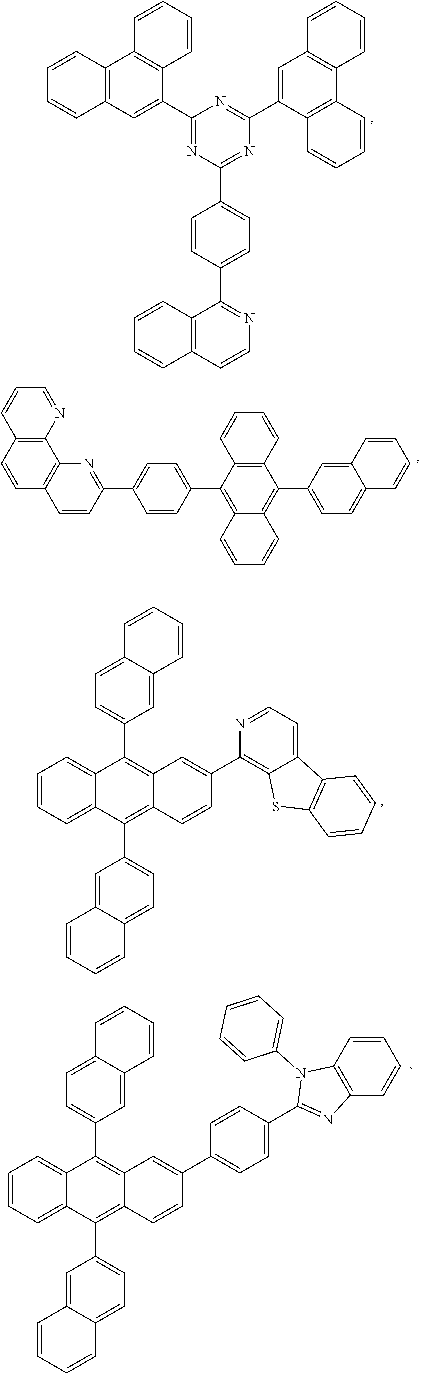

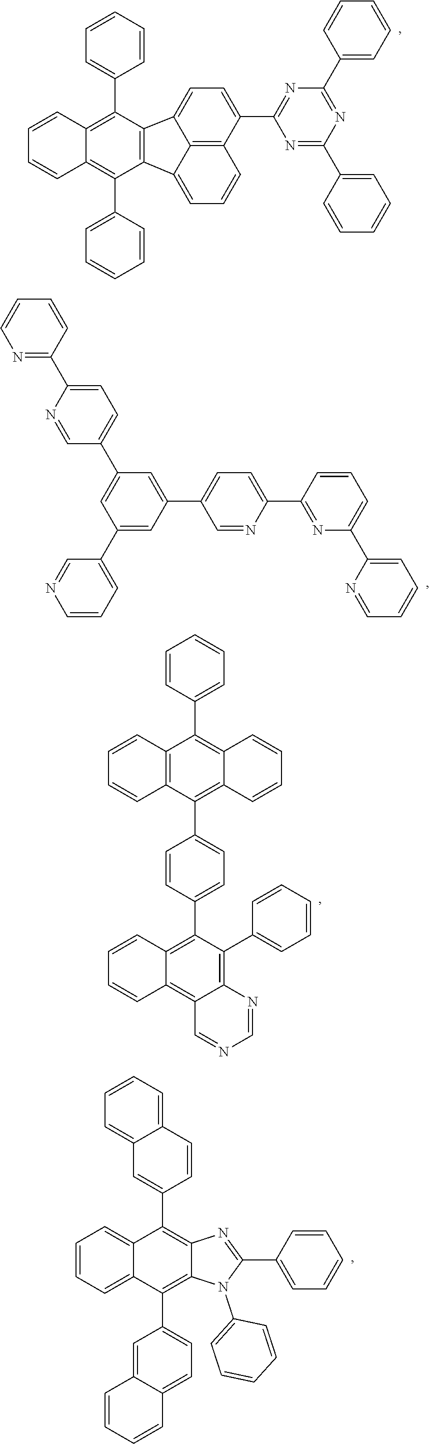 [SMILES: c1ccc(-c2nc(-c3ccccc3)nc(-c3ccc4c5c(cccc35)-c3c-4c(-c4ccccc4)c4ccccc4c3-c3ccccc3)n2)cc1 ; c1ccc(-c2ccc(-c3cc(-c4cccnc4)cc(-c4ccc(-c5cccc(-c6ccccn6)n5)nc4)c3)cn2)nc1 ; c1ccc(-c2c3ccccc3c(-c3ccc(-c4c(-c5ccccc5)c5ncncc5c5ccccc45)cc3)c3ccccc23)cc1 ; c1ccc(-c2nc3c(-c4ccc5ccccc5c4)c4ccccc4c(-c4ccc5ccccc5c4)c3n2-c2ccccc2)cc1]

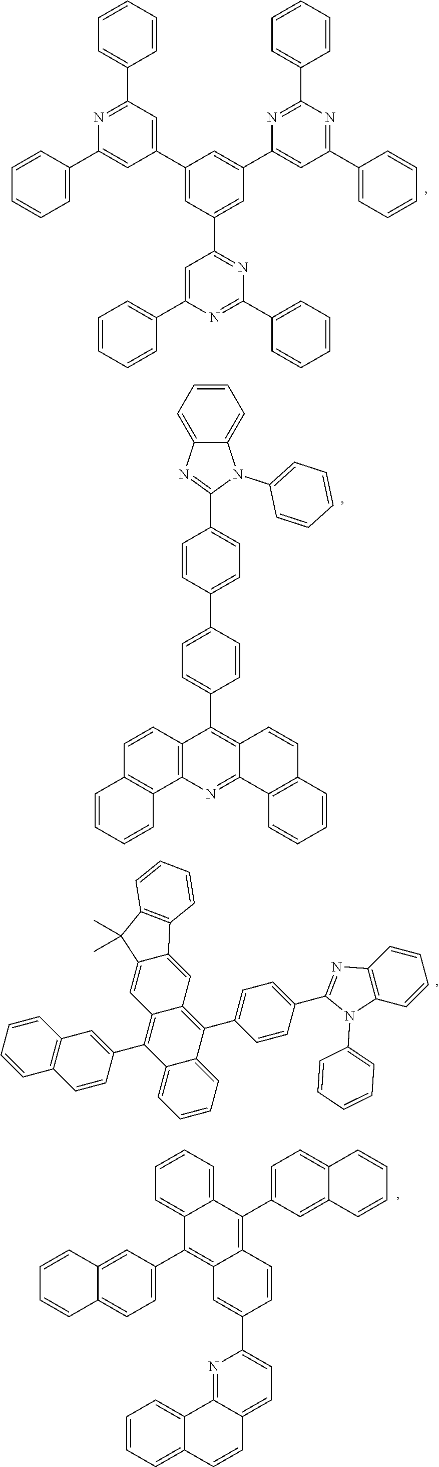

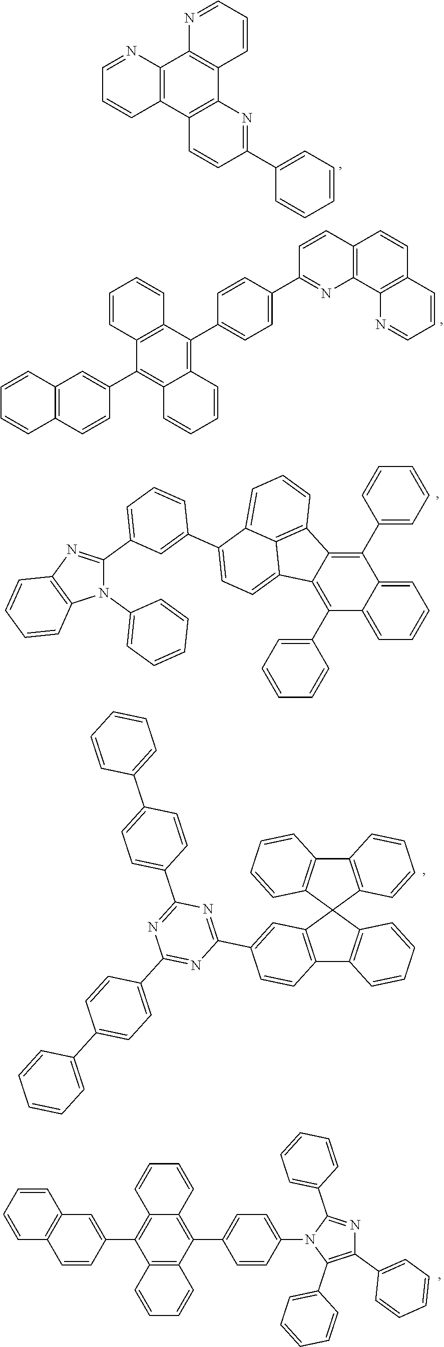

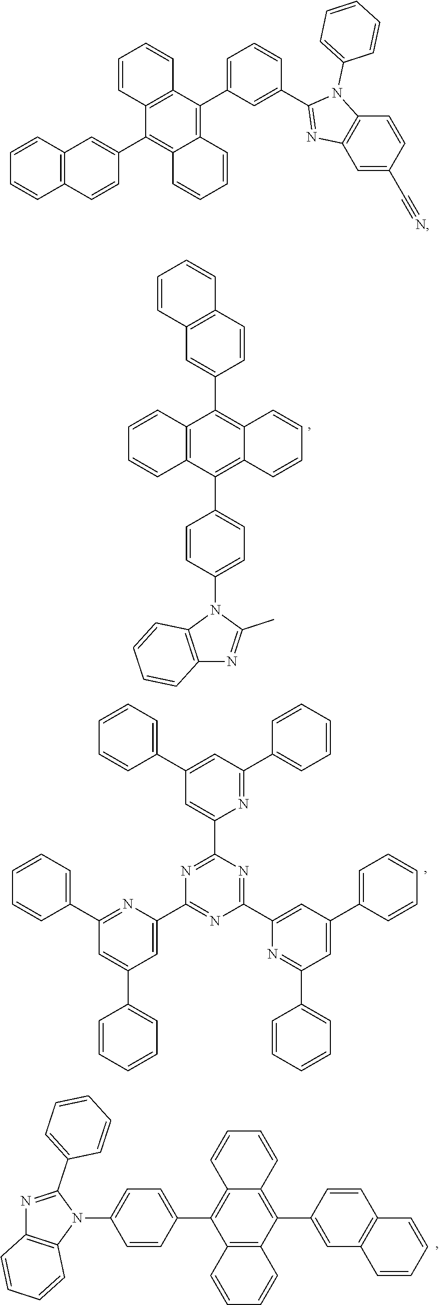

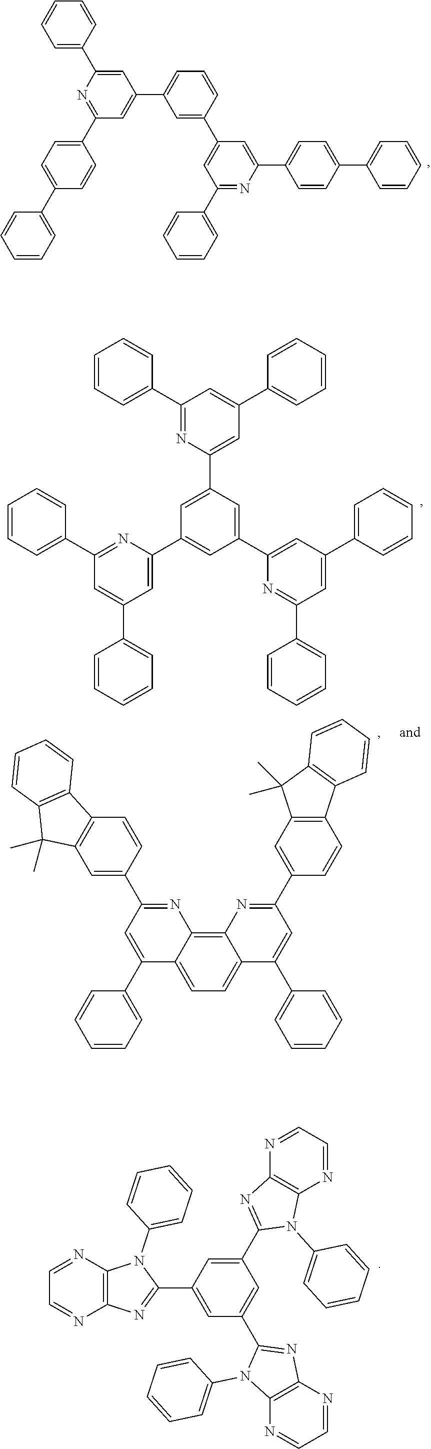

### h) Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

In any above-mentioned compounds used in each layer of the OLED device, the hydrogen atoms can be partially or fully deuterated. Thus, any specifically listed substituent, such as, without limitation, methyl, phenyl, pyridyl, etc. may be undeuterated, partially deuterated, and fully deuterated versions thereof. Similarly, classes of substituents such as, without limitation, alkyl, aryl, cycloalkyl, heteroaryl, etc. also may be undeuterated, partially deuterated, and fully deuterated versions thereof.

### Experimental Data

Compounds and emitters used in experimental device data:

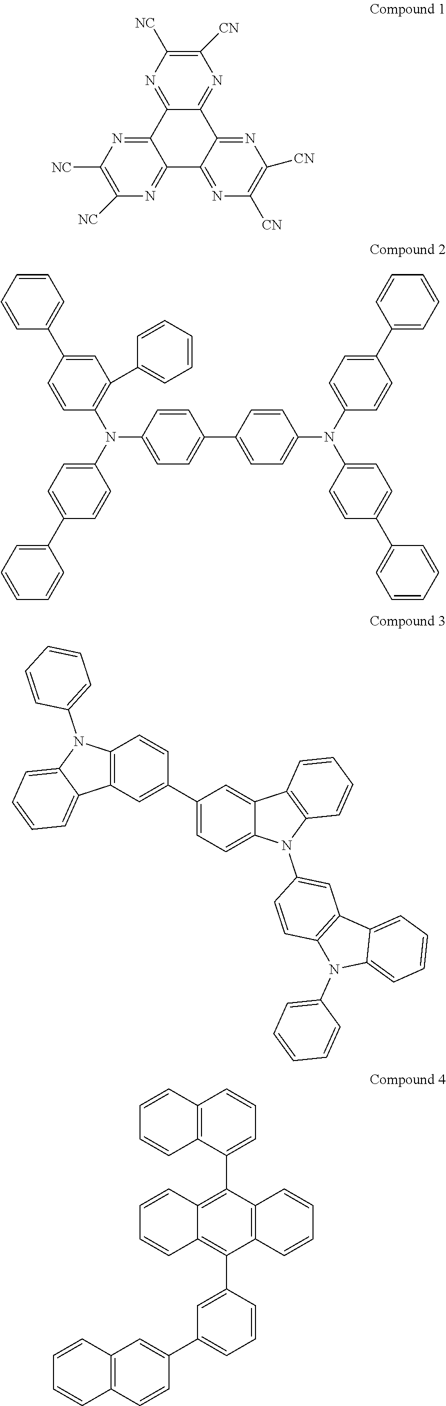

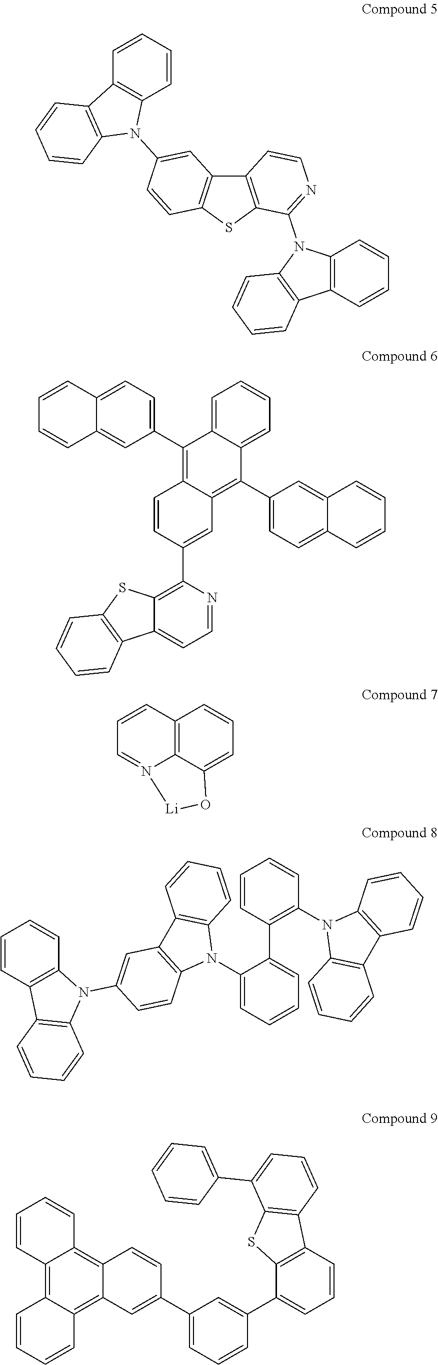

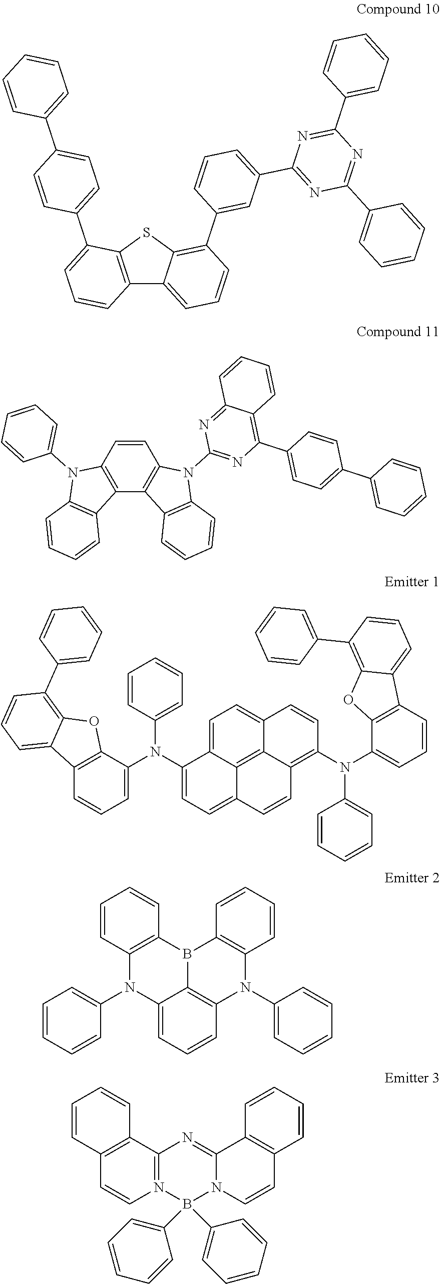

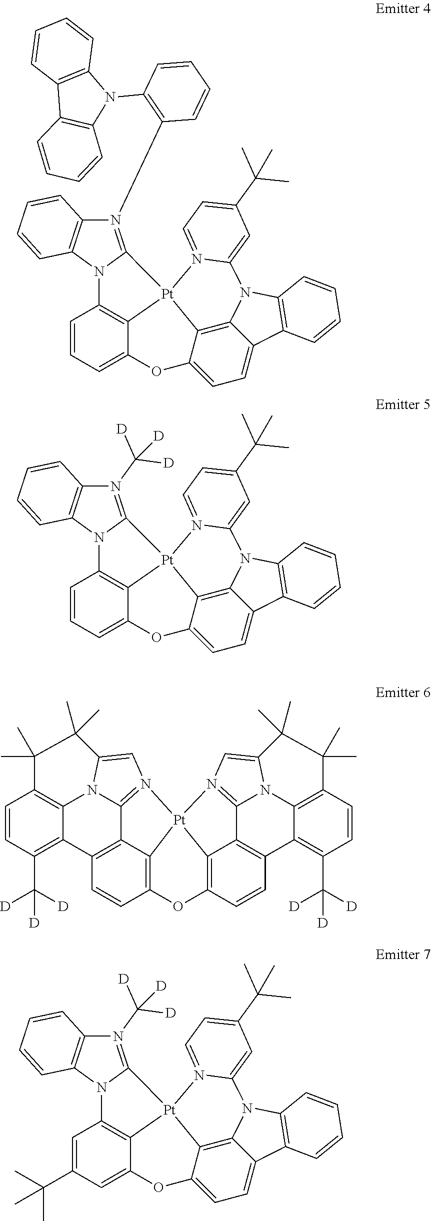

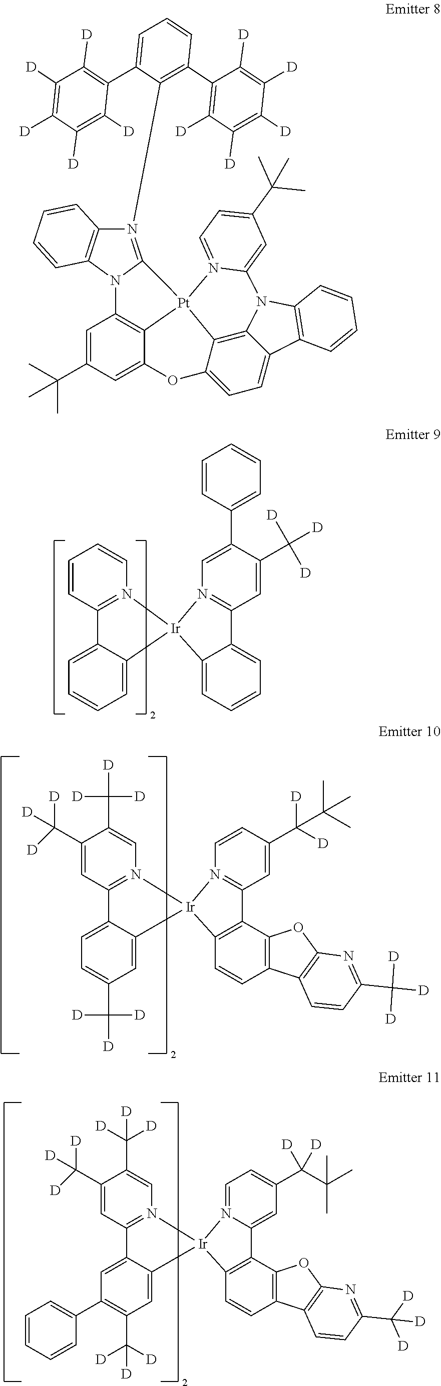

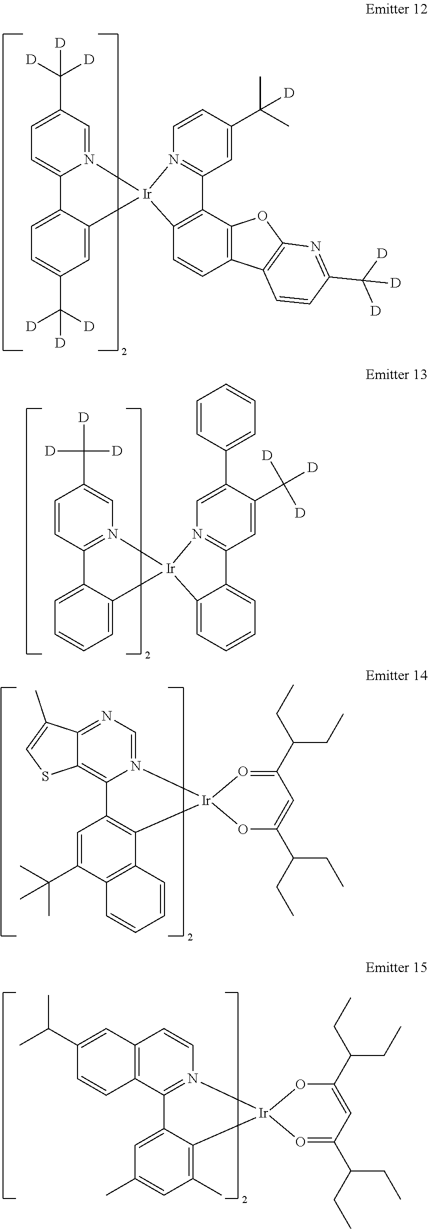

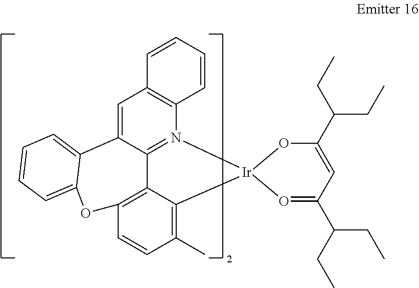

OLEDs were grown on a glass substrate pre-coated with an indium-tin-oxide (ITO) layer having a sheet resistance of 15 Ω/sq. Prior to any organic layer deposition or coating, the substrate was degreased with solvents and then treated with an oxygen plasma for 1.5 minutes with 50 W at 100 mTorr and with UV ozone for 5 minutes.

The devices in Tables 1 were fabricated in high vacuum (<10⁻⁶ Torr) by thermal evaporation. The anode electrode was 750 Å of indium tin oxide (ITO). The device examples had organic layers consisting of, sequentially from the ITO surface, 100 Å thick Compound 1 (as HIL), 250 Å layer of Compound 2 (as HTL), 50 Å of Compound 3 (as EBL) if any, 300 Å of Compound 4 doped with 3% of example Emitters 1, 2, or 3 (EML), 50 Å of Compound 5 (as HBL), 200-300 Å of Compound 7 doped with 35% of Compound 6 (as ETL), 10 Å of Compound 7 (as EIL) followed by 1,000 Å of Al (as Cathode). All devices were encapsulated with a glass lid sealed with an epoxy resin in a nitrogen glove box (<1 ppm of H₂O and O₂) immediately after fabrication with a moisture getter incorporated inside the package. Doping percentages are in volume percent.

TABLE 1
Summarized devices with and without EBL with emitter Example 1 and an ETL of 300 Å.

| | | | | | at 10 mA/cm² | | | | at 1,000 cd/m² |
|---|---|---|---|---|---|---|---|---|---|
| | | ETL | 1931 CIE | | λ max | FWHM | Voltage | EQE | LT_{95%} |
| | Emitter | [Å] | x | y | [nm] | [nm] | [norm] | [%] | [norm] |
| With EBL | 1 | 300 | 0.135 | 0.115 | 457 | 45 | 1.0 | 10 | 5.0 |
| Without EBL | 1 | 300 | 0.137 | 0.114 | 457 | 44 | 1.0 | 7 | 1.0 |

TABLE 2
Summarized devices with and without EBL with emitter Example 2 and an ETL of 200 Å.

| | | | | | at 10 mA/cm² | | | | at 1,000 cd/m² |
|---|---|---|---|---|---|---|---|---|---|
| | | ETL | 1931 CIE | | λ max | FWHM | Voltage | EQE | LT_{95%} |
| | Emitter | [Å] | x | y | [nm] | [nm] | [norm] | [%] | [norm] |
| With EBL | 2 | 200 | 0.134 | 0.077 | 460 | 25 | 1.0 | 8 | 3.1 |
| Without EBL | 2 | 200 | 0.136 | 0.078 | 459 | 25 | 1.0 | 6 | 1.0 |

TABLE 3
Summarized devices with and without EBL with Emitter 3 and an ETL of 250 Å.

| | | | | | at 10 mA/cm² | | | | at 1,000 cd/m² |
|---|---|---|---|---|---|---|---|---|---|
| | | ETL | 1931 CIE | | λ max | FWHM | Voltage | EQE | LT_{95%} |
| | Emitter | [Å] | x | y | [nm] | [nm] | [norm] | [%] | [norm] |
| With EBL | 3 | 250 | 0.137 | 0.375 | 479 | 49 | 1.0 | 9 | 8.9 |
| Without | 3 | 250 | 0.139 | 0.363 | 478 | 48 | 1.0 | 6 | 1.0 |
| EBL | | | | | | | | | |

Emitter 3 increased the device EQE and lifetime for all example emitters. Emitter 2 is a thermally activated delayed fluorescent (TADF) fluorophore with a large fraction of initial fluorescence. By using it as an emitter in compound 4 as a host, all the triplets created on Emitter example 2 will be transferred to the host rather than converted to emission via reverse inter-system crossing. It is worth noting that Compound 3 works as an EBL for this emitter as well.

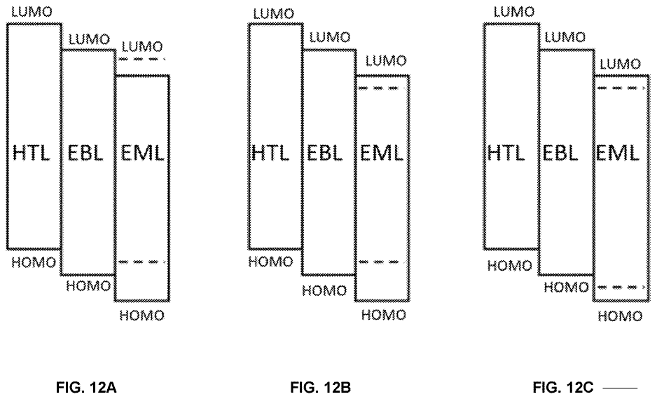

FIG. 12 shows an example energy level diagram of an OLED containing an EBL comprising the EBL material of the present disclosure. The dashed lines in the EML represent the energy levels of the emitter. FIG. 12A represents the energy levels of the EBL relative to the EML for the devices in Table 1. Note that the emitter has a LUMO level greater in energy than that of the host but less than that of the EBL. FIG. 12B represents the energy levels of EBL relative to the EML for the devices in Table 2. Note that the emitter has a LUMO level less than that of the host and less than that of the EBL while the HOMO level of the emitter is greater than that of the EBL and the host. FIG. 12C represents the energy levels of the EBL relative to the EML for the devices in Table 3. Note that the emitter has a LUMO level less than that of the host and less than that of the EBL while the HOMO level of the emitter is greater than the host but less than the EBL. Thus, the use of these EBLs extends to many energy level configurations of the host and emitter HOMO level and LUMO level. We will additionally note that the T₁ of the EBL is greater than that of both the host and the emitter and is high enough that it can be utilized as an EBL for phosphorescent devices simultaneously as with fluorescent devices.

It was also observed that use of Compound 3 as the EBL resulted in better EQE at low current density in the device compared to the reference device without the EBL.

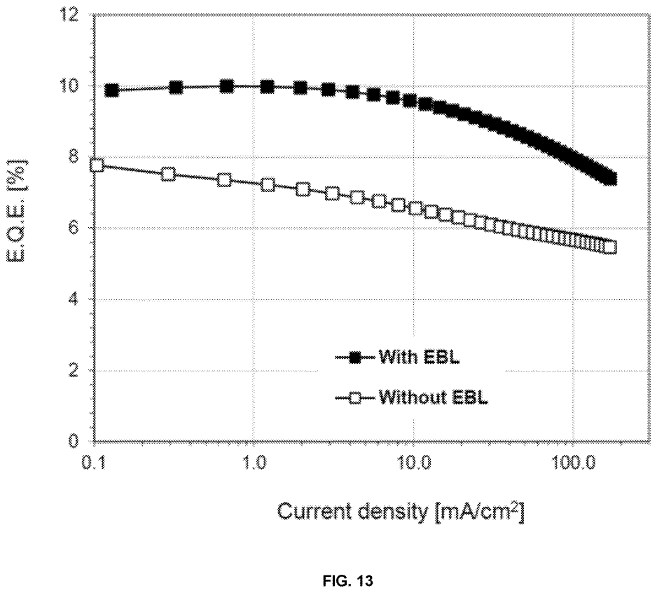

FIG. 13 is a plot of EQE vs. current density for two devices with Emitter 1. One device with an EBL of the present disclosure and one device without the EBL. Note that the device with the EBL demonstrates less roll-off, maintaining 96% of the EQE of the value at 0.1 mA/cm² at 10 mA/cm². While the device without the EBL shows significant roll-off, achieving only 82% of the EQE at 10 mA/cm² that it has at 0.1 mA/cm².

In addition to working well for fluorescent materials, Compound 3 also works for phosphorescent organic light emitting devices (PHOLED) including blue, green, and red emitters. Examples devices are summarized below in Tables 4 through 6.

TABLE 4
Summarized blue PHOLED devices with and without EBL.

| | | | | at 10 mA/cm² | | | | at 1,000 cd/m² |
|---|---|---|---|---|---|---|---|---|
| | | 1931 CIE | | λ max | FWHM | Voltage | EQE | LT_{95%} |
| | Emitter | x | y | [nm] | [nm] | [norm] | [norm] | [norm] |
| With EBL | 4 | 0.134 | 0.255 | 471 | 45 | 1.0 | 1.2 | 8.9 |
| Without EBL | 4 | 0.134 | 0.246 | 471 | 43 | 1.1 | 0.7 | 8.7 |
| With EBL | 5 | 0.137 | 0.134 | 459 | 33 | 1.0 | 1.2 | 1.1 |
| Without EBL | 5 | 0.138 | 0.129 | 459 | 29 | 1.0 | 1.0 | 1.0 |
| With EBL | 6 | 0.154 | 0.438 | 484 | 18 | 1.1 | 1.9 | 49.4 |
| Without EBL | 6 | 0.152 | 0.425 | 484 | 18 | 1.1 | 1.2 | 53.0 |
| With EBL | 7 | 0.134 | 0.155 | 462 | 34 | 1.1 | 1.4 | 2.4 |
| Without EBL | 7 | 0.135 | 0.146 | 462 | 29 | 1.1 | 1.1 | 2.2 |
| With EBL | 8 | 0.133 | 0.218 | 468 | 42 | 1.1 | 1.5 | 5.6 |
| Without EBL | 8 | 0.133 | 0.207 | 467 | 39 | 1.1 | 1.1 | 5.3 |

The devices in Table 4 were fabricated in high vacuum (<10-6 Torr) by thermal evaporation. The anode electrode was 750 Å of indium tin oxide (ITO). The device example had organic layers consisting of, sequentially, from the ITO surface, 100 Å thick Compound 1 (HIL), 250 Å layer of Compound 2 (HTL), 50 Å of Compound 3 (EBL) if any, 300 Å of Compound 8 doped at 40% with Compound with 5 and 12% of the emitter (EMIL), 50 Å of Compound 5 (BL), 300 Å of Compound 7 doped with 35% of Compound 6 (ETL), 10 Å of Compound 7 (EIL) followed by 1,000 Å of Al (Cath). Doping percentages are in volume percent. Note the EBL increases the EQE for all blue PHOLED emitters and maintains or increases stability of the device.

TABLE 5
Summarized green PHOLED devices with and without EBL

| | | | | | | | | | at 3,000 |
|---|---|---|---|---|---|---|---|---|---|
| | | | | | at 10 mA/cm² | | | | cd/m² |
| | | HTL | 1931 CIE | | λ max | FWHM | Voltage | EQE | LT_{95%} |
| | Emitter | [Å] | x | y | [nm] | [nm] | [norm] | [norm] | [norm] |
| With EBL | 9 | 400 | 0.344 | 0.616 | 526 | 74 | 1.0 | 1.1 | 1.3 |
| Without EBL | 9 | 450 | 0.338 | 0.620 | 526 | 73 | 1.0 | 1.0 | 1.0 |
| With EBL | 10 | 400 | 0.350 | 0.624 | 529 | 59 | 1.0 | 1.3 | 5.4 |
| Without EBL | 10 | 450 | 0.349 | 0.624 | 529 | 59 | 1.0 | 1.3 | 3.8 |
| With EBL | 11 | 400 | 0.342 | 0.629 | 528 | 58 | 1.0 | 1.4 | 3.1 |
| Without EBL | 11 | 450 | 0.343 | 0.629 | 528 | 59 | 1.0 | 1.4 | 3.1 |
| With EBL | 12 | 400 | 0.346 | 0.624 | 527 | 62 | 1.0 | 1.3 | 3.1 |
| Without EBL | 12 | 450 | 0.342 | 0.627 | 527 | 61 | 1.0 | 1.2 | 2.7 |
| With EBL | 13 | 400 | 0.341 | 0.619 | 527 | 72 | 1.0 | 1.1 | 4.8 |
| Without EBL | 13 | 450 | 0.343 | 0.618 | 528 | 72 | 0.9 | 1.0 | 4.5 |

The devices in Table 5 were fabricated in high vacuum (<10-6 Torr) by thermal evaporation. The anode electrode was 750 Å of indium tin oxide (ITO). The device example had organic layers consisting of, sequentially, from the ITO surface, 100 Å thick Compound 1 (HIL), 400 or 450 Å layer of Compound 2 (HTL), 50 Å of Compound 3 (EBL) if any, 400 Å of Compound 9 doped at 40% with Compound with 10 and 12% of the emitter (EML), 350 Å of Compound 7 doped with 35% of Compound 6 (ETL), 10 Å of Compound 7 (EIL) followed by 1,000 Å of Al (Cath). Doping percentages are in volume percent. Note the EBL increases or maintains the EQE of the green PHOLED emitters and maintains or increases stability of the device.

TABLE 6
Summarized red PHOLED devices with and without EBL

| | | | | | at 10 mA/cm² | | | | at 1,000 cd/m² |
|---|---|---|---|---|---|---|---|---|---|
| | | HTL | 1931 CIE | | λ max | FWHM | Voltage | EQE | LT_{95%} |
| | Emitter | [Å] | x | y | [nm] | [nm] | [norm] | [norm] | [norm] |
| With EBL | 14 | 400 | 0.686 | 0.313 | 628 | 38 | 1.1 | 1.3 | 6.0 |
| Without EBL | 14 | 450 | 0.686 | 0.313 | 628 | 38 | 1.1 | 1.3 | 4.7 |
| With EBL | 15 | 400 | 0.683 | 0.316 | 624 | 50 | 1.2 | 1.6 | 65.4 |
| Without EBL | 15 | 450 | 0.682 | 0.317 | 625 | 50 | 1.2 | 1.5 | 68.8 |
| With EBL | 16 | 400 | 0.651 | 0.348 | 617 | 76 | 1.0 | 1.0 | 1.0 |
| Without EBL | 16 | 450 | 0.651 | 0.348 | 617 | 76 | 1.0 | 1.0 | 1.0 |

The devices in Table 6 were fabricated in high vacuum (<10-6 Torr) by thermal evaporation. The anode electrode was 1150 Å of indium tin oxide (ITO). The device example had organic layers consisting of, sequentially, from the ITO surface, 100 Å thick Compound 1 (HIL), 400 or 450 Å layer of Compound 2 (HTL), 50 Å of Compound 3 (EBL) if any, 400 Å of Compound 11 doped at 3% of the emitter (EML), 350 Å of Compound 7 doped with 35% of Compound 6 (ETL), 10 Å of Compound 7 (EIL) followed by 1,000 Å of Al (Cathod). Doping percentages are in volume percent. Note the EBL increases or maintains the EQE of the red PHOLED emitters and maintains similar or better stability of the device.

It is understood that the various embodiments described herein are by way of example only and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

What is claimed is:

1. A device comprising:
a first pixel comprising a first OLED;
a second pixel comprising a second OLED; wherein each OLED independently comprises, sequentially:
an anode;
a hole transporting layer comprising a hole transporting material;
an electron blocking layer (EBL) comprising an electron/exciton blocking material;
an emissive region comprising an emissive layer (EML) that comprises an emissive dopant; and
a cathode;
wherein the EML of the first OLED and the EML of the second OLED have different emissive dopants resulting in the two OLEDs having different emission spectra;
wherein the EBLs of the first and second OLEDs comprise the same electron/exciton blocking material.

2. The device of claim 1, wherein the electron/exciton blocking material is a compound of 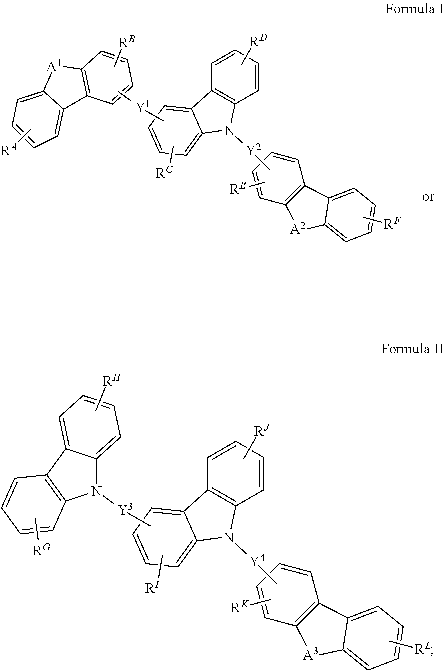
wherein,
A¹, A², and A³ are each independently selected from the group consisting of O, S, and NR;
Y¹, Y², Y³, and Y⁴ are each independently a direct bond, O, S, NR, or an organic linker comprising 1 to 18 carbon atoms;
R^{A} to R^{L} each independently represents mono to the maximum allowable substitutions, or no substitution;
each R, R^{A} to R^{L} is independently a hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, boryl, and combinations thereof; and any two substituents can be joined or fused together to form a ring.

3. The device of claim 1, wherein the device further comprises a third pixel comprising a third OLED;
wherein the third OLED comprises the same sequence of layers as the and second OLEDs and the emissive dopant in the EML in the third OLED is different from the emissive dopants of the first and second OLEDs, thus resulting in the three OLEDs having different emission spectra; and
wherein the EBLs of the first, second, and third OLEDs comprise the same electron/exciton blocking material.

4. The device of claim 1, wherein the EML of the first OLED emits light having a peak wavelength in the visible spectrum of 400-500 nm and the emissive layer of the second OLED emits light having a peak wavelength in the visible spectrum of 500-700 nm.

5. The device of claim 3, wherein the EML of the first OLED emits light having a peak wavelength in the visible spectrum of 400-500 nm,
the emissive layer of the second OLED emits light having a peak wavelength in the visible spectrum of 500-600 nm, and
the emissive layer of the third OLED emits light having a peak wavelength in the visible spectrum of 600-700 nm.

6. The device of claim 1, wherein the emissive dopant of the first OLED and the emissive dopant of the second OLED are independently a phosphorescent material.

7. The device of claim 1, wherein the emissive dopant of the first OLED is a fluorescent or a delayed fluorescent material; and the emissive dopant of the second OLED is a phosphorescent material.

8. The device of claim 1, wherein the emissive dopant of the first OLED and the emissive dopant of the second OLED are independently a fluorescent or a delayed fluorescent material.

9. The device of claim 3, wherein the emissive dopants of the first, second, and third OLEDs are all phosphorescent material.

10. The device of claim 3, wherein the emissive dopant of at least one of the first, second, and third OLEDs is a phosphorescent material; and the emissive dopant of at least one of the first, second, and third OLEDs is a fluorescent or a delayed fluorescent material.

11. The device of claim 3, wherein the device further comprises a fourth pixel comprising a fourth OLED;
wherein the fourth OLED comprises the same sequence of layers as the first, second, and third OLEDs, and the emissive dopant in the emissive layer of the fourth OLED is different from the emissive dopants of the first, second, and third OLEDs, thus resulting in the four OLEDs having different emission spectra; and
wherein the EBLs of the first, second, third, and fourth OLEDs comprise the same electron/exciton blocking material.

12. The device of claim 1, wherein every OLED in the device share a single EBL.

13. The device of claim 1, wherein every OLED in the device share a single hole injecting layer between their anode and hole transporting layer.

14. The device of claim 1, wherein every OLED in the device share a single hole blocking layer between their emissive layer and cathode.

15. The device of claim 3, wherein every OLED in the device share a single EBL.

16. The device of claim 3, wherein every OLED in the device share a single hole injecting layer between their anode and hole transporting layer.

17. The device of claim 3, wherein every OLED in the device share a single hole blocking layer between their emissive layer and cathode.

18. The device of claim 1, wherein every OLED in the device share a single EBL.

19. The device of claim 3, wherein every OLED in the device share a single hole injecting layer between their anode and hole transporting layer.

20. The device of claim 3, wherein every OLED in the device share a single hole blocking layer between their emissive layer and cathode.
